(19) United States
(12) Patent Application Publication
(10) Pub. No.: US 2026/0136908 A1
(43) Pub. Date: May 14, 2026

(54) SEMICONDUCTOR DEVICE AND METHODS OF FORMATION

(71) Applicant: Tiawan Semiconductor Manufacturing Company, Ltd., Hsinchu (TW)

(72) Inventor: Tzu-Ging LIN, Kaohsiung City (TW)

(21) Appl. No.: 18/947,412

(22) Filed: Nov. 14, 2024

(51) Int. Cl. H01L 23/48; H01L 29/06; H01L 29/417; H01L 29/423; H01L 29/66; H01L 29/775; H01L 29/786

(52) U.S. Cl. CPC H10W 20/20; H10D 30/014; H10D 30/43; H10D 30/6729; H10D 30/6735; H10D 30/6757; H10D 62/121; H10D 64/017

(57) ABSTRACT

An electrical isolation structure of a semiconductor device is removed from a back side of the semiconductor device after formation of nanostructure transistors of the semiconductor device and replaced with a through-substrate interconnect structure. The back side of the semiconductor device may be grinded down to reveal the bottom of the electrical isolation structure, and the electrical isolation structure may be removed through the back side of the semiconductor device and filled in with the through-substrate interconnect structure from the back side of the semiconductor device. Using the electrical isolation structure as a placeholder for the through-substrate interconnect structure enables the through-substrate interconnect structure to be formed from the back side of the semiconductor device in a self-aligned manner, which increases the reliability and repeatability of forming electrical connections between the back side and a front side of the semiconductor device.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are diagrams of an example implementation of a fin definition process described herein.

FIG. 2 is a diagram of an example implementation of a dummy gate formation process described herein.

FIG. 3 is a diagram of an example implementation of a source/drain recess formation process described herein.

FIGS. 4A and 4B are diagrams of an example implementation of an inner spacer formation process described herein.

FIG. 5 is a diagram of an example implementation of a source/drain region formation process described herein.

FIG. 6 is a diagram of an example implementation of an interlayer dielectric (ILD) formation process described herein.

FIGS. 7A-7N are diagrams of an example implementation of an active region isolation structure formation process described herein.

FIGS. 8A-8E are diagrams of an example implementation of a replacement gate (RPG) process described herein.

FIGS. 9A-9L are diagrams of an example implementation of a gate isolation structure formation process described herein.

FIGS. 10A-10D are diagrams of an example implementation of an interconnect layer formation process described herein.

FIGS. 11A-11H are diagrams of an example implementation of a source/drain contact formation process described herein.

FIGS. 12A-12D are diagrams of an example implementation of a through-substrate interconnect formation process described herein.

FIGS. 13A-13D are diagrams of an example implementation of a through-substrate interconnect formation process described herein.

FIGS. 14A-14D are diagrams of an example implementation of a through-substrate interconnect formation process described herein.

FIGS. 15A-15D are diagrams of an example implementation of a through-substrate interconnect formation process described herein.

FIGS. 16A-16F are diagrams of an example implementation of a gate isolation structure formation process described herein.

FIGS. 17A-17I are diagrams of an example implementation of an active region isolation structure formation process described herein.

FIGS. 18A-18L are diagrams of an example implementation of a gate isolation structure formation process described herein.

FIGS. 19A-19E are diagrams of an example implementation of a gate isolation structure formation process described herein.

FIG. 20 is a diagram of an example implementation of an interconnect layer formation process described herein.

FIG. 21 is a diagram of an example implementation of an interconnect layer formation process described herein.

FIGS. 22A-22I are diagrams of example implementations of top view layouts for through-substrate interconnect structures in a semiconductor device described herein.

FIGS. 23A-23C are diagrams of example implementations of top view layouts for through-substrate interconnect structures in a semiconductor device described herein.

FIG. 24 is a flowchart of an example process associated with forming a semiconductor device described herein.

FIG. 25 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various types of electrical isolation structures may be provided in a semiconductor to electrically isolate regions of nanostructure transistors (e.g., nanowire transistors, nanosheet transistors, gate-all-around (GAA) transistors, multi-bridge channel transistors, nanoribbon transistors, and/or other types of nanostructure transistors) of the semiconductor device.

One type of electrical isolation structure is an active region isolation structure that is formed by a continuous polysilicon on diffusion edge (CPODE) process or a continuous metal on diffusion edge (CMODE) process. An active region isolation structure is a type of electrical isolation structure that cuts through nanostructure channels between adjacent nanostructure transistors to provide electrical isolation between the active regions of the nanostructure transistors.

Another type of electrical isolation structure is a gate isolation structure that is formed by a cut metal gate (CMG) process. A gate isolation structure is a type of electrical isolation structure that cuts through a gate structure to electrically isolate the gates of adjacent nanostructure transistors.

In some implementations described herein, an electrical isolation structure (e.g., an active region isolation structure, a gate isolation structure) of a semiconductor device is removed from a back side of the semiconductor device after formation of nanostructure transistors of the semiconductor device and replaced with a through-substrate interconnect structure. The back side of the semiconductor device may be grinded down to reveal the bottom of the electrical isolation structure, and the electrical isolation structure may be removed through the back side of the semiconductor device and filled in with the through-substrate interconnect structure from the back side of the semiconductor device. Using the electrical isolation structure as a placeholder for the through-substrate interconnect structure enables the through-substrate interconnect structure to be formed from the back side of the semiconductor device in a self-aligned manner, which increases the reliability and repeatability of forming electrical connections between the back side and a front side of the semiconductor device compared to other techniques that might otherwise result in misalignment (and failed electrical connection) when forming portions of a through-substrate interconnect structure from both the front side and the back side of the semiconductor device. The through-substrate interconnect structure may be electrically coupled to conductive structures on the front side and on the back side of the semiconductor device. In this way, the through-substrate interconnect structure enables signals and/or power to be routed between the front side and the back side of the semiconductor device.

The processes and techniques described herein may be used to realize a combination of MEOL/FEOL transistor patterning processes (CPODE or CMODE) and gate patterning processes (CPO or CMG). CMG/CPO may be used as an isolation to separate gate and TSV contact metal if CMG or CPO is intersecting with CPODE/CMODE. If high selective etch processes are used, substantial STI material may remain for CPODE or CMODE, and substantial ILD and STI material may remain for CPO or CMG, which can be observed in the TSV contact structures. If low selective etch processes is used, no STI and ILD will be obtained in TSV contact structures. Moreover, to avoid layout depend effects, the transistors around TSV are sometimes disabled, which is also implemented by disconnecting the transistor channels using PODE, CPODE, CMODE, or avoid EPI growth by lithography patterning in EPI loop.

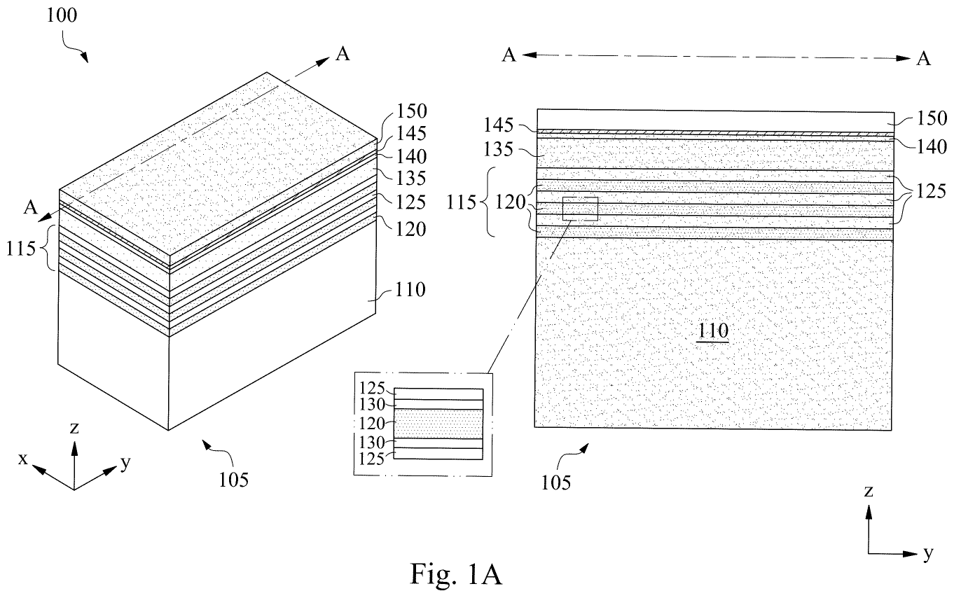

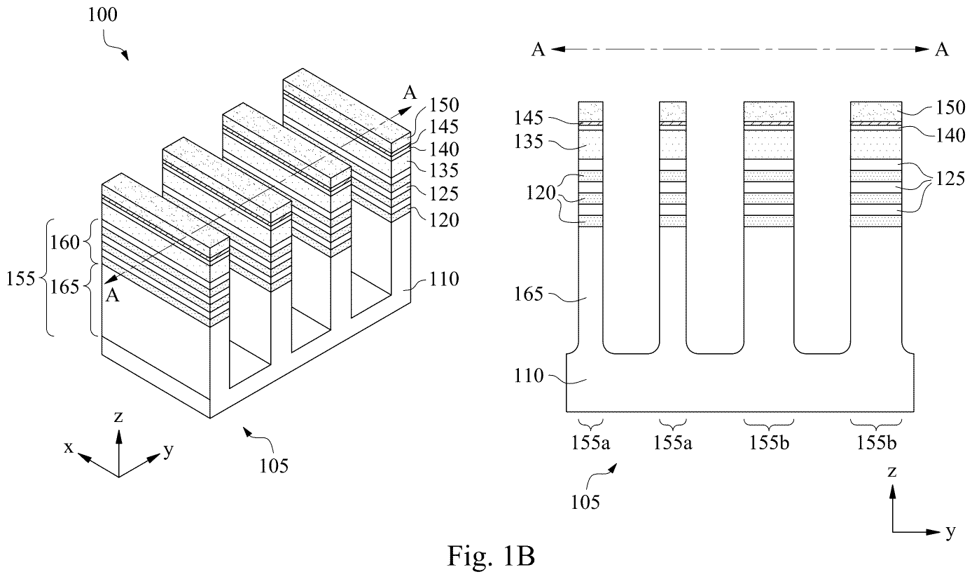

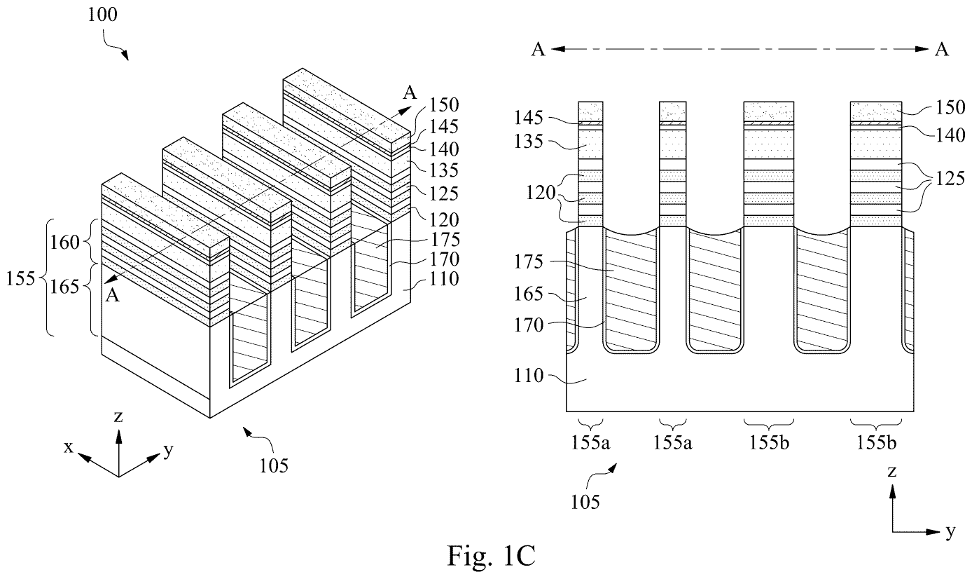

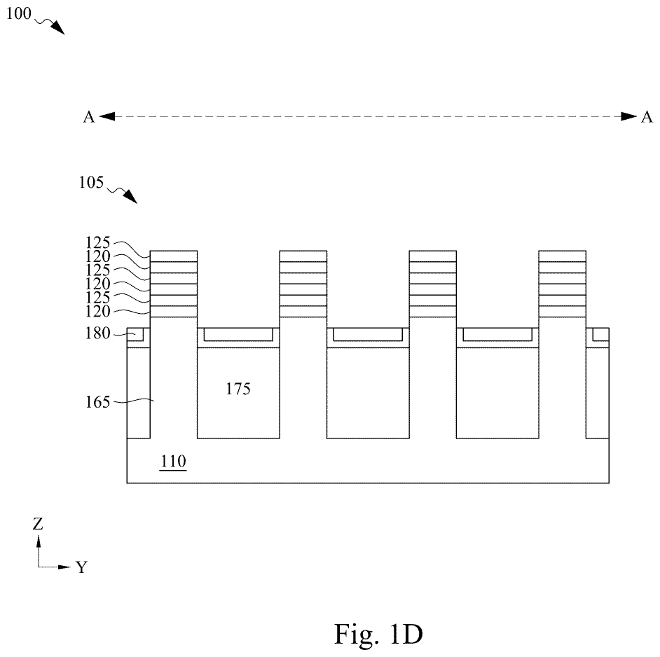

FIGS. 1A-1D are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1D each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique.

Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

As shown in a close-up view in FIG. 1A of a portion of the layer stack 115, intermixing between two or more nanostructure layers in the layer stack 115 may occur. For example, intermixing may occur between a sacrificial nanostructure layer 120 and a vertically adjacent nanostructure channel layer 125, resulting in formation of intermixing layers 130. The intermixing may result in diffusion of silicon (Si) and/or germanium (Ge) between the sacrificial nanostructure layer 120 and the nanostructure channel layer 125.

One or more masking layers may be formed (e.g., using one or more deposition tools) on the layer stack 115. The masking layer(s) may include a hard mask (HM) layer 135, a capping layer 140, an oxide layer 145, and/or a nitride layer 150. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 155 that extend above the semiconductor substrate 110. The fin structures 155 may extend in an x-direction in the semiconductor device 105 and may be arranged in a y-direction in the semiconductor device 105. A fin structure 155 includes a portion 160 of the layer stack 115 over and/or on a fin portion 165 above the semiconductor substrate 110. The fin structures 155 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 155 may be formed to have different widths for different types of nanostructure transistors. As an example, a first subset of fin structures 155a may be formed for p-type nanostructure transistors (e.g., p-type metal oxide semiconductor (PMOS) nanostructure transistors), and a second subset of fin structures 155b may be formed for n-type nanostructure transistors (e.g., n-type metal oxide semiconductor (NMOS) nanostructure transistors). As another example, a first subset of fin structures 155a may be formed for nanostructure transistors that are configured to operate at lower voltages, and a second subset of fin structures 155b may be formed for nanostructure transistors that are configured to operate at higher voltages.

As shown in FIG. 1C, a liner 170 and STI regions 175 are formed between adjacent fin portions 165 of the fin structures 155. The liner 170 and the STI regions 175 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner 170 (e.g., using ALD or another conformal deposition technique), and may deposit a dielectric layer (e.g., using CVD, PVD, a ALD, and/or another suitable deposition technique) on the liner 170 such that the dielectric layer fully fills in the spaces between the fin structures 155 and extends above the tops of the fin structures 155. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 150. The nitride layer 150 functions as a CMP stop layer in the planarization operation. An etch tool may be used to then etch the dielectric layer to form the STI regions 175 such that the top surfaces of the STI region 175 are approximately co-planar with or below the bottom-most sacrificial nanostructure layer 120.

FIG. 1D illustrates an alternative implementation in which a capping layer 180 is included over the STI regions 175. The capping layer 180 may be included to protect the STI regions 175 in subsequent processes described herein. The capping layer 180 may include a nitride-containing material (e.g., a silicon nitride, a silicon oxynitride, a silicon carbide, a silicon carbonitride, a silicon oxycarbonitride), and may be deposited by CVD, plasma-enhanced CVD, ALD, and/or another suitable deposition process. In some implementations, the capping layer 180 may be deposited as a blanket layer that is etched to define the capping layer 180 from the blanket layer.

As indicated above, FIGS. 1A-1D are provided as an example. Other examples may differ from what is described with regard to FIGS. 1A-1D.

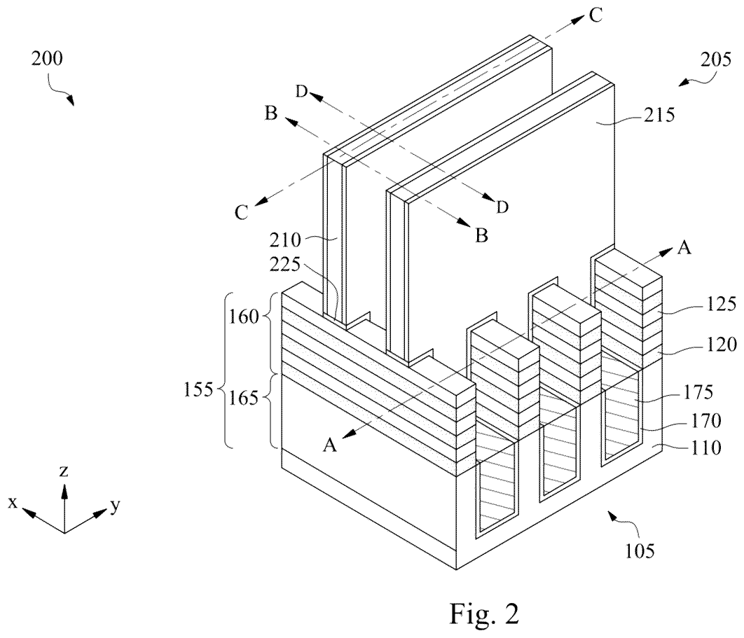

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1D.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 155 and portions of the STI regions 175. The dummy gate structures 205 extend in the x-direction and are arranged in the y-direction such that the dummy gate structures 205 are approximately perpendicular to the fin structures 155. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 155.

A dummy gate structure 205 may include a gate electrode layer 210. In some implementations, a dummy gate structure 205 may include spacer layers 215 on opposing sides of the gate electrode layer 210 (or the spacer layers 215 may be separate from the dummy gate structure 205) and/or a gate dielectric layer 220 (or the gate dielectric layer 220 may be separate from the dummy gate structure 205) under the gate electrode layer 210. The gate electrode layer 210 includes polycrystalline silicon (polysilicon or PO) or another material. The spacer layers 215 include a silicon oxycarbide (SiOC), a nitrogen free SiOC, or another suitable material. The gate dielectric layer 220 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an y-z plane (referred to as an x-cut) across the fin structures 155 in the source/drain areas of the semiconductor device 105. Cross-section B-B is in an x-z plane (referred to as a y-cut) perpendicular to the cross-section A-A, and is across the dummy gate structures 205 and along an underlying fin structure 155. Cross-section C-C is in the y-z plane (referred to as an x-cut) parallel to the cross-section A-A and perpendicular to the cross-section B-B, and is along a dummy gate structure 205. Cross-section D-D is in a x-z plane (referred to as a y-cut) parallel to the cross-section B-B, and is across the dummy gate structures 205 and along an underlying STI region 175. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

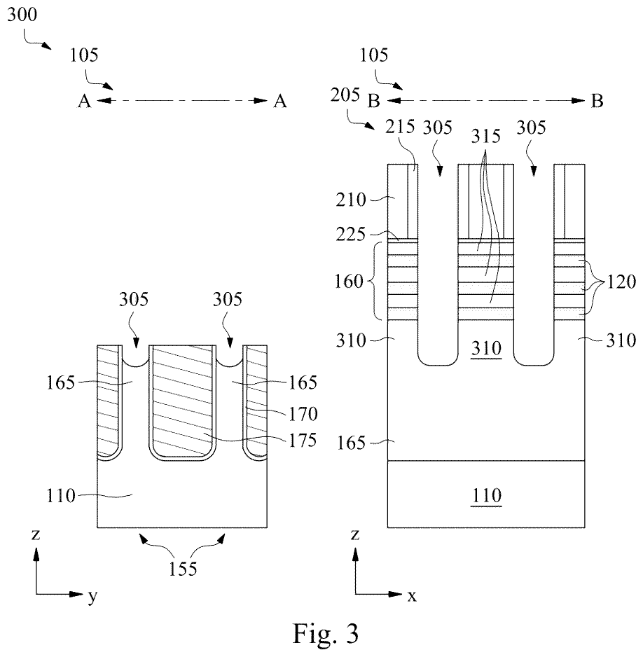

FIG. 3 is a diagram of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 160 of a fin structure 155 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 165 of the fin structure 155. This results in formation of mesa regions 310 in the fin structure 155. The sidewalls of the portions of each source/drain recess 305 below the layer stack 115 correspond to sidewalls of mesa regions 310. A mesa region 310 (also referred to as pedestals) refers to a region of the fin portion 165 of the fin structure 155 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

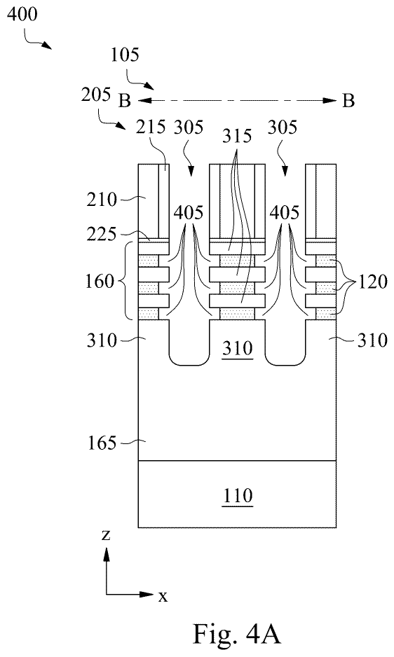

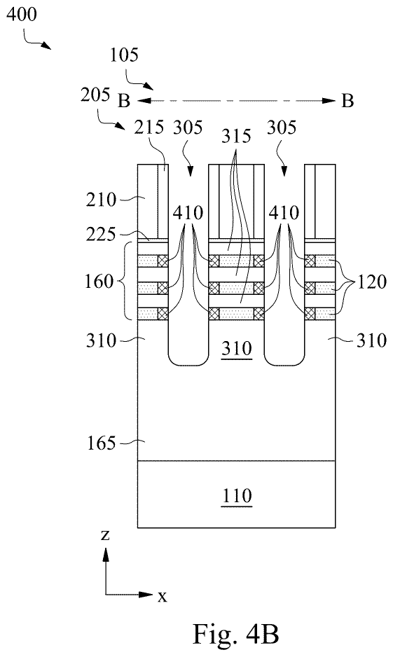

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are each illustrated from the perspective of the cross-sectional plane B-B in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in one or more first etch operations, thereby forming cavities 405 between the ends of the sacrificial nanostructure layers 120 that are exposed in the source/drain recesses 305. In particular, an etch tool may be used to laterally etch the ends of the sacrificial nanostructure layers 120 under the dummy gate structures 205 through the source/drain recesses 305 to form the cavities 405 between ends of the nanostructure channels 315.

In implementations where the sacrificial nanostructure layers 120 are silicon germanium (SiGe) and the nanostructure channels 315 are silicon (Si), the sacrificial nanostructure layers 120 are etched in the one or more first etch operations using a wet etchant such as a mixed solution including hydrogen peroxide (H₂O₂), acetic acid (CH₃COOH), and/or hydrogen fluoride (HF), followed by cleaning with water (H₂O). The mixed solution and the water may be provided into the source/drain recesses 305 to etch the sacrificial nanostructure layers 120 in the source/drain recesses 305. In some implementations, the etching by the mixed solution and cleaning by water is repeated for a plurality of cycles to form the cavities 405.

As shown in FIG. 4B, inner spacers 410 are formed in the cavities 405 between the ends of vertically adjacent nanostructure channels 315 in the source/drain recesses 305. The inner spacers 410 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410 in the cavities 405. In some implementations, the etch operation may result in the surfaces of the inner spacers 410 facing the source/drain recesses 305 being curved or recessed. In some implementations, the surfaces of the inner spacers 410 facing the source/drain recesses 305 are approximately flat such that the surfaces of the inner spacers 410 and the surfaces of the ends of the nanostructure channels 315 are approximately even and flush.

As indicated above, FIGS. 4A and 4B provided as an example. Other examples may differ from what is described with regard to FIGS. 4A and 4B.

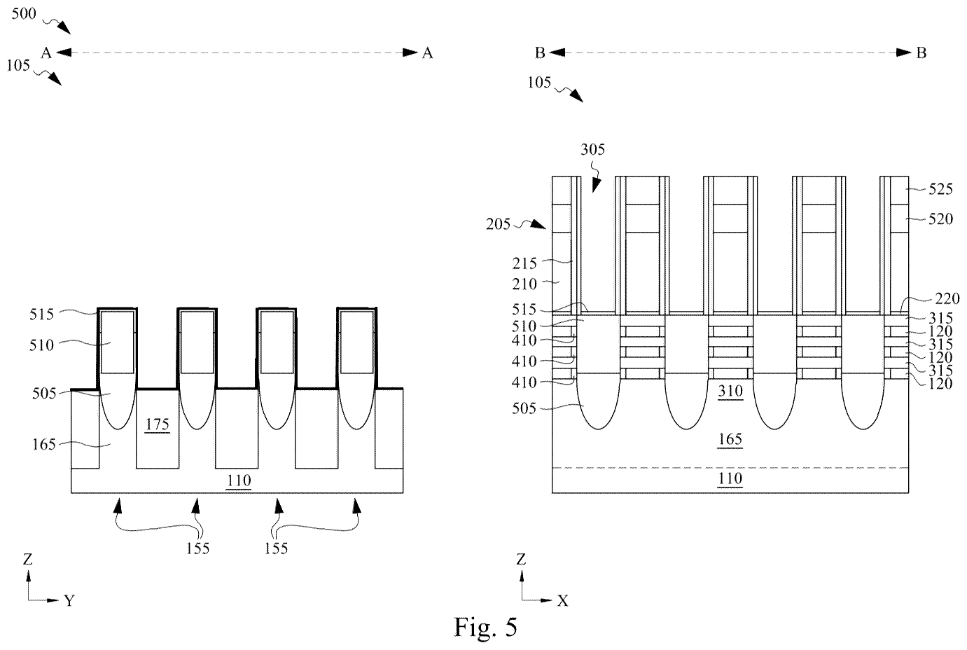

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of the source/drain recess 305, and a deposition tool may deposit a source/drain region 510 on the buffer region 505 in the source/drain recess 305. In some implementations, a deposition tool is used to deposit a capping layer 515 on the source/drain regions 510 in the source/drain recess 305.

A buffer region 505 may include silicon (Si), silicon doped with boron (Si:B) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

“Source/drain region” may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as a shielding layer to reduce short channel effects in the semiconductor device 105 and to reduce dopant extrusion or migration into the nanostructure channels 315. The second layer may include a highly doped silicon or highly doped silicon germanium. In some implementations, the second layer may be included to provide a compressive stress for PMOS in the source/drain regions 510 to reduce boron loss.

A capping layer 515 may include silicon, silicon germanium, doped silicon, doped silicon germanium, and/or another material. The capping layer 515 may be included to reduce dopant diffusion and to protect an underlying source/drain region 510 in semiconductor processing operations for the semiconductor device 105 prior to contact formation. Moreover, the capping layer 515 may contribute to metal-semiconductor (e.g., silicide) alloy formation.

As further shown in FIG. 5, in some implementations, one or more hard mask layers 520, 525 may be included over the dummy gate structures 205. In some implementations, the hard mask layers 520, 525 may be used to define the dummy gate structures 205.

As indicated above, FIG. 5 is provided as an example. Other examples may differ from what is described with regard to FIG. 5.

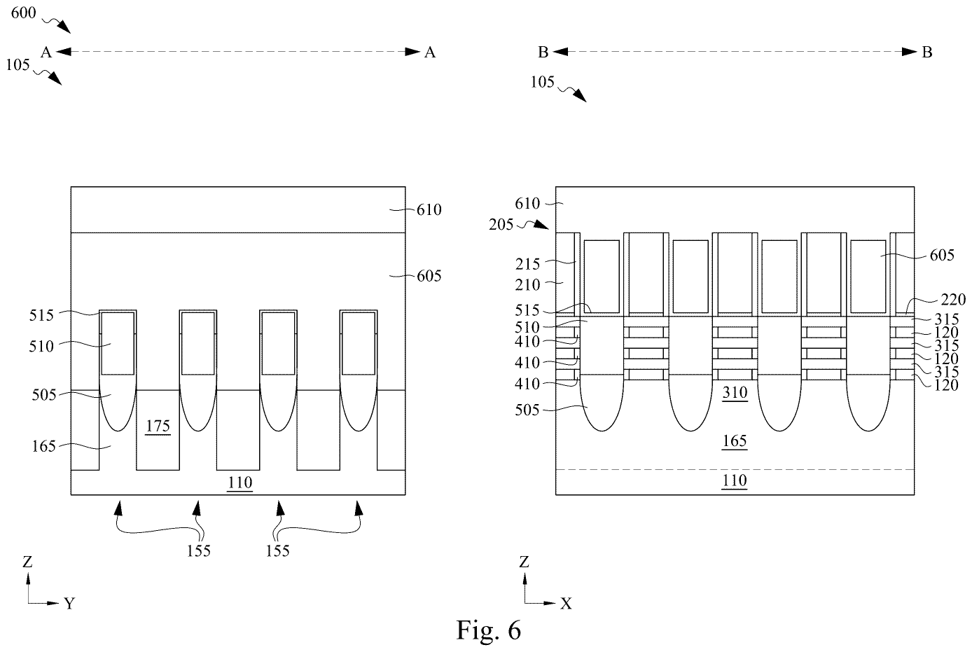

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 600 are performed after the processes described in connection with FIGS. 1A-5.

As shown in the cross-sectional plane A-A and the cross-sectional plane B-B in FIG. 6, a ILD layer 605 is formed over the source/drain regions 510. The ILD layer 605 fills in areas between the dummy gate structures 205. The ILD layer 605 is formed to reduce the likelihood of and/or prevent damage to the source/drain regions 510 during a replacement gate process to replace the dummy gate structures 205. The ILD layer 605 may be referred to as an ILD zero (ILDO) layer or another ILD layer.

In some implementations, a contact etch stop layer (CESL) is conformally deposited (e.g., by a deposition tool) over the source/drain regions 510 prior to formation of the ILD layer 605. Alternatively, the capping layer 515 may be a CESL. The ILD layer 605 is then formed on the CESL. The CESL may provide a mechanism to stop an etch process when forming contacts or vias for the source/drain regions 510. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As further shown in FIG. 6, a hard mask layer 610 may be formed over and/or on the ILD layer 605, and/or over and/or on the gate electrode layers 210 of the dummy gate structures 205. The hard mask layer 610 includes one or more layers such as an oxide layer (e.g., a pad oxide layer that may include silicon dioxide (SiO₂) or another material) and/or a nitride layer (e.g., a pad nitride layer that may include a silicon nitride such as Si₃N₄ or another material) formed over the oxide layer. The hard mask layer 610 may be deposited using a deposition process, such as ALD, CVD, or another deposition technique.

As indicated above, FIG. 6 is provided as an example. Other examples may differ from what is described with regard to FIG. 6.

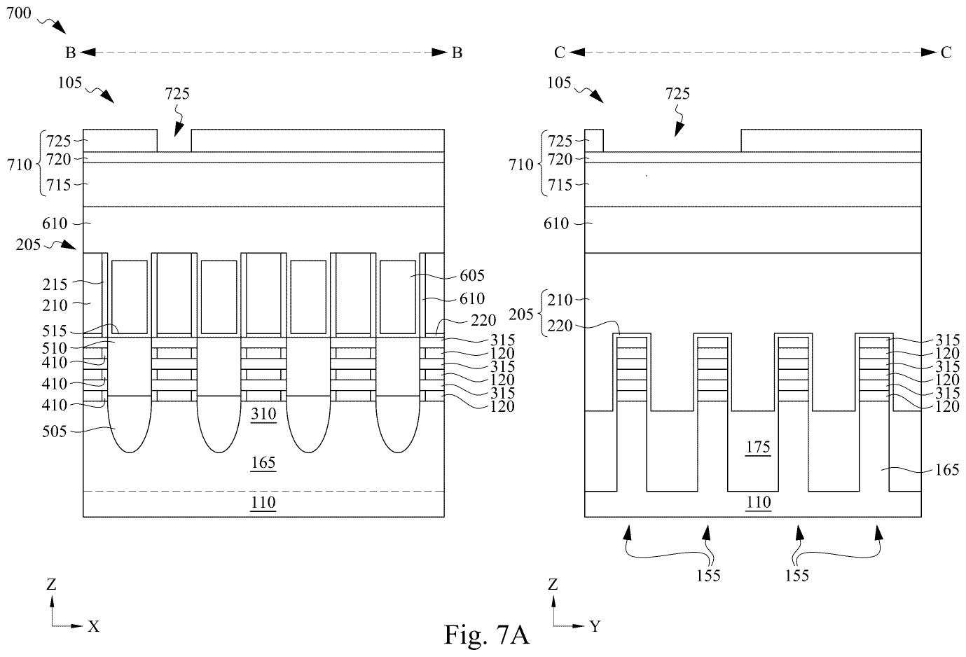

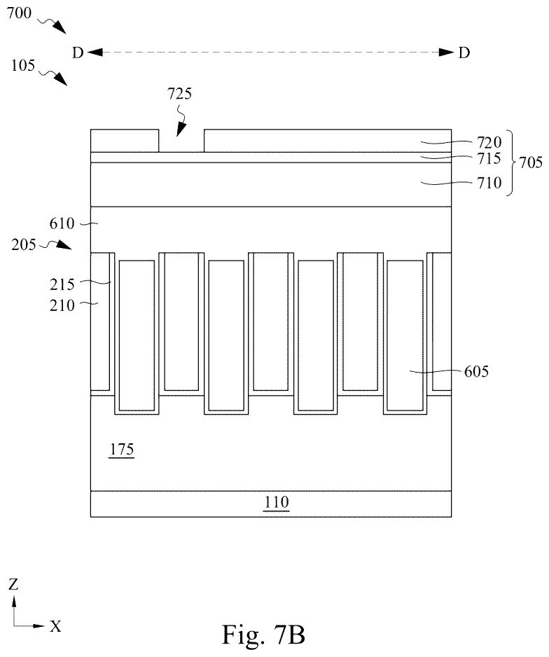

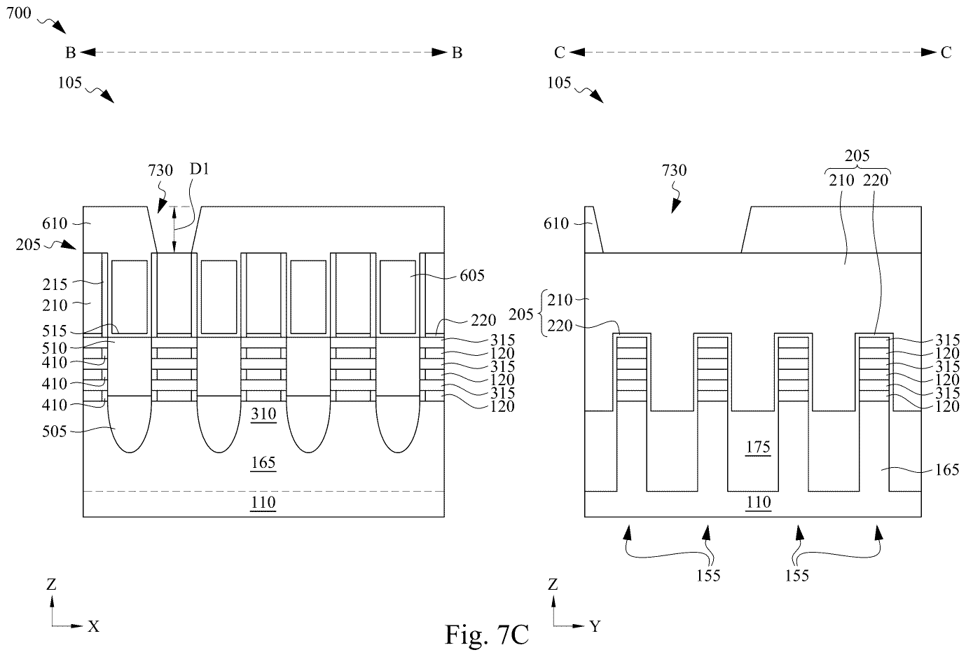

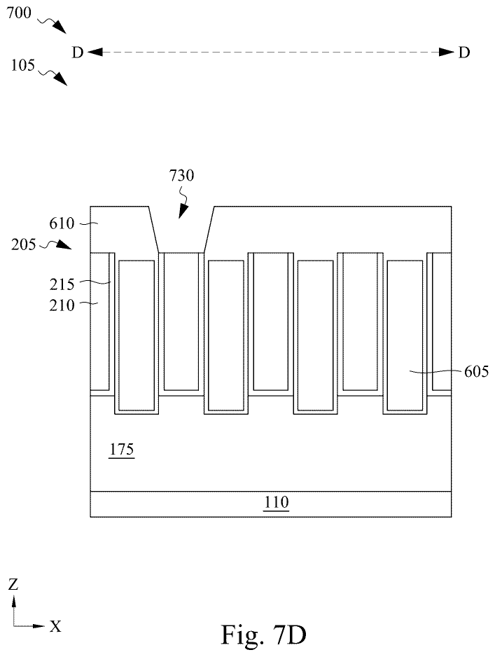

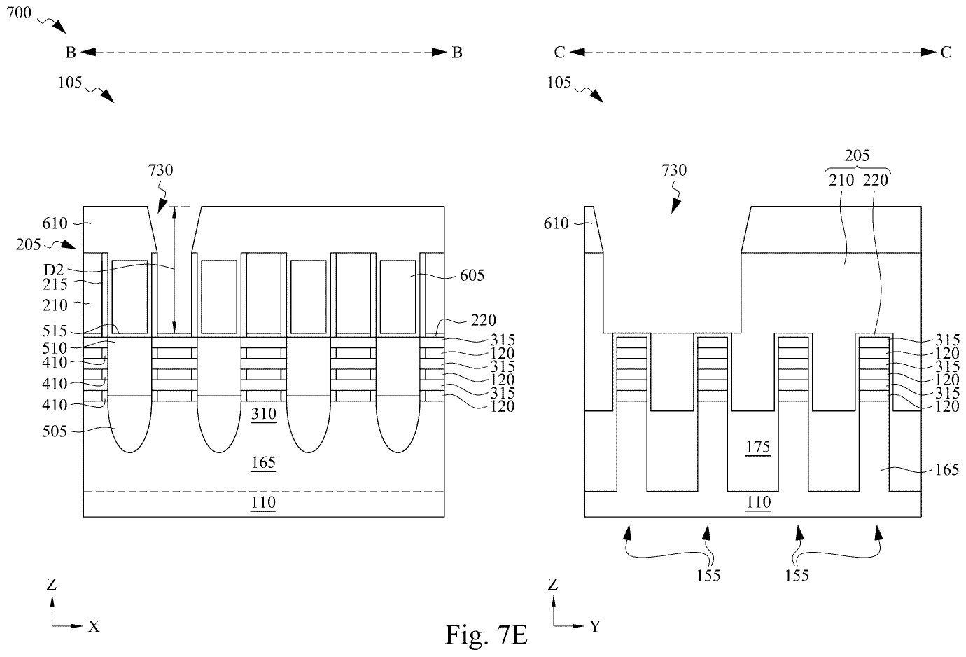

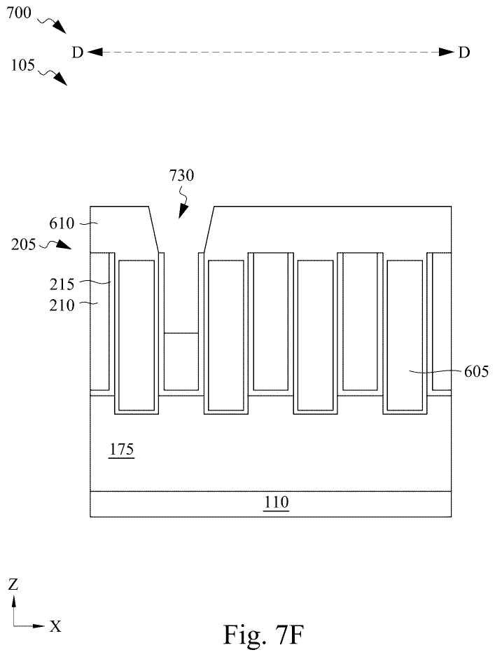

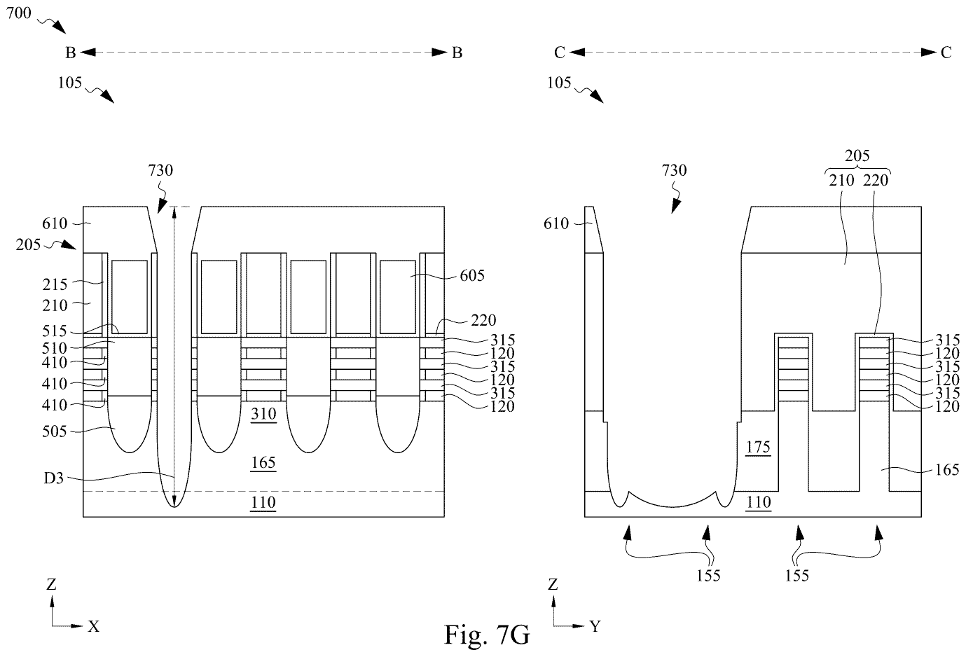

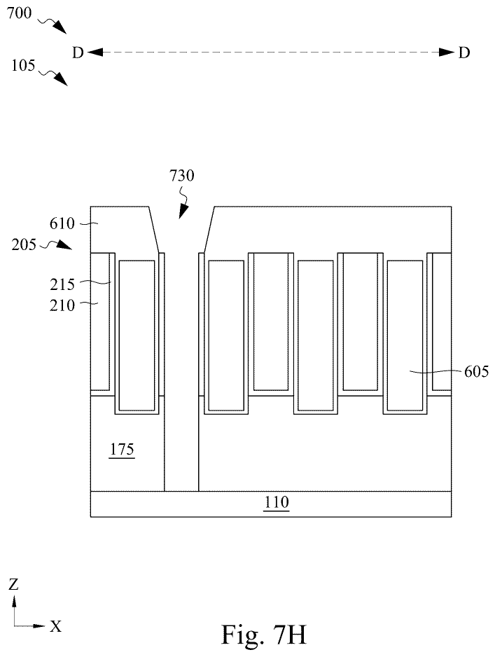

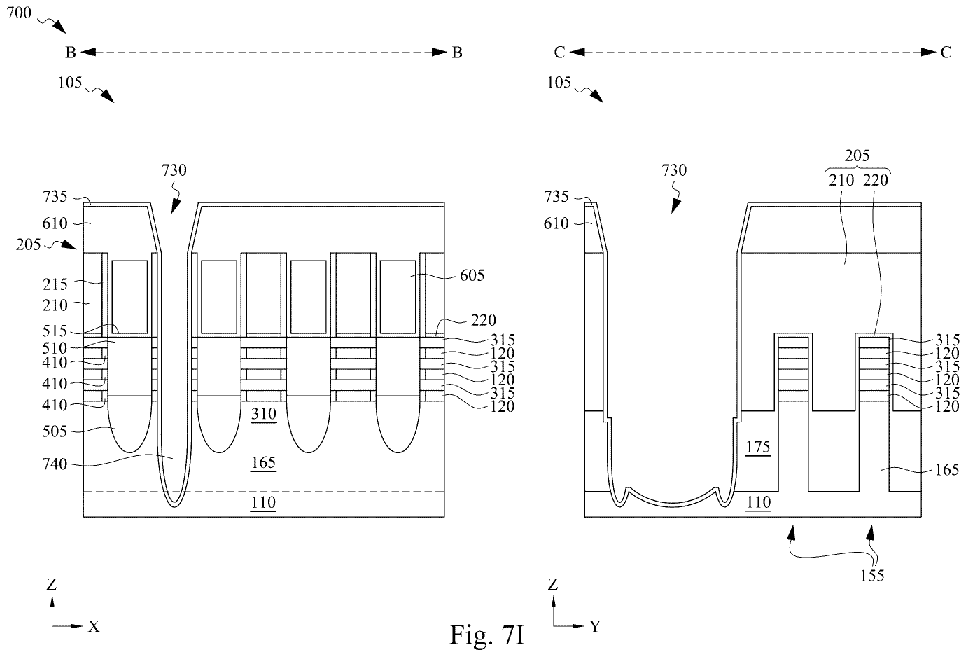

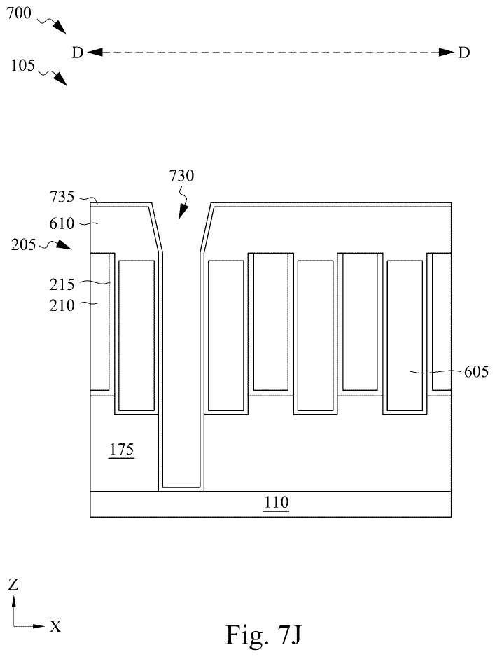

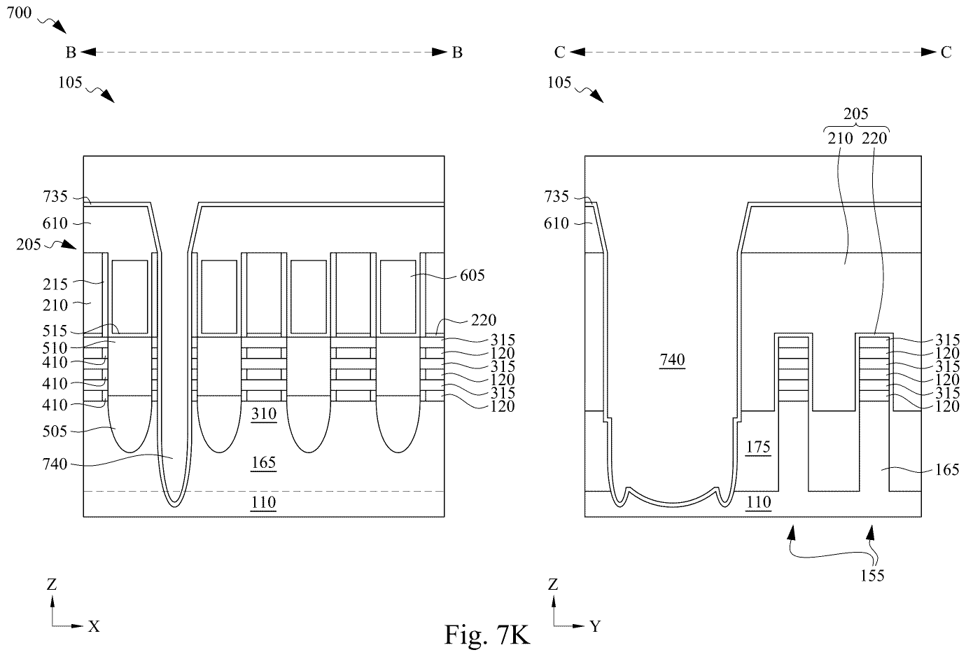

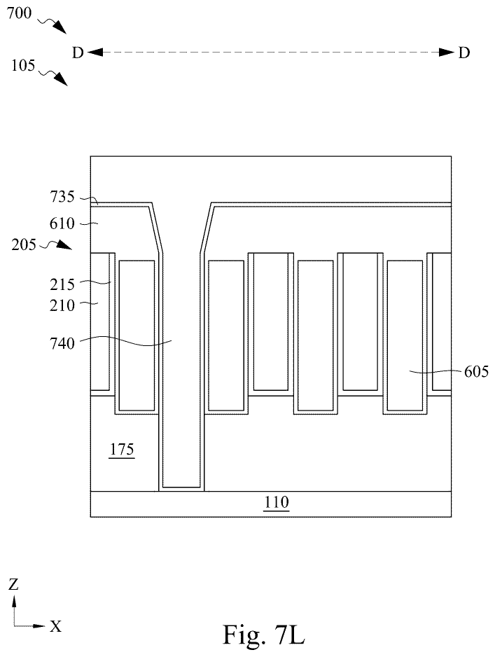

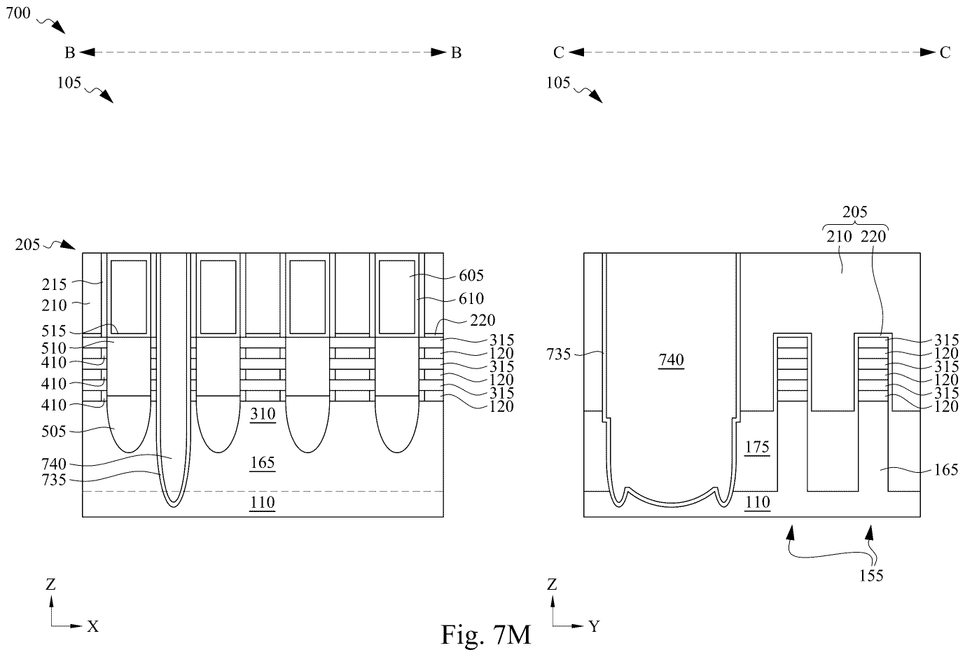

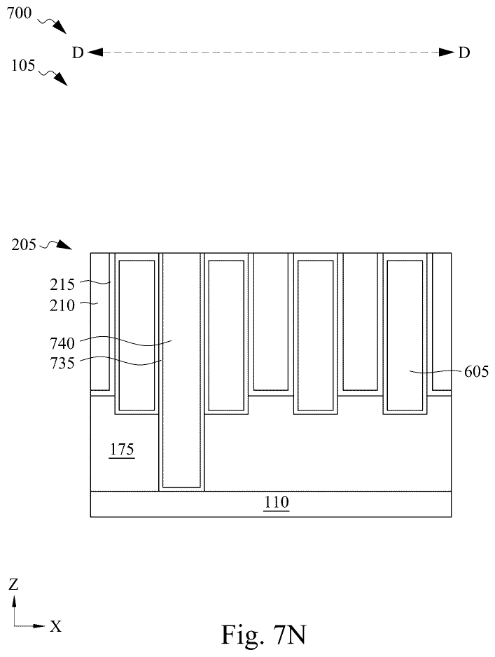

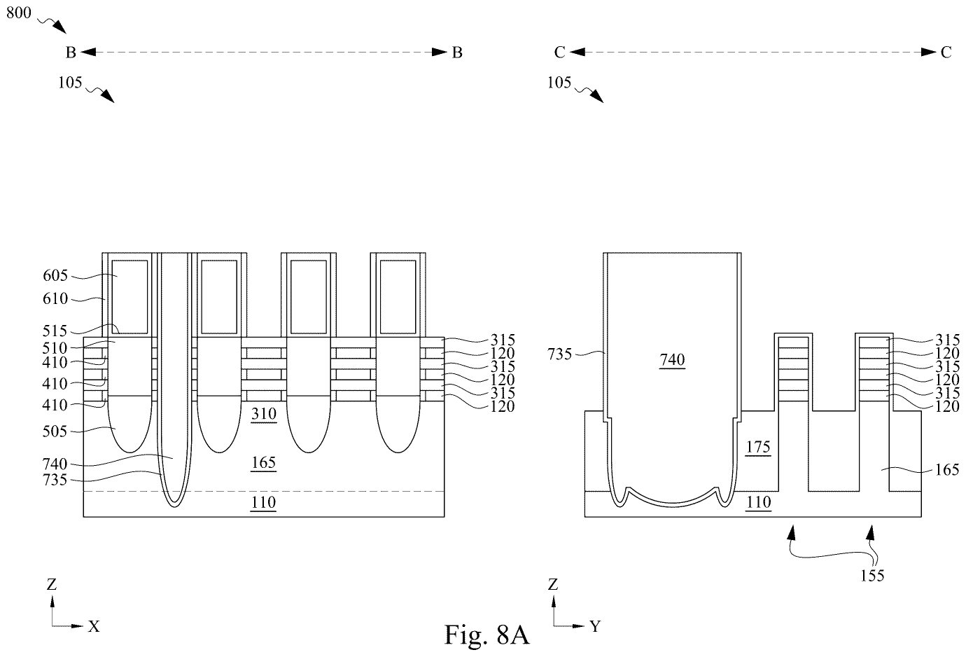

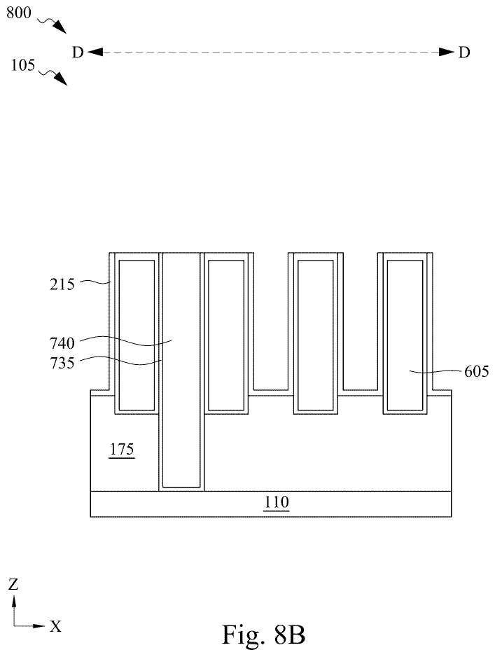

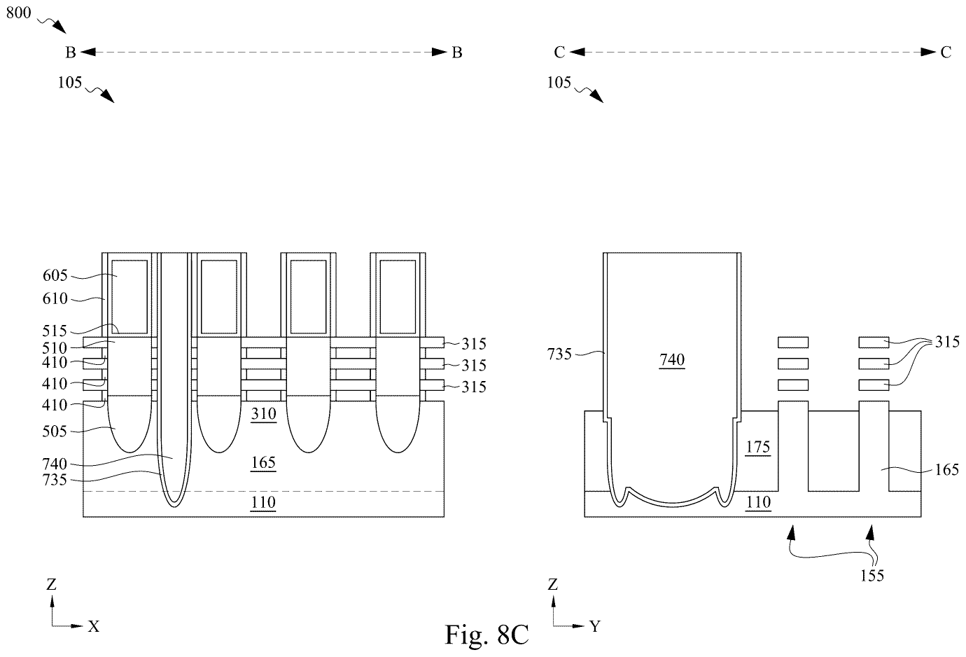

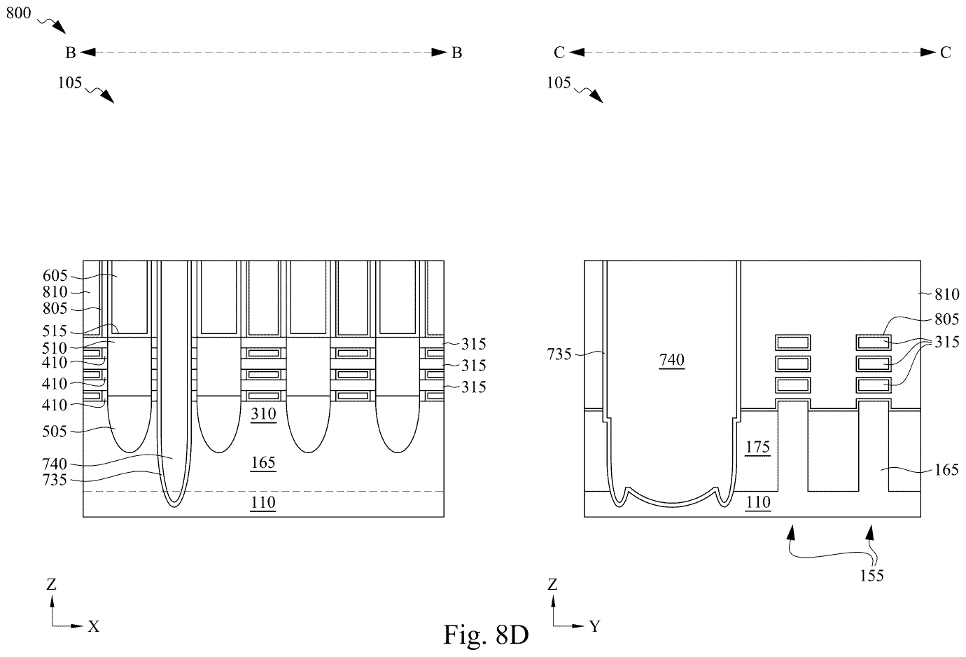

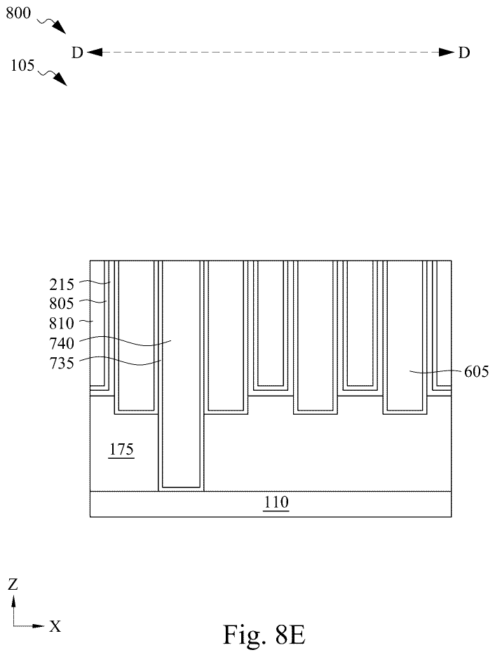

FIGS. 7A-7N are diagrams of an example implementation 700 of an active region isolation structure formation process described herein. The example implementation 700 includes an example of forming an active region isolation structure (e.g., a CPODE structure) in the semiconductor device 105 prior to the replacement gate process (which is described in connection with FIGS. 8A-8E) to replace the dummy gate structures 205 with replacement gate structures (e.g., metal gate structures) of the semiconductor device 105. Therefore, the example implementation 700 may be referred to as a front end of line (FEOL) CPODE process. The active region isolation structure may be formed along a dummy gate structure 205 to create a region of electrical isolation that extends across one or more stacks of nanostructure channels 315 under the dummy gate structure 205. Thus, the active region isolation structure enables underlying fin structures 155 to be separated into multiple electrically isolated fin structures 155.

FIGS. 7A-7N are illustrated from a plurality of perspectives illustrated in FIG. 2, including the perspective of the cross-sectional plane B-B in FIG. 2, the perspective of the cross-sectional plane C-C in FIG. 2, and/or the perspective of the cross-sectional plane D-D in FIG. 2. In some implementations, the operations described in connection with the example implementation 700 are performed after the operations described in connection with FIGS. 1A-6.

As shown in FIGS. 7A and 7B, a patterning stack 705 may be formed over and/or on the hard mask layer 610. The patterning stack 705 may be used to pattern the hard mask layer 610 for forming an active region isolation recess through the dummy gate structure 205. The patterning stack 705 may include one or more masking layers, such as a bottom layer 710, a middle layer 715, and a top layer 720. The bottom layer 710 may include a carbon-containing material and/or another suitable material. The middle layer 715 may include an oxide-containing material and/or another suitable material. The top layer 720 may include a photoresist layer that is used to transfer a pattern 725 to the bottom layer 710 and middle layer 715. The different materials of the bottom layer 710 and middle layer 715 provide etch selectivity between the bottom layer 710 and middle layer 715, which enables the aspect ratio of the pattern 725 to be tightly controlled.

A deposition tool may be used to deposit the bottom layer 710 and the middle layer 715 using a PVD technique, an ALD technique, a CVD technique, an oxidation technique, and/or another suitable deposition technique. In some implementations, a planarization tool may be used to planarize the bottom layer 710 and/or the middle layer 715 after the bottom layer 710 and/or the middle layer 715 are deposited. A deposition tool may be used to deposit the top layer 720 using a spin coating technique and/or another suitable deposition technique.

As shown in FIGS. 7C and 7D, the pattern 725 may be used to form an active region isolation recess 730 (e.g., a CPODE recess) in the hard mask layer 610 to a first depth (indicated in FIG. 7C as a dimension D1). An etch tool may be used to etch the middle layer 715 and the bottom layer 710 to transfer the pattern 725 to the middle layer 715 and the bottom layer 710, and may be used to etch the hard mask layer 610 based on the pattern 725 in the bottom layer 710 and in the middle layer 715 to form the active region isolation recess 730 in the hard mask layer 610. In some implementations, the etch operation includes dry etch (e.g., a plasma etch operation). In some implementations, the etch operation includes another type of etch operation such as a wet chemical etch operation. The etch may stop on the dummy gate structure 205.

As further shown in FIGS. 7C and 7D, a photoresist removal tool may be used to remove the remaining portions of the patterning stack 705 (e.g., using a chemical stripper, plasma ashing, and/or another technique) after the active region isolation recess 730 is formed in the hard mask layer 610. In some implementations, a wet cleaning operation may be performed after the active region isolation recess 730 is formed.

As shown in FIGS. 7E and 7F, the dummy gate structure 205 may be etched to extend the active region isolation recess 730 down to a second depth (indicated in FIG. 7E as a dimension D2) corresponding to the tops of the fin structures 155. The etch may stop at the tops of the topmost nanostructure channels 315 of the fin structures 155.

As shown in FIGS. 7G and 7H, the active region isolation recess 730 is extended through the dummy gate structure 205, through portions of the underlying STI regions 175 under the dummy gate structure 205, and into the semiconductor substrate 110 to a third depth (indicated in FIG. 7G as a dimension D3). Moreover, one or more of the fin structures 155 (including the fin portions 165, the nanostructure channels 315, and the sacrificial nanostructure layers 120) under the active region isolation recess 730 formed in the hard mask layer 610, are removed. In some implementations, the etch operation includes another type of etch operation such as a wet chemical etch operation. The etch may stop on the dummy gate structure 205.

In some implementations, a high density plasma is used in an etch tool to remove the fin structures 155 (including the fin portions 165, the nanostructure channels 315, and the sacrificial nanostructure layers 120). The plasma may be a hydrogen bromide (HBr) based plasma etchant and/or another plasma based etchant with oxygen (O₂) and/or carbon dioxide (CO₂) added. The plasma may be generated using an inductively coupled plasma (ICP) generator, a resonant antenna plasma source driven by a radio frequency (RF) power generator, and/or another type of plasma based etch tool. A frequency of a multiple of 13.56 megahertz (MHz) (e.g., 13.56 MHz, 27 MHz) may be used for the RF power generator. The RF power generator may be operated to provide a source power that is included in a range of approximately 100 watts to approximately 2500 watts. However, other values for the range are within the scope of the present disclosure. In some implementations, a pulse plasma etch may be performed with a duty cycle that is included in a range of approximately 10% to approximately 100%. However, other values for the range are within the scope of the present disclosure. An RF bias power to a pedestal in the process chamber of the etch tool may be included in a range of approximately 10 watts to approximately 2000 watts. However, other values for the range are within the scope of the present disclosure. The process chamber of the etch tool may be operated at a pressure that is included in a range of approximately 3 milliTorr (mTorr) to approximately 150 mTorr.

However, other values for the range are within the scope of the present disclosure. The process chamber of the etch tool may be operated at a temperature that is included in a range of approximately 20 degrees Celsius to approximately 150 degrees Celsius. However, other values for the range are within the scope of the present disclosure.

In some implementations, one or more methane (CH₄)-based deposition operations may be performed to protect the hard mask layer 610 during etch operation to remove the fin structures 155 (including the fin portions 165, the nanostructure channels 315, and the sacrificial nanostructure layers 120). Passivation operations, such as silicon tetrachloride (SiCl₄) passivation and/or oxygen (O₂) passivation, may be performed to form a passivation layer to reduce the likelihood of and/or magnitude of etching of layers and/or structures other than the fin structures 155. After the passivation operations, a break-through operation utilizing tetrafluoromethane (CF₄), trifluoromethane (CHF₃), difluoromethane (CH₂F₂), and/or hexafluorobutadine (C₄F₆) may be performed to remove the passivation layer from the bottom surface of the active region isolation recess 730 to enable further etching of the active region isolation recess 730.

As shown in FIGS. 7I and 7J, a dielectric liner 735 may be formed on the sidewalls and on the bottom surface of the active region isolation recess 730. In some implementations, the dielectric liner 735 is formed along the top surface of the hard mask layer 610. The dielectric liner 735 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material. A deposition tool may be used to deposit the dielectric liner 735 using a PVD technique, an ALD technique, a CVD technique, an oxidation technique, and/or another suitable deposition technique.

As shown in FIGS. 7K and 7L, an active region isolation structure 740 may be formed in the active region isolation recess 730. In particular, the active region isolation structure 740 may be formed on the dielectric liner 735 in the active region isolation recess 730. The active region isolation recess 730 may be over-filled with the material of the active region isolation structure 740 to ensure that the active region isolation recess 730 is fully filled with the material of the active region isolation structure 740 and to minimize the formation of gaps or voids in the active region isolation structure 740.

A deposition tool may be used to deposit the active region isolation structure 740 using a PVD technique, an ALD technique, a CVD technique, an oxidation technique, and/or another suitable deposition technique. The active region isolation structure 740 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material.

As shown in FIGS. 7M and 7N, a planarization operation may be performed to planarize the semiconductor device 105 after the active region isolation recess 730 is filled in with the active region isolation structure 740. A planarization tool may be used to perform a CMP operation and/or another type of planarization operation to remove the hard mask layer 610 (except for portions of the hard mask layer 610 below the top surfaces of the ILD layer 605), to remove excess material of the dielectric liner 735, and/or to remove excess material of the active region isolation structure 740.

As indicated above, FIGS. 7A-7N are provided as an example. Other examples may differ from what is described with regard to FIGS. 7A-7N.

FIGS. 8A-8E are diagrams of an example implementation 800 of a replacement gate (RPG) process described herein. The example implementation 800 includes an example of a replacement gate process for replacing the dummy gate structures 205 with the replacement gate structures (e.g., metal gate structures) of the semiconductor device 105.

FIGS. 8A-8E are illustrated from a plurality of perspectives illustrated in FIG. 2, including the perspective of the cross-sectional plane B-B in FIG. 2, the perspective of the cross-sectional plane C-C in FIG. 2, and/or the perspective of the cross-sectional plane D-D in FIG. 2. In some implementations, the operations described in connection with the example implementation 800 are performed after the operations described in connection with FIGS. 1A-7N.

As shown in FIGS. 8A and 8B, the RPG process includes a replacement gate operation in which the dummy gate structures 205 are removed from the semiconductor device 105. The removal of the dummy gate structures 205 leaves behind openings (or recesses) in the ILD layer 605 over the source/drain regions 510. The dummy gate structures 205 may be removed in one or more etch operations. Such etch operations may include a plasma etch technique, a wet chemical etch technique, and/or another type of etch technique.

As shown in FIG. 8C, the RPG process includes a nanosheet release operation (e.g., an SiGe release operation) in which the sacrificial nanostructure layers 120 (e.g., the silicon germanium layers) are removed from between the nanostructure channels 315. This results in openings between the nanostructures channels 315 (e.g., the areas around the nanostructure channels 315). The nanostructure release operation may include using an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacers 410. The inner spacers 410 may function as etch stop layers in the etch operation to protect the source/drain regions 510 from being etched during the nanosheet release operation.

As shown in FIGS. 8D and 8E, the RPG process includes using a deposition tool to form a gate dielectric layer 805 around the nanostructure channels 315 and gate structures 810 that wrap around the nanostructure channels 315. The gate dielectric layer 805 and the gate structures 810 may be formed in the openings between the source/drain regions 510 and in the areas between nanostructure channels 315.

In some implementations, the gate dielectric layer 805 is a high-k gate dielectric layer that includes one or more high-k materials (e.g., dielectric materials having a dielectric constant greater than silicon dioxide (SiO₂—dielectric constant of approximately 3.9). Examples include lanthanum oxide (LaₓO_{y} such as La₂O₃), hafnium oxide (HfOₓ such as HfO₂), zirconium oxide (ZrOₓ such as ZrO₂), and/or aluminum oxide (AlₓO_{y} such as Al₂O₃), among other examples. Additionally and/or alternatively, silicon dioxide (SiO₂) and/or another dielectric material may be used instead of a high-k dielectric material. In some implementations, the gate dielectric layer 805 may have a thickness that is included in a range of approximately 0.5 nanometers to approximately 3 nanometers. However, other values for the range are within the scope of the present disclosure. A deposition tool may be used to deposit the gate dielectric layer 805 using a PVD technique, an ALD technique, a CVD technique, an oxidation technique, and/or another suitable deposition technique.

The gate structures 810 includes one or more electrically conductive metal materials, such as ruthenium (Ru), tungsten (W), cobalt (Co), copper (Cu), and/or molybdenum (Mo), among other examples. A deposition tool may be used to deposit the gate structures 810 using a CVD technique, a PVD technique, an ALD technique, an electroplating technique, and/or another suitable deposition technique. The gate structures 810 may be deposited in one or more deposition operations. In some implementations, a seed layer is first deposited, and the gate structures 810 is deposited on the seed layer. In some implementations, a planarization tool may be used to planarize the gate structures 810 after the gate structures 810 are deposited.

As indicated above, FIGS. 8A-8E are provided as an example. Other examples may differ from what is described with regard to FIGS. 8A-8E.

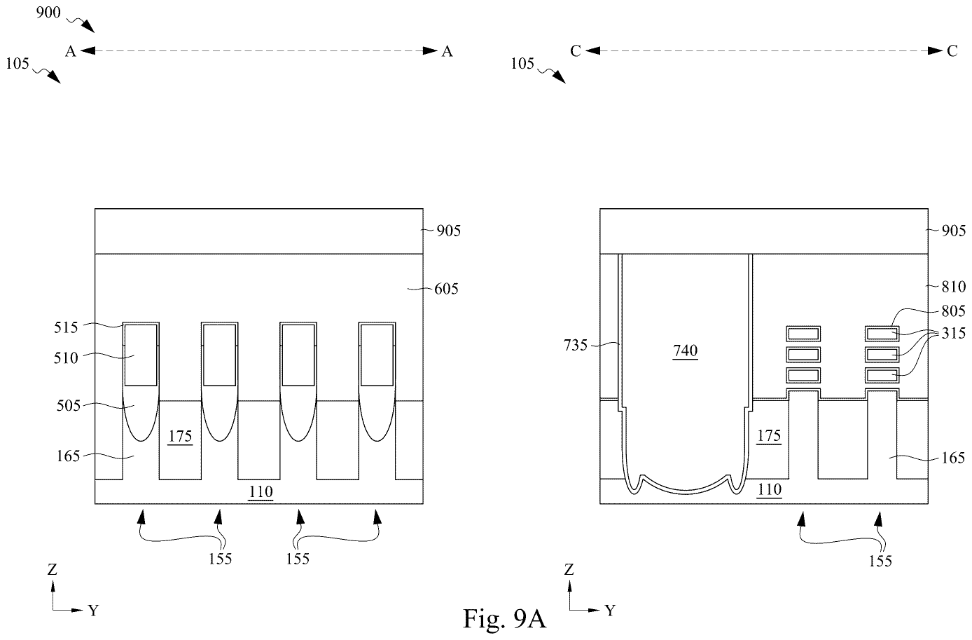

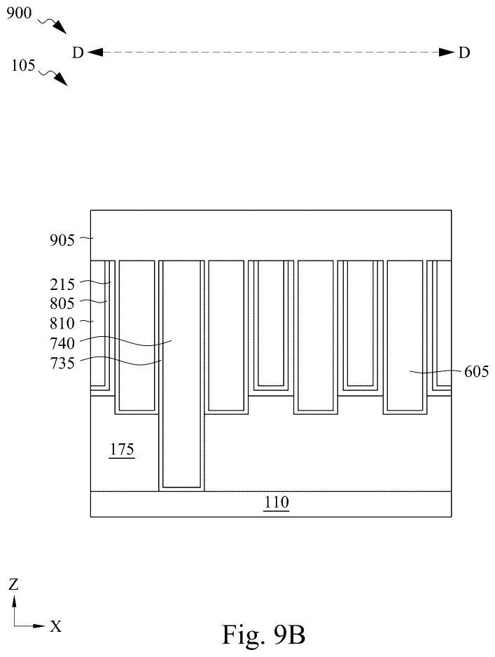

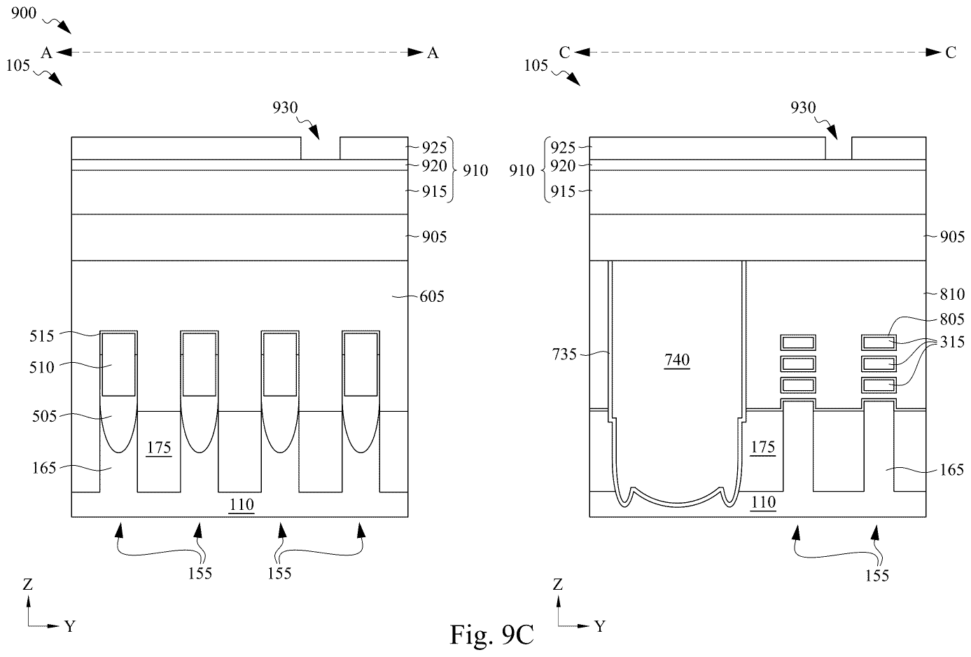

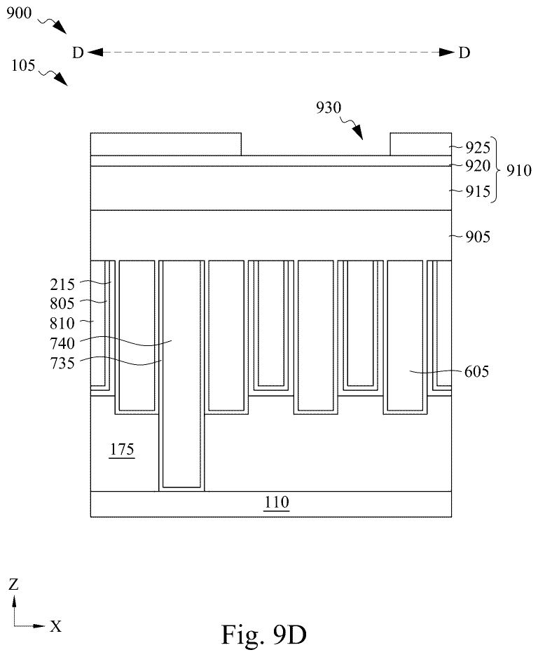

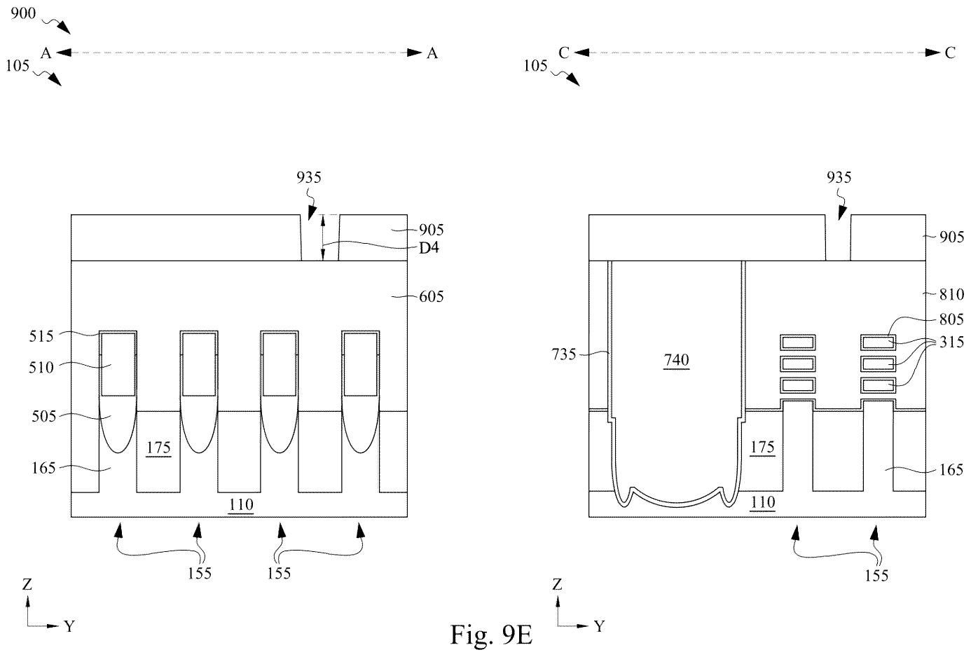

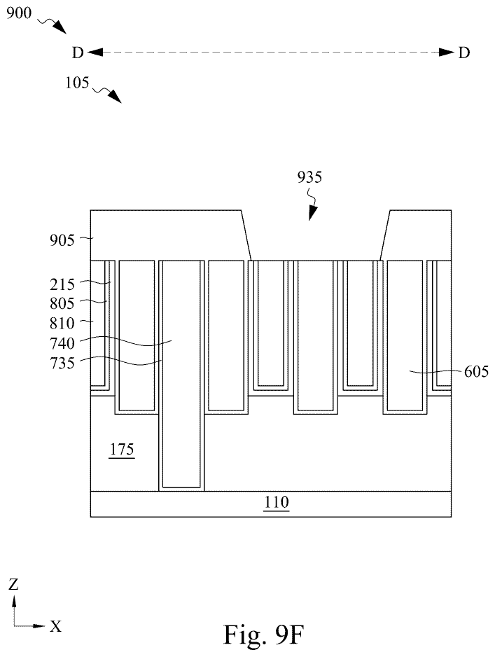

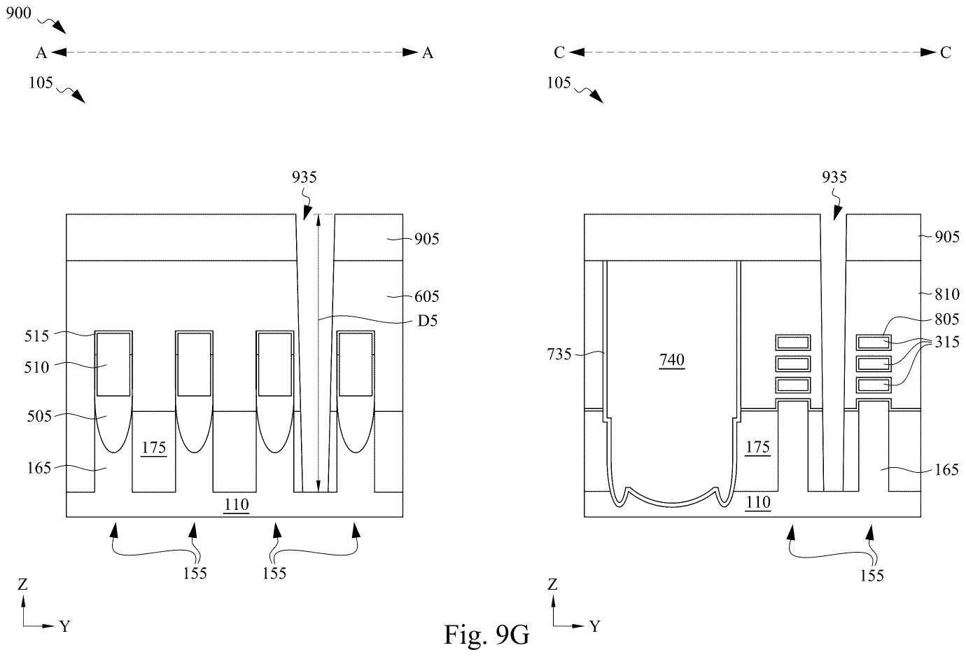

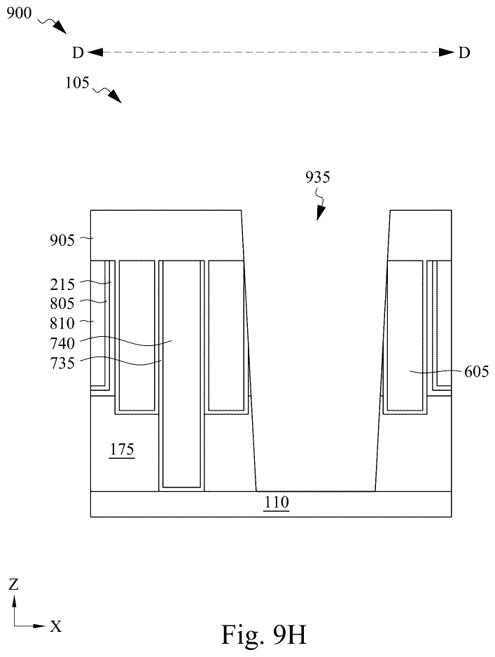

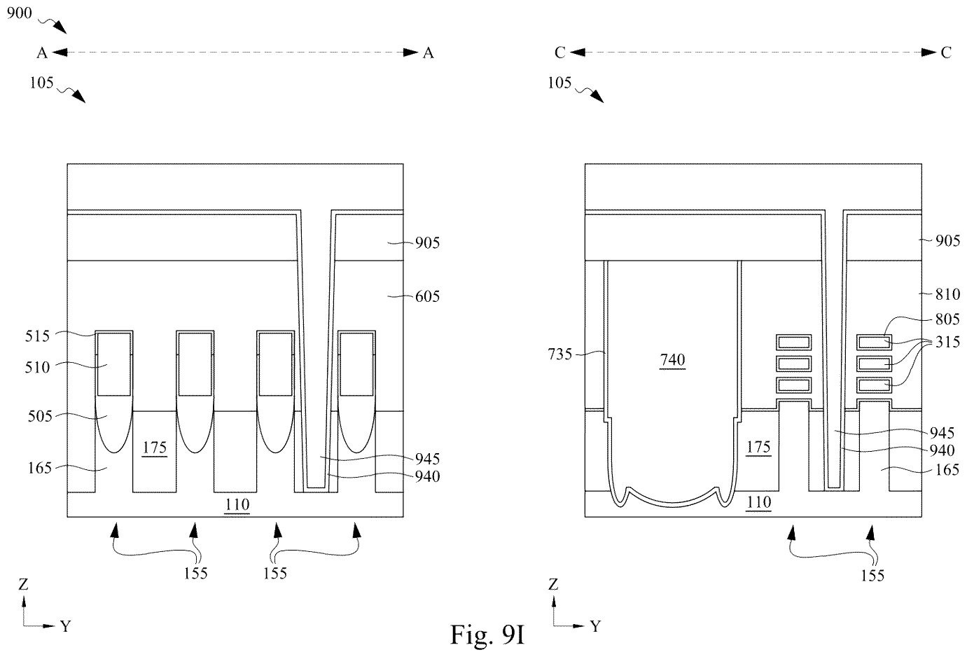

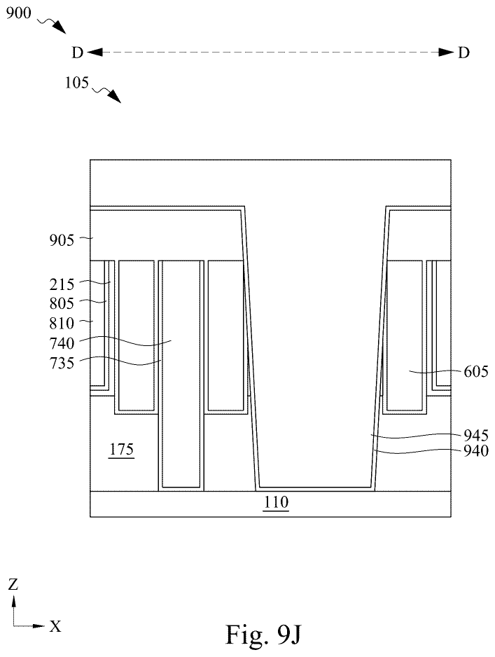

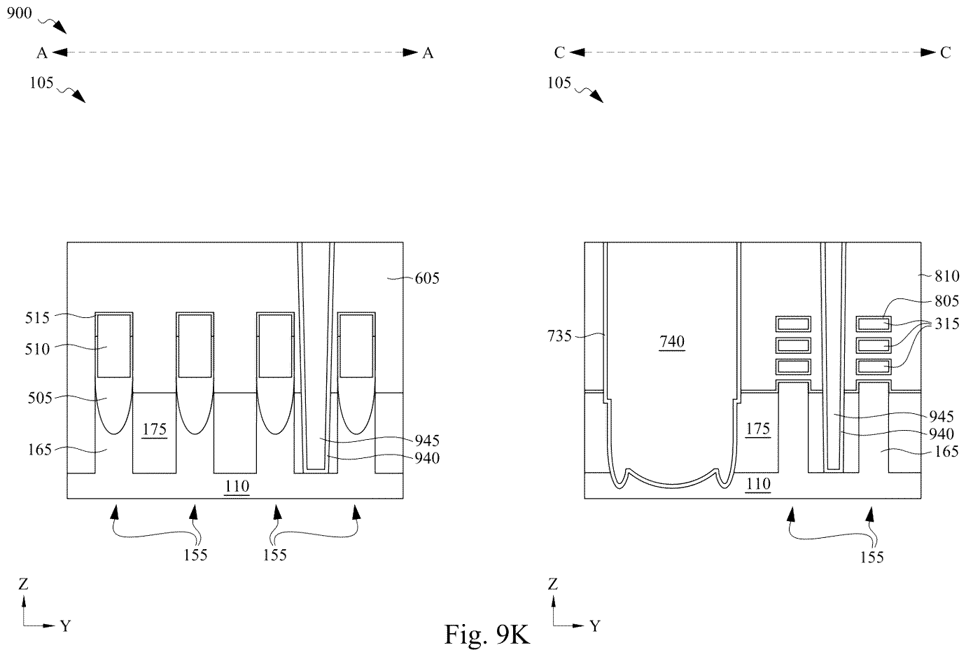

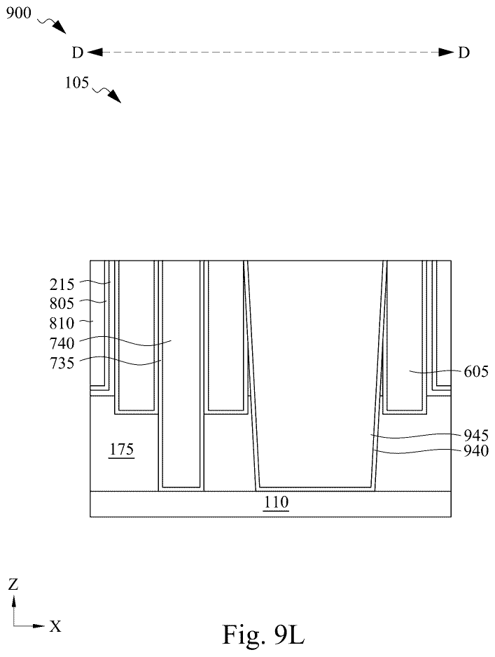

FIGS. 9A-9L are diagrams of an example implementation 900 of a gate isolation structure formation process described herein. The example implementation 900 includes an example of forming a gate isolation structure (e.g., a CMG structure) in the semiconductor device 105 after the replacement gate process described in connection with FIGS. 8A-8E and prior to a BEOL process to form an interconnect layer of the semiconductor device 105. Therefore, the example implementation 900 may be referred to as a middle end of line (MEOL) process. The gate isolation structure may be formed across one or more gate structures 810 in the x-direction and along one or more fin structures 155 to form a plurality of electrically isolated gate structures 810 in the y-direction.

FIGS. 9A-9L are illustrated from a plurality of perspectives illustrated in FIG. 2, including the perspective of the cross-sectional plane A-A in FIG. 2, the perspective of the cross-sectional plane C-C in FIG. 2, and/or the perspective of the cross-sectional plane D-D in FIG. 2. In some implementations, the operations described in connection with the example implementation 900 are performed after the operations described in connection with FIGS. 1A-8E. In these implementations, the semiconductor device 105 may include one or more active region isolation structures 740. In some implementations, the operations described in connection with the example implementation 800 shown in FIGS. 8A-8E are omitted. In these implementations, the active region isolation structures 740 are omitted from the semiconductor device 105.

As further shown in FIGS. 9A and 9B, a hard mask layer 905 may be formed over and/or on the ILD layer 605, and/or over and/or on the gate structures 810. In some implementations, the hard mask layer 905 is formed on the active region isolation structure 740. The hard mask layer 905 includes one or more layers such as an oxide layer (e.g., a pad oxide layer that may include silicon dioxide (SiO₂) or another material) and/or a nitride layer (e.g., a pad nitride layer that may include a silicon nitride such as Si₃N₄ or another material) formed over the oxide layer. The hard mask layer 905 may be deposited using a deposition process, such as ALD, CVD, or another deposition technique.

As shown in FIGS. 9C and 9D, a patterning stack 910 may be formed over and/or on the hard mask layer 905. The patterning stack 910 may be used to pattern the hard mask layer 905 for forming a gate isolation recess through a gate structure 810. The patterning stack 910 may include one or more masking layers, such as a bottom layer 915, a middle layer 920, and a top layer 925. The bottom layer 915 may include a carbon-containing material and/or another suitable material. The middle layer 920 may include an oxide-containing material and/or another suitable material. The top layer 925 may include a photoresist layer that is used to transfer a pattern 930 to the bottom layer 915 and middle layer 920. The different materials of the bottom layer 915 and middle layer 920 provide etch selectivity between the bottom layer 915 and middle layer 920, which enables the aspect ratio of the pattern 930 to be tightly controlled.

A deposition tool may be used to deposit the bottom layer 915 and the middle layer 920 using a PVD technique, an ALD technique, a CVD technique, an oxidation technique, and/or another suitable deposition technique. In some implementations, a planarization tool may be used to planarize the bottom layer 915 and/or the middle layer 920 after the bottom layer 915 and/or the middle layer 920 are deposited. A deposition tool may be used to deposit the top layer 925 using a spin coating technique and/or another suitable deposition technique. An exposure tool may be used to expose the top layer 925 to a radiation source to form the pattern 930 in the top layer 925. A developer tool may be used to develop and remove portions of the top layer 925 to expose the pattern 930.

As shown in FIGS. 9E and 9F, the pattern 930 may be used to form a gate isolation recess 935 (e.g., a CMG recess) in the hard mask layer 905 to a first depth (indicated in FIG. 9E as a dimension D4). An etch tool may be used to etch the middle layer 920 and the bottom layer 915 to transfer the pattern 930 to the middle layer 920 and the bottom layer 915, and may be used to etch the hard mask layer 905 based on the pattern 930 in the bottom layer 915 and in the middle layer 920 to form the gate isolation recess 935 in the hard mask layer 905. In some implementations, the etch operation includes dry etch (e.g., a plasma etch operation). In some implementations, the etch operation includes another type of etch operation such as a wet chemical etch operation. The etch may stop on the gate structure 810.

As further shown in FIGS. 9E and 9F, a photoresist removal tool may be used to remove the remaining portions of the patterning stack 910 (e.g., using a chemical stripper, plasma ashing, and/or another technique) after the gate isolation recess 935 is formed in the hard mask layer 905. In some implementations, a wet cleaning operation may be performed after the gate isolation recess 935 is formed.

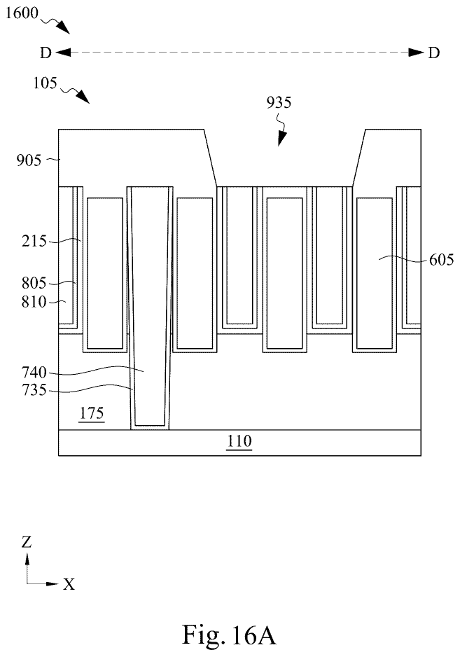

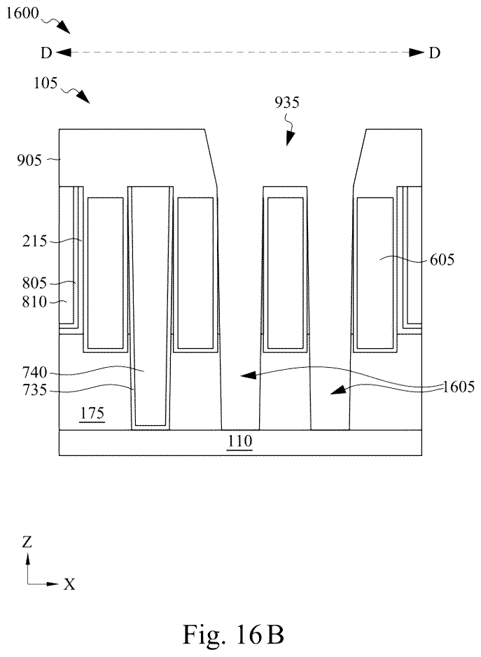

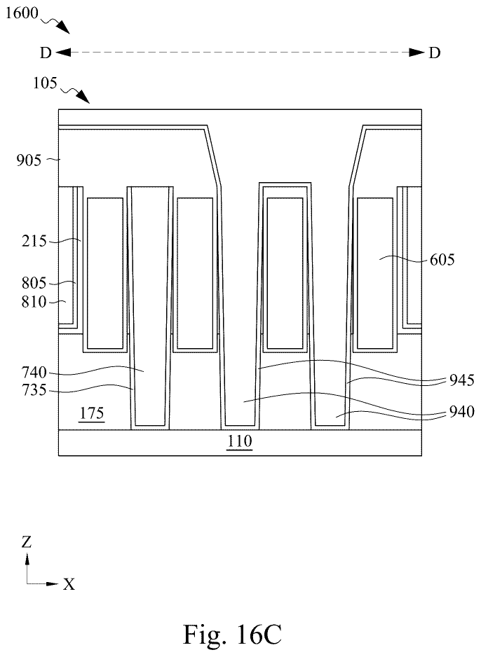

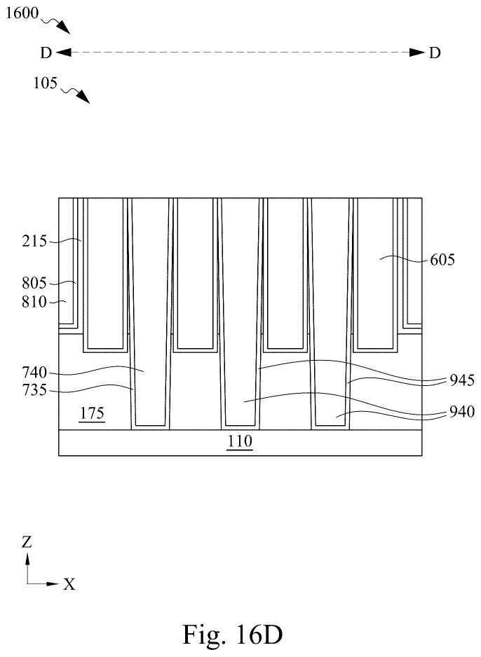

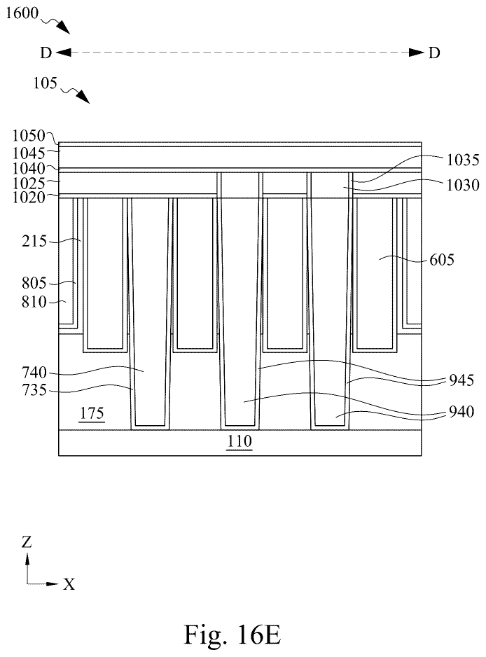

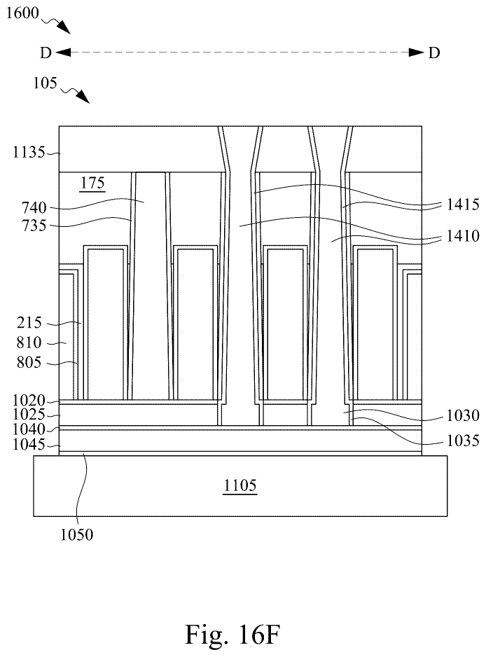

As shown in FIGS. 9G and 9H, one or more gate structures 810 may be etched to extend the gate isolation recess 935 down to a second depth (indicated in FIG. 9G as a dimension D5) corresponding to a top of the semiconductor substrate 110. The gate isolation recess 935 may extend through the one or more gate structures 810 and through one or more STI regions 175 under the one or more gate structures 810. As further shown in FIGS. 9G and 9H, the gate isolation recess 935 may also be formed through one or more portions of the ILD layer 605. This is referred to as a “non-selective” gate isolation recess 935. Alternatively, “selective” gate isolation recess 935 may be formed by selectively etching the gate structure(s) 810 with minimal to no etching of the ILD layer 605, as described in greater detail in connection with FIGS. 16A-16F.

As shown in FIGS. 91 and 9J, a dielectric liner 940 may be formed on the sidewalls and on the bottom surface of the gate isolation recess 935. In some implementations, the dielectric liner 940 is formed along the top surface of the hard mask layer 905. The dielectric liner 940 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material. A deposition tool may be used to deposit the dielectric liner 940 using a PVD technique, an ALD technique, a CVD technique, an oxidation technique, and/or another suitable deposition technique.

As further shown in FIGS. 91 and 9J, a gate isolation structure 945 may be formed in the gate isolation recess 935. In particular, the gate isolation structure 945 may be formed on the dielectric liner 940 in the gate isolation recess 935. The gate isolation recess 935 may be over-filled with the material of the gate isolation structure 945 to ensure that the gate isolation recess 935 is fully filled with the material of the gate isolation structure 945 and to minimize the formation of gaps or voids in the gate isolation structure 945.

A deposition tool may be used to deposit the gate isolation structure 945 using a PVD technique, an ALD technique, a CVD technique, an oxidation technique, and/or another suitable deposition technique. The gate isolation structure 945 may include a dielectric material such as a silicon oxide (SiOₓ such as SiO₂), a silicon nitride (SiₓN_{y} such as a Si₃N₄), a silicon oxynitride (SiON), fluoride-doped silicate glass (FSG), a high-k dielectric material, and/or another suitable dielectric material.

As shown in FIGS. 9K and 9L, a planarization operation may be performed to planarize the semiconductor device 105 after the gate isolation recess 935 is filled in with the gate isolation structure 945. A planarization tool may be used to perform a CMP operation and/or another type of planarization operation to remove the hard mask layer 905, to remove excess material of the dielectric liner 940, and/or to remove excess material of the gate isolation structure 945.

As indicated above, FIGS. 9A-9L are provided as an example. Other examples may differ from what is described with regard to FIGS. 9A-9L.

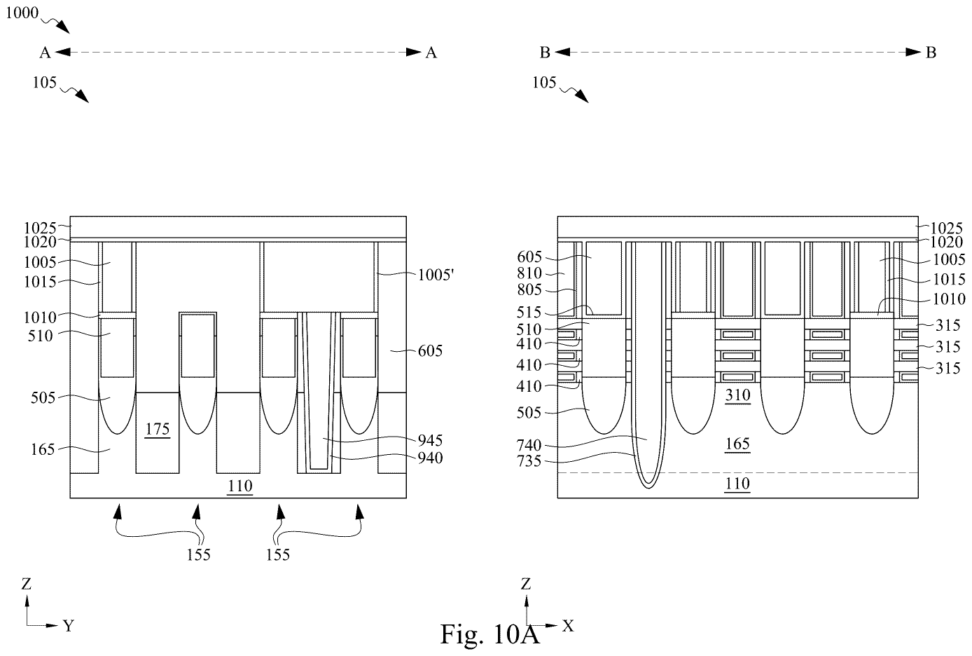

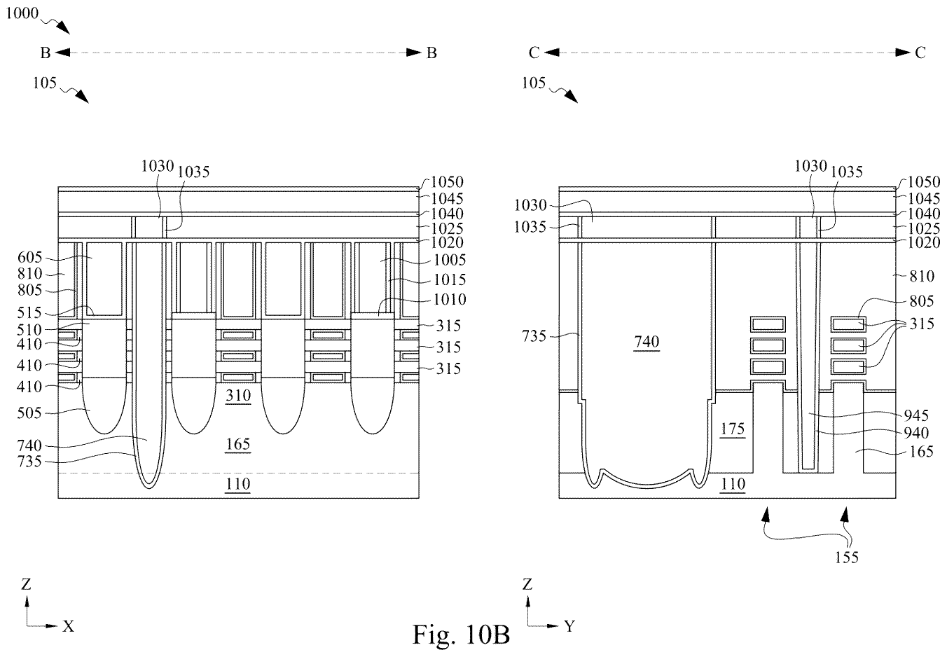

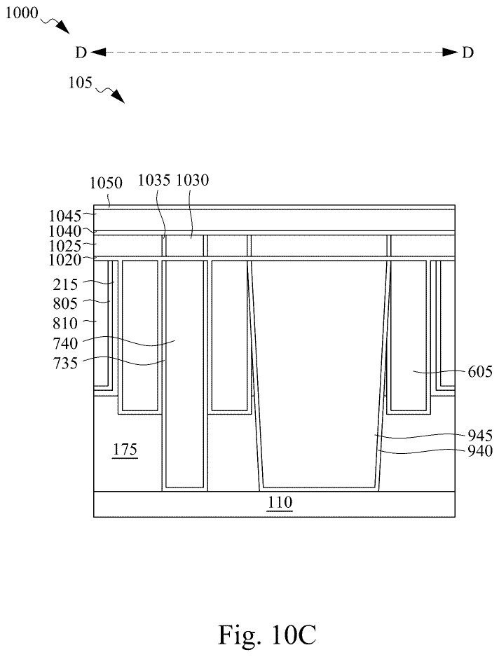

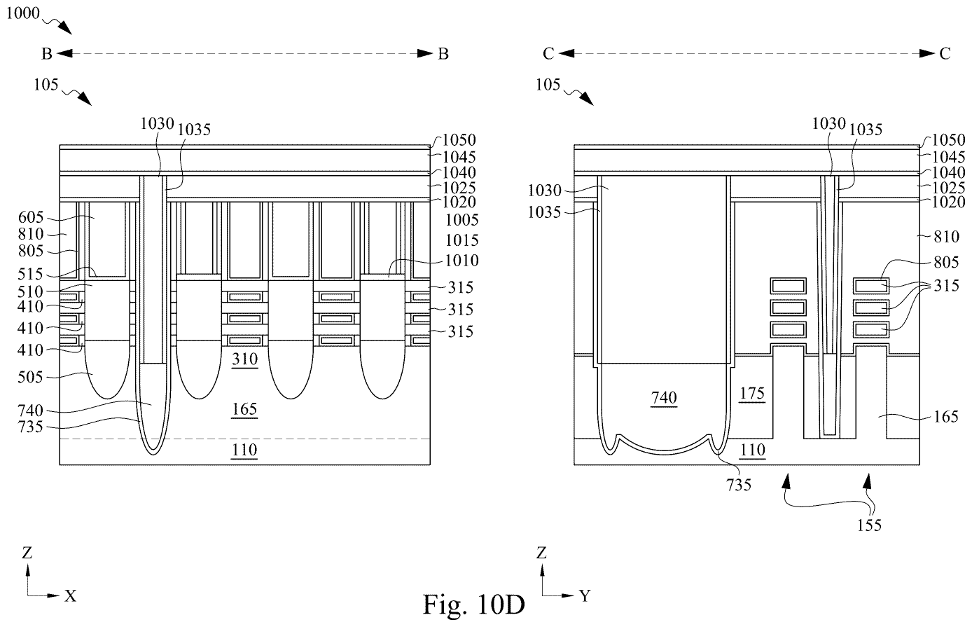

FIGS. 10A-10D are diagrams of an example implementation 1000 of an interconnect layer formation process described herein. The example implementation 1000 includes an example of BEOL process for forming dielectric layers and conductive structures of a front side interconnect layer (e.g., an interconnect layer on the front side of the semiconductor device 105). FIGS. 10A-10D are illustrated from a plurality of perspectives illustrated in FIG. 2, including the perspective of the cross-sectional plane A-A in FIG. 2, the perspective of the cross-sectional plane B-B in FIG. 2, the perspective of the cross-sectional plane C-C in FIG. 2, and/or the perspective of the cross-sectional plane D-D in FIG. 2. In some implementations, the operations described in connection with the example implementation 1000 are performed after one or more operations described in connection with FIGS. 1A-9L.

As shown in FIG. 10A, source/drain contacts 1005 may be formed on one or more of the source/drain regions 510 of the semiconductor device. In some implementations, a source/drain contact 1005 may be formed over and/or on a single source/drain region 510. In some implementations, a source/drain contact 1005 (e.g., a merged source/drain contact 1005′ illustrated in the cross-section along the line A-A in FIG. 10A) may span across a plurality of source/drain regions 510. In some implementations, the merged source/drain contact 1005′ may span across a gate isolation structure 945.

To form a source/drain contact 1005, a recess may be formed through the ILD layer 605 and through the capping layer 515 to an underlying source/drain region 510. A metal silicide layer 1010 may be formed on the exposed surface of the source/drain region 510, and the source/drain contact 1005 may be formed on the metal silicide layer 1010. The recess and the associated source/drain contact 1005 may be formed from the front side of the semiconductor device 105. Thus, the source/drain contact 1005 may be referred to as a front side source/drain contact.

In some implementations, a pattern in a photoresist layer is used to etch the ILD layer 605 and/or the capping layer 515 to form the recess. In these implementations, a deposition tool may be used to form the photoresist layer on the ILD layer 605 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ILD layer 605 and/or the capping layer 515 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A metal silicide layer 1010 may include titanium silicide (TiSi), ruthenium silicide (RuSi), and/or another metal silicide material that is included on a source/drain region 510 to achieve a low contact resistance between the source/drain region 510 and an associates source/drain contact 1005. To form a metal silicide layer 1010 in a recess over a source/drain region 510, a deposition tool may be used to deposit metal material using a CVD technique, a PVD technique, an ALD technique, an electroplating technique, and/or another suitable deposition technique. An annealing operation may then be performed to cause the metal material to diffuse into the top surface of the source/drain region 510 (referred to as salicidation), resulting in formation of the metal silicide layer 1010.

To form a source/drain contact 1005 on the metal silicide layer 1010 in the recess, a deposition tool may be used to deposit the material of the source/drain contact 1005 using a CVD technique, a PVD technique, an ALD technique, an electroplating technique, and/or another suitable deposition technique. The source/drain contact 1005 may include one or mor electrically conductive materials, such as ruthenium (Ru), tungsten (W), cobalt (Co), titanium (Ti), and/or tantalum (Ta), among other examples. In some implementations, a liner 1015 is deposited on the sidewalls of the recess, and the source/drain contact 1005 is then deposited in the recess such that the liner 1015 is between the source/drain contact 1005 and the ILD layer 605. The liner 1015 may include tantalum nitride (TaN), titanium nitride (TiN), and/or another suitable liner material. In some implementations, a planarization tool is used to perform a planarization operation (e.g., a CMP operation) to planarize the source/drain contact 1005 after the source/drain contact 1005 is deposited.

As further shown in FIG. 10A, an etch stop layer (ESL) 1020 may be formed over the front side of the semiconductor device 105 such that the ESL 1020 is formed over the source/drain contacts 1005. An ILD layer 1025 may be formed over the ESL 1020. A deposition tool may be used to deposit the ESL 1020 and/or the ILD layer 1025 using a PVD technique, an ALD technique, a CVD technique, an oxidation technique, and/or another suitable deposition technique. In some implementations, a planarization tool may be used to perform a planarization operation (e.g., a CMP operation) to planarize the ESL 1020 and/or the ILD layer 1025 after the ESL 1020 and/or the ILD layer 1025 are deposited.

The ESL 1020 may include a silicon nitride (SiₓN_{y}), silicon carbide (SiC), silicon oxynitride (SiON), and/or another suitable dielectric material. The ILD layer 1025 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the ILD layer 1025 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples. In some implementations, the ESL 1020 and the ILD layer 1025 include different dielectric materials to provide etch selectivity to enable various structures to be formed in the front side interconnect layer.

As shown in FIGS. 10B and 10D, conductive structures 1030 of the front side interconnect layer may be formed in and/or through the ILD layer 1025 and the ESL 1020. In some implementations, one or more of the conductive structures 1030 may be formed on (e.g., may land on) an active region isolation structure 740. In some implementations, one or more of the conductive structures 1030 may be formed on (e.g., may land on) a gate structure 810. In some implementations, one or more of the conductive structures 1030 may be formed on (e.g., may land on) a gate isolation structure 945. In some implementations, one or more of the conductive structures 1030 may be formed on (e.g., may land on) a source/drain contact 1005.

The conductive structures 1030 provide electrical routing that enables signals and/or power to be distributed across the front side of the semiconductor device 105. The conductive structures 1030 may include a combination of metallization structures and interconnect structures. The metallization structures may include trenches, metallization layers, conductive traces, and/or other types of metallization structures. The interconnect structures may include vias, plugs, interconnects, and/or another type of interconnect structures. The conductive structures 1030 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liners 1035 are included on sidewalls of the conductive structures 1030. The one or more liners 1035 may include barrier liners, adhesion liners, and/or another type of liners. Examples of materials for the one or more liners 1035 include tantalum nitride (TaN) and/or titanium nitride (TiN), among other examples.

As further shown in FIGS. 10B and 10D, additional ILD layers and additional ESLs may be formed over the front side of the semiconductor device 105. For example, an ESL 1040 may be formed over the ILD layer 1025, an ILD layer 1045 may be formed over the ESL 1040, an ESL 1050 may be formed over the ILD layer 1045, and so on. Moreover, additional conductive structures 1030 may be formed in the ILD layers and ESLs in the front side interconnect layer.

In some implementations, the conductive structures 1030 of the front side interconnect layer may be arranged in a plurality of layers that are arranged in a vertical manner (e.g., in the z-direction) in the front side interconnect layer. In other words, a plurality of layers of conductive structures 1030 may extend above the front side of the semiconductor device 105. The conductive structures 1030 may include metallization structures that are arranged in metallization layers referred to as M-layers. For example, a metal-0 (M0) layer that includes a plurality of conductive structures 1030 (e.g., metallization structures) may be located at the bottom of the front side interconnect layer and may be directly coupled with the gate structures 810 and/or with the source/drain contacts 1005. A via-1 (V1) layer that includes a plurality of conductive structures 1030 (e.g., interconnect structures) may be included above the MO layer.

A metal-1 layer (M1) layer that includes a plurality of conductive structures 1030 (e.g., metallization structures) may be located above the V1 layer in the front side interconnect layer, a via-2 (V2) layer that includes a plurality of conductive structures 1030 (e.g., interconnect structures) may be included above the M1 layer, a metal-2 layer (M2) layer that includes a plurality of conductive structures 1030 (e.g., metallization structures) may be located above the V2 layer, and so on.

FIG. 10D illustrates an alternative implementation in which one or more conductive structures 1030 extend into one or more active region isolation structures 740. In these implementations, portions of the one or more active region isolation structures 740 may be etched to remove material from the one or more active region isolation structures 740, and the removed portions may be backfilled with the material of the one or more conductive structures 1030. Accordingly, the one or more conductive structures 1030 may extend through a gate structure 810 and/or into an underlying STI region 175, and/or may extend into an underlying fin portion 165.

As indicated above, FIGS. 10A-10D are provided as an example. Other examples may differ from what is described with regard to FIGS. 10A-10D.

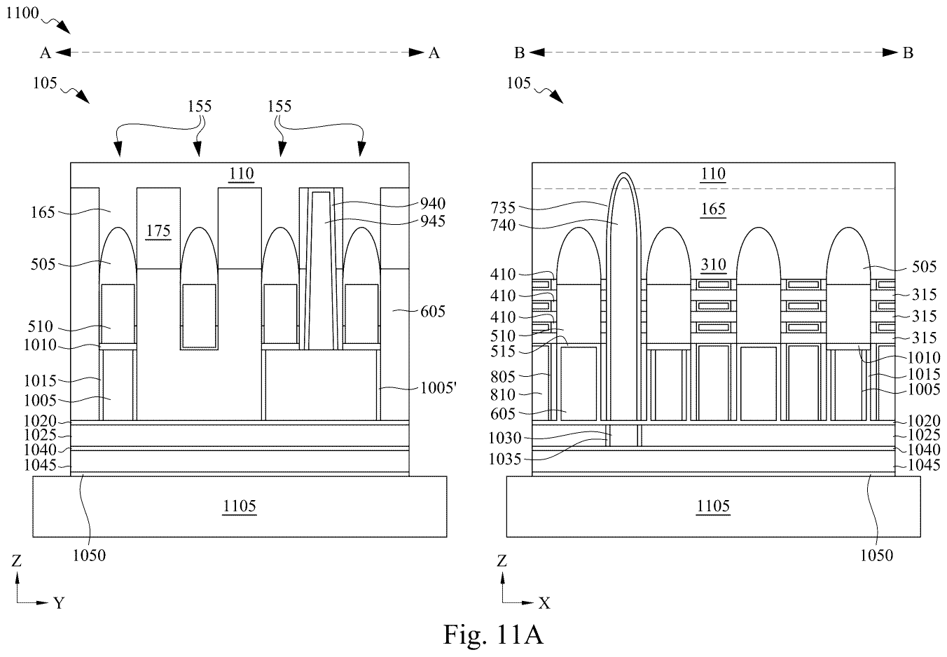

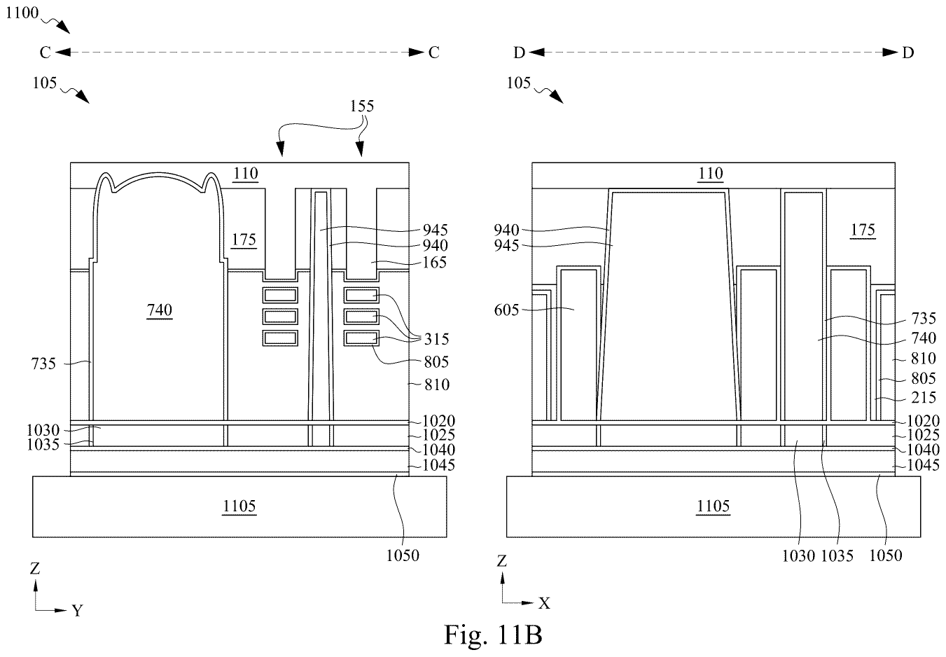

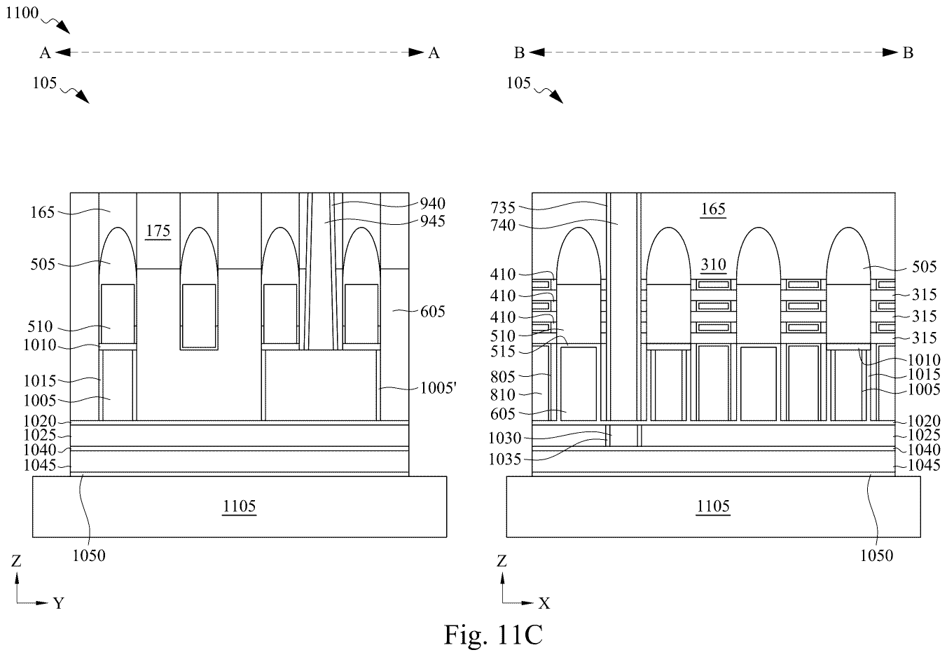

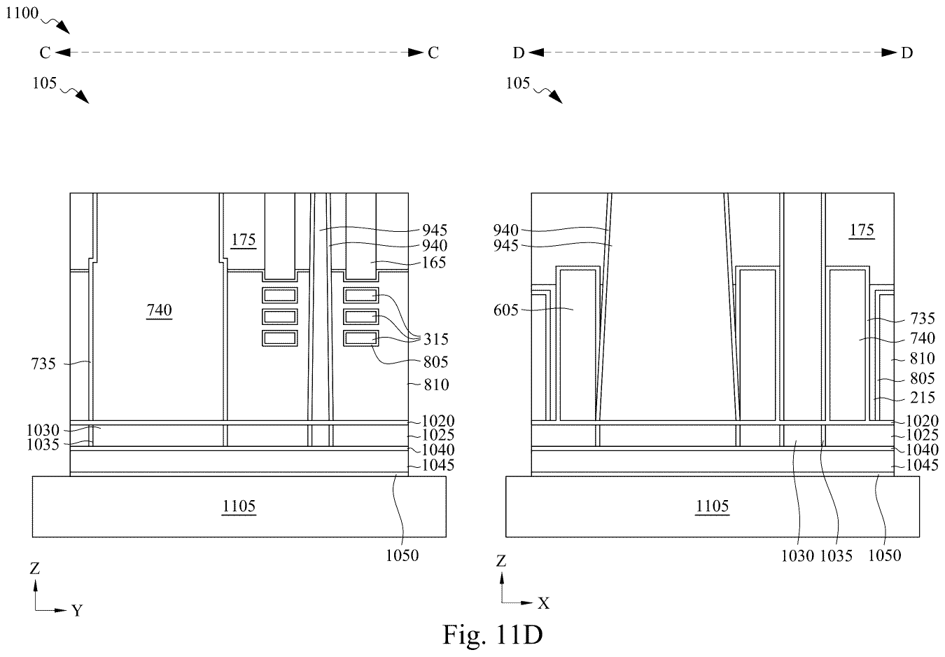

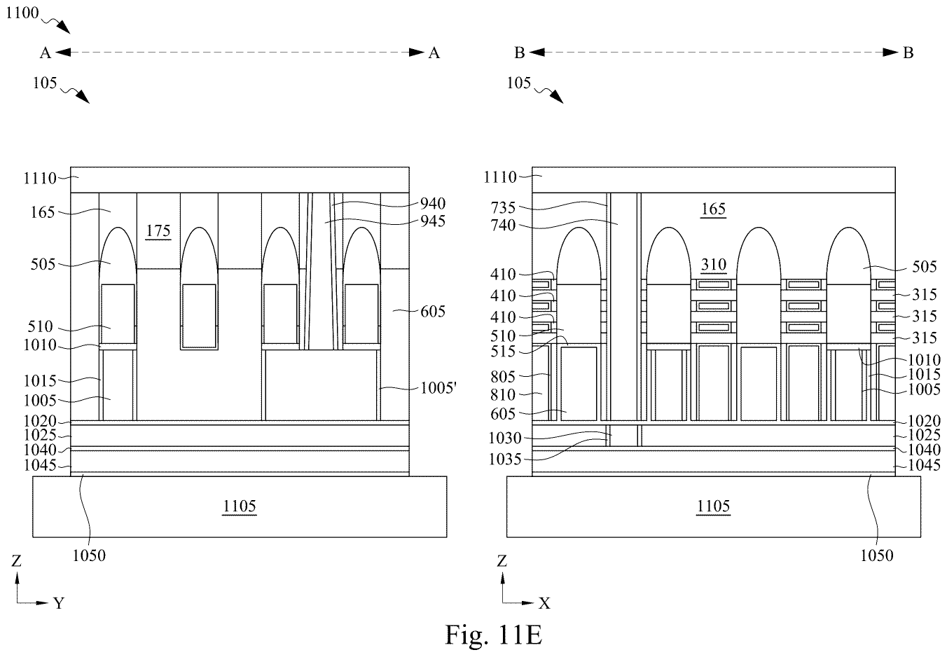

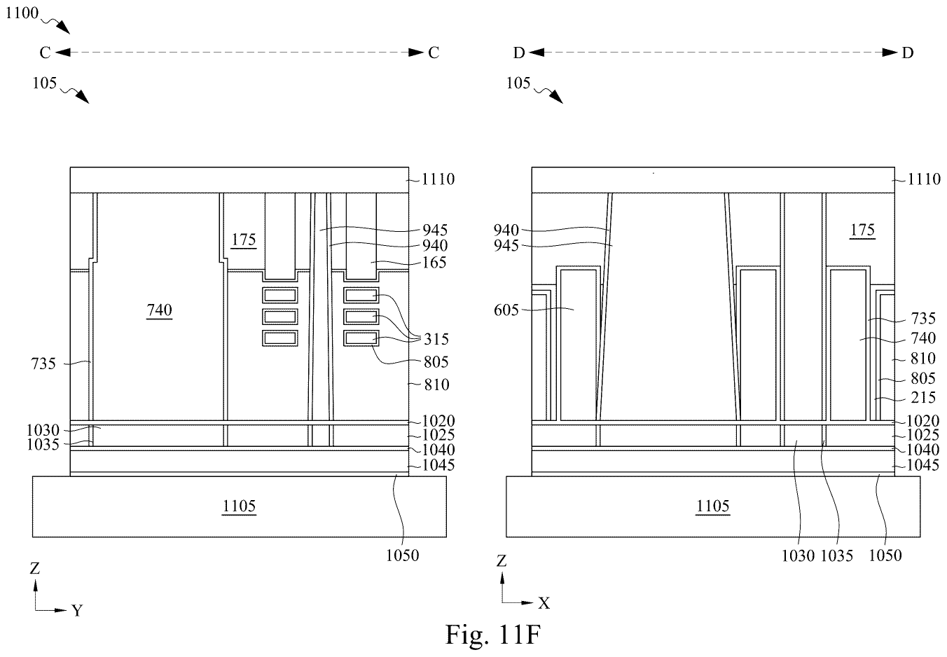

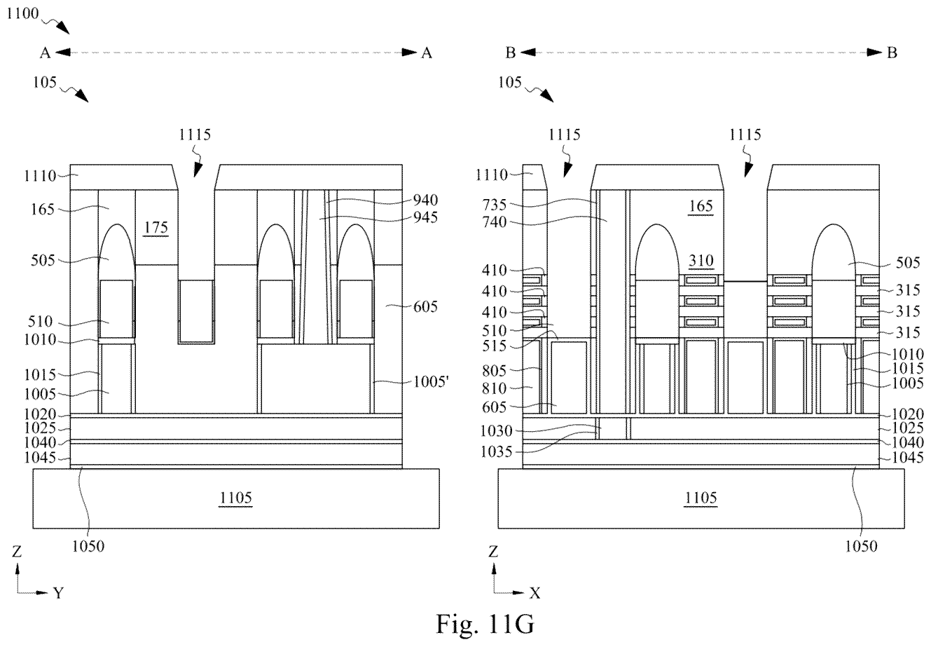

FIGS. 11A-11H are diagrams of an example implementation 1100 of a source/drain contact formation process described herein. The example implementation 1100 includes an example of back side processing for the semiconductor device 105. In particular, the example implementation 1100 includes an example of forming back side source/drain contacts of the semiconductor device 105. FIGS. 11A-11H are illustrated from a plurality of perspectives illustrated in FIG. 2, including the perspective of the cross-sectional plane A-A in FIG. 2, the perspective of the cross-sectional plane B-B in FIG. 2, the perspective of the cross-sectional plane C-C in FIG. 2, and/or the perspective of the cross-sectional plane D-D in FIG. 2. In some implementations, the operations described in connection with the example implementation 1100 are performed after one or more operations described in connection with FIGS. 1A-10C.

As shown in FIGS. 11A and 11B, the semiconductor device 105 may be flipped, and the front side of the semiconductor device 105 may be secured to a carrier substrate 1105. This enables processing to be performed on a back side of the semiconductor device 105. The carrier substrate 1105 may include a semiconductor substrate (e.g., a silicon (Si) wafer) a dielectric substrate, and/or another suitable substrate that supports the semiconductor device 105.

As shown in FIGS. 11C and 11D, a planarization operation may be performed on the back side of the semiconductor device 105 to remove the semiconductor substrate 110. A planarization tool may be used to perform the planarization operation, which may include a CMP operation, a wafer grinding operation, and/or another suitable planarization operation. The planarization operation may result in the STI regions 175 and the fin portions 165 of the fin structures 155 being exposed through the back side of the semiconductor device 105. Moreover, the planarization operation may result in the bottoms of one or more active region isolation structures 740 and/or the bottoms of one or more gate isolation structures 945 being exposed through the back side of the semiconductor device 105. In some implementations, material from the STI regions 175, material from the fin portions 165, material from the one or more active region isolation structures 740, and/or material from the one or more gate isolation structures 945 is also removed during the planarization operation.

In some implementations, a CMP stop layer may be embedded in the fin portions 165 to provide a mechanism by which to control the depth of the planarization operation. For example, a silicon germanium (SiGe) stop layer or another type of stop layer may be formed above the semiconductor substrate 110 prior to formation of the layer stack 115. The planarization operation may be completed once the CMP stop layer is reached.

As shown in FIGS. 11E and 11F, a hard mask layer 1110 may be formed over and/or on the back side of the semiconductor device 105. The hard mask layer 1110 includes one or more layers such as an oxide layer (e.g., a pad oxide layer that may include silicon dioxide (SiO₂) or another material) and/or a nitride layer (e.g., a pad nitride layer that may include a silicon nitride such as Si₃N₄ or another material) formed over the oxide layer. The hard mask layer 1110 may be deposited using a deposition process, such as ALD, CVD, or another deposition technique.

As shown in FIG. 11G, one or more source/drain recesses 1115 are formed from the back side of the semiconductor device 105 through the hard mask layer 1110 and to one or more source/drain regions 510 of the semiconductor device 105. In some implementations, a patterning stack, similar to the patterning stack 705 and/or 910 may be formed over and/or on the hard mask layer 1110 and used to etch the hard mask layer 1110 and the fin portions 165 above the source/drain regions 510 to form the source/drain recesses 1115.

As shown in FIG. 11H, one or more source/drain contacts 1120 may be formed on the bottom surfaces of the source/drain regions 510 exposed in the source/drain recesses 1115. The source/drain contacts 1120 are formed from the back side of the semiconductor device 105 and may therefore be referred to as back side source/drain contacts. The source/drain contacts 1005 (e.g., front side source/drain contacts) electrically connect one or more source/drain regions 510 to one or more conductive structures 1030 in the front side interconnect layer of the semiconductor device 105, whereas the source/drain contacts 1120 are formed to electrically connect one or more source/drain regions 510 to one or more conductive structures that are to be formed in a back side interconnect layer on a back side of the semiconductor device 105.

The source/drain contacts 1120 may be formed of similar materials and/or using similar processes as those described for the source/drain contacts 1005. Moreover, metal silicide layers 1125 may be formed on the bottom surfaces of the source/drain regions 510 in a similar manner as the metal silicide layers 1010, and the source/drain contacts 1120 may be formed on the metal silicide layers 1125 in the source/drain recesses 1115. Additionally and/or alternatively, liners 1130 may be formed on the sidewalls of the source/drain recesses 1115 in a similar manner as the liners 1015, and the source/drain contacts 1120 may be formed in the source/drain recesses 1115 such that the liners 1130 are between the source/drain contacts 1120 and the STI regions 175 and/or between the source/drain contacts 1120 and the fin portions 165.

As further shown in FIG. 11H, another hard mask layer 1135 may be formed over and/or on the back side of the semiconductor substrate 110. In some implementations, the hard mask layer 1135 may correspond to additional material of the hard mask layer 1110. The hard mask layer 1135 includes one or more layers such as an oxide layer (e.g., a pad oxide layer that may include silicon dioxide (SiO₂) or another material) and/or a nitride layer (e.g., a pad nitride layer that may include a silicon nitride such as Si₃N₄ or another material) formed over the oxide layer. The hard mask layer 1135 may be deposited using a deposition process, such as ALD, CVD, or another deposition technique.

As indicated above, FIGS. 11A-11H are provided as an example. Other examples may differ from what is described with regard to FIGS. 11A-11H.

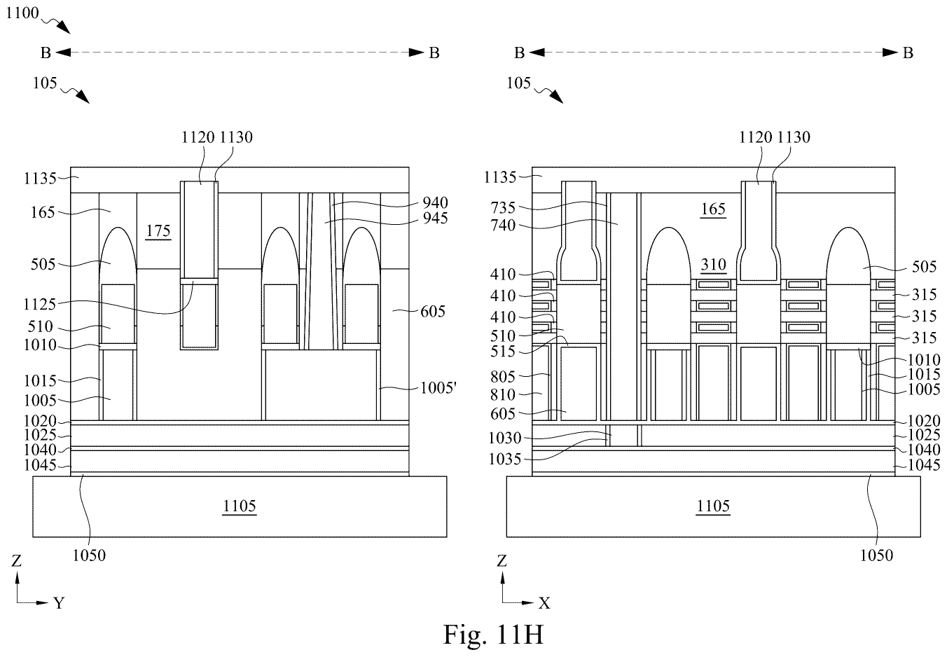

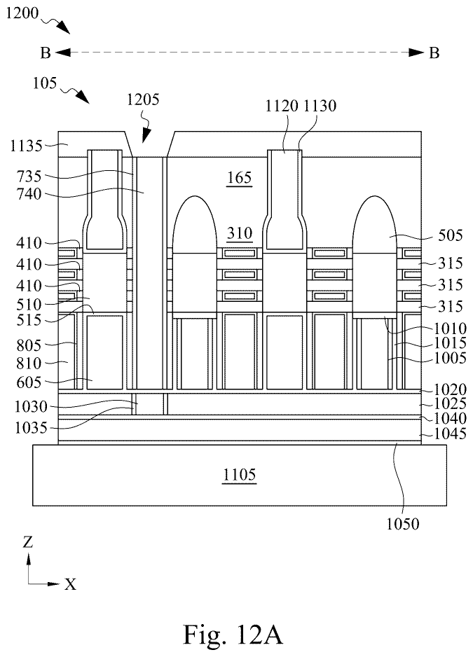

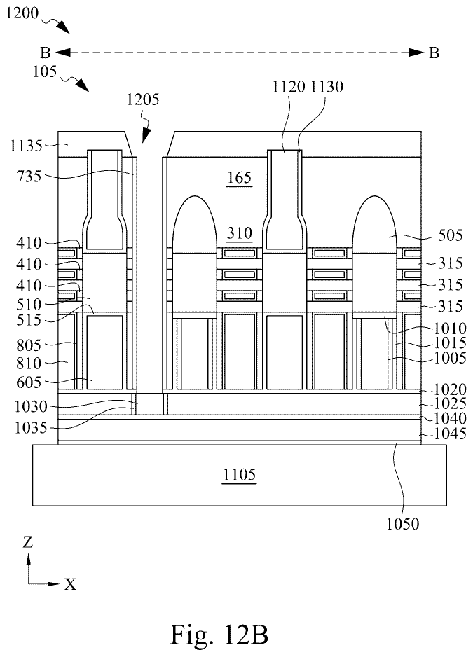

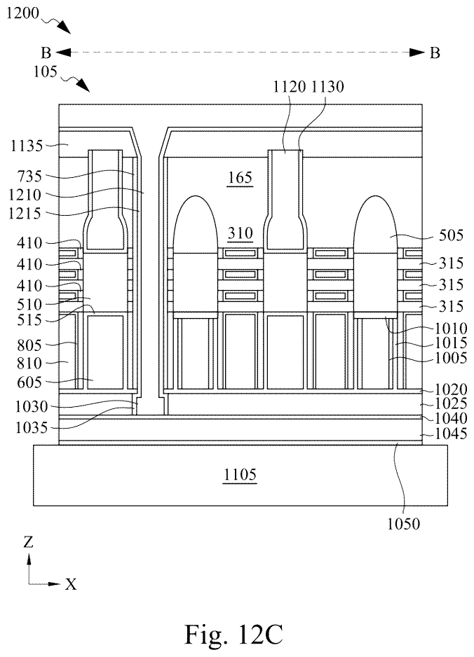

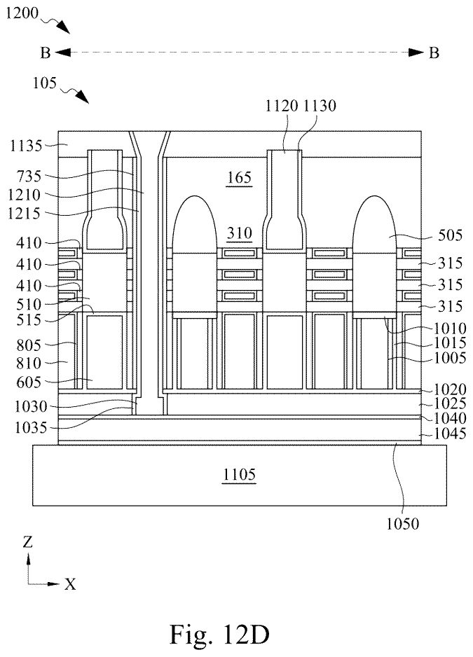

FIGS. 12A-12D are diagrams of an example implementation 1200 of a through-substrate interconnect formation process described herein. The example implementation 1200 includes an example of back side processing for the semiconductor device 105. In particular, the example implementation 1200 includes an example of replacing an active region isolation structure 740 from the back side of the semiconductor device 105 with a through-substrate interconnect structure (e.g., a CPODE TSV structure). FIGS. 12A-12D are illustrated from the cross-sectional plane B-B in FIG. 2. In some implementations, the operations described in connection with the example implementation 1200 are performed after one or more operations described in connection with FIGS. 1A-11H.

As shown in FIG. 12A, a recess 1205 is formed from the back side of the semiconductor device 105 through the hard mask layer 1135. In some implementations, a patterning stack, similar to the patterning stack 705 and/or 910 may be formed over and/or on the hard mask layer 1135 and used to etch the hard mask layer 1135 to form the recess 1205. The recess 1205 is formed above the bottom of an active region isolation structure 740 so that the bottom of the active region isolation structure 740 is exposed through the recess 1205.

As shown in FIG. 12B, an etch tool may be used to perform an etch operation to etch the active region isolation structure 740 from the back side of the semiconductor device 105 to remove the active region isolation structure 740 through the recess 1205. This results in the recess 1205 extending through the area previously occupied by the active region isolation structure 740 and down to an underlying conductive structure 1030 of the front side interconnect layer that was formed on the top of the active region isolation structure 740.

The etch operation may be self-aligned in that the active region isolation structure 740 was formed of a material that enables the active region isolation structure 740 to be selectively etched with minimal to no etching of the hard mask layer 1135 and the dielectric liner 735. As an example, the hard mask layer 1135 and the dielectric liner 735 may be formed of a high-k dielectric material such as silicon nitride (SiₓN_{y} such as Si₃N₄), and the active region isolation structure 740 may be formed of a low-k dielectric material such as silicon oxide (SiOₓ such as SiO₂). As an example, the hard mask layer 1135 and the dielectric liner 735 may be formed of silicon carbide (SiC), and the active region isolation structure 740 may be formed of a low-k dielectric material such as silicon oxide (SiOₓ such as SiO₂).

The etch operation may include a buffered oxide etch (BOE) in which a mixture of hydrofluoric acid (HF) and ammonium fluoride (NH₄F) is used to etch the silicon oxide material of the active region isolation structure 740 with minimal to no etching of the silicon nitride material or silicon carbide material of the hard mask layer 1135 and the dielectric liner 735.

As shown in FIG. 12C, the recess 1205 is filled in with material of a through-substrate interconnect structure 1210 (e.g., a CPODE TSV). The through-substrate interconnect structure 1210 provides electrical routing between the front side of the semiconductor device 105 and the back side of the semiconductor device 105, and enables signals and/or power to be distributed between the front side and the back side of the semiconductor device 105. The through-substrate interconnect structure 1210 may include a trench, a via, a pillar, a column, and/or another type of conductive structure that extends between the front side and the back side of the semiconductor device 105. The through-substrate interconnect structure 1210 may extend through one or more fin portions 165, through one or more STI regions 175, through one or more stacks of nanostructure channels 315, and/or through the ILD layer 605, among other examples.

The through-substrate interconnect structure 1210 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. A deposition tool may be used to through-substrate interconnect structure 1210 in the recess 1205 using an ALD technique, a CVD technique, a PVD technique, an electroplating technique, and/or another suitable deposition technique. In some implementations, material of the through-substrate interconnect structure 1210 is also deposited across the back side of the semiconductor device 105 to ensure that the recess 1205 is fully filled in with the material of the through-substrate interconnect structure 1210 to reduce the likelihood of void formation in the through-substrate interconnect structure 1210.

In some implementations, one or more liners 1215 are included on sidewalls of the through-substrate interconnect structure 1210. The one or more liners 1215 may include barrier liners, adhesion liners, and/or another type of liners. Examples of materials for the one or more liners 1215 include tantalum nitride (TaN) and/or titanium nitride (TiN), among other examples. A deposition tool may be used to deposit the liner(s) 1215 on the sidewalls of the recess 1205 using a conformal deposition technique such as an ALD technique and/or a CVD technique, among other examples. The through-substrate interconnect structure 1210 may then be deposited in the recess 1205 to fill in the remaining area in the recess 1205. Thus, the liner(s) 1215 may be on the sidewalls of the through-substrate interconnect structure 1210 and may be located between the sidewalls of the through-substrate interconnect structure 1210 and other layers and/or structures of the semiconductor device 105. The liner(s) 1215 may also be deposited across the back side of the semiconductor device 105.

As shown in FIG. 12D, a planarization tool may be used to perform a planarization operation (e.g., a CMP operation) to remove the excess material of the through-substrate interconnect structure 1210 and the excess material of the liner(s) 1215 from the back side of the semiconductor device 105. The planarization operation may be stopped once the hard mask layer 1135 is reached. Alternatively, material of the hard mask layer 1135 may also be removed during the planarization operation.

As indicated above, FIGS. 12A-12D are provided as an example. Other examples may differ from what is described with regard to FIGS. 12A-12D.

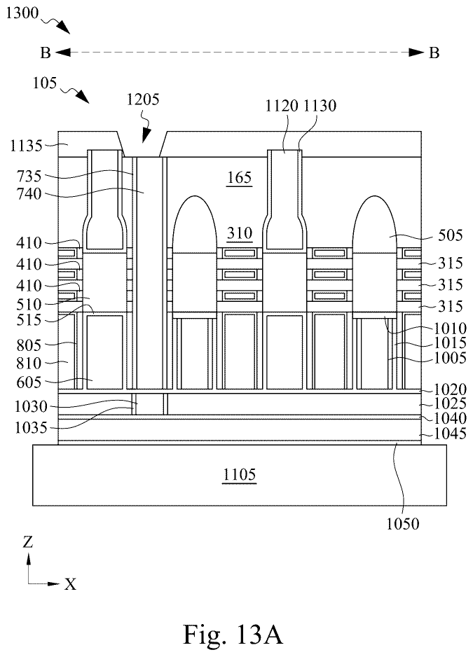

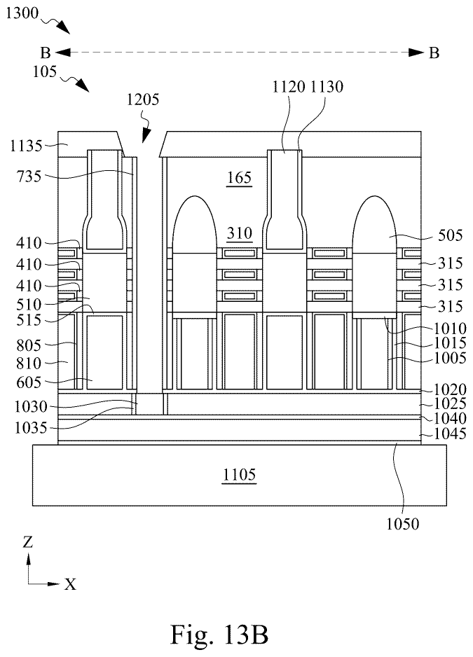

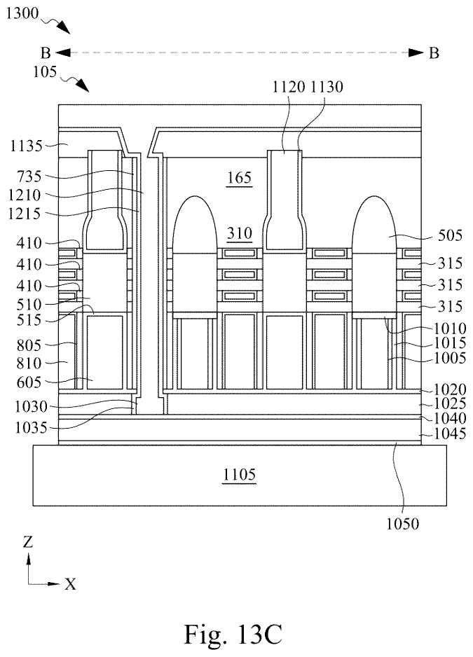

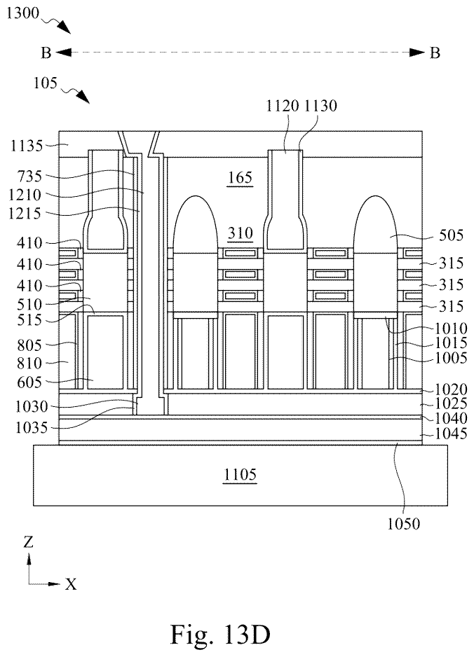

FIGS. 13A-13D are diagrams of an example implementation 1300 of a through-substrate interconnect formation process described herein. The example implementation 1300 includes an example of back side processing for the semiconductor device 105. In particular, the example implementation 1200 includes an example of replacing an active region isolation structure 740 from the back side of the semiconductor device 105 with a through-substrate interconnect structure (e.g., a CPODE TSV structure). FIGS. 13A-13D are illustrated from the cross-sectional plane B-B in FIG. 2. In some implementations, the operations described in connection with the example implementation 1300 are performed after one or more operations described in connection with FIGS. 1A-11H.

As shown in FIGS. 13A-13D, the example implementation 1300 is similar to the example implementation 1200 in that a recess 1205 is formed from the back side of the semiconductor device 105 through the hard mask layer 1135, an active region isolation structure 740 is removed through the recess 1205 in the back side of the semiconductor device 105 using a self-aligned etch technique, and a through-substrate interconnect structure 1210 and the associated liner(s) 1215 are formed in the recess 1205.

However, in the example implementation 1300, an overlay shift occurs during formation of the recess 1205, resulting in the recess 1205 being partially laterally offset relative to the active region isolation structure 740. Thus, a portion of the semiconductor material of a fin portion 165 may be exposed through the recess 1205. The use of the self-aligned etch technique enables the active region isolation structure 740 to be removed through the recess 1205, even where overlay shift occurs, with minimal to no etching of the fin portion 165. This is achieved through the use of different materials for the fin portion 165 and the active region isolation structure 740, in combination with an etchant that selectively etches the material of the active region isolation structure 740 with minimal to no etching of the material of the fin portion 165.

As shown in FIG. 13D, the portion of the through-substrate interconnect structure 1210 formed through the hard mask layer 1135 is partially laterally offset relative to the portion of the through-substrate interconnect structure 1210 formed in the area previously occupied by the active region isolation structure 740. The liner(s) 1215 may be prevent, minimize, and/or otherwise reduce the likelihood of material migration from the through-substrate interconnect structure 1210 into the portions of the fin portion 165 that were exposed through the recess 1205.

As indicated above, FIGS. 13A-13D are provided as an example. Other examples may differ from what is described with regard to FIGS. 13A-13D.

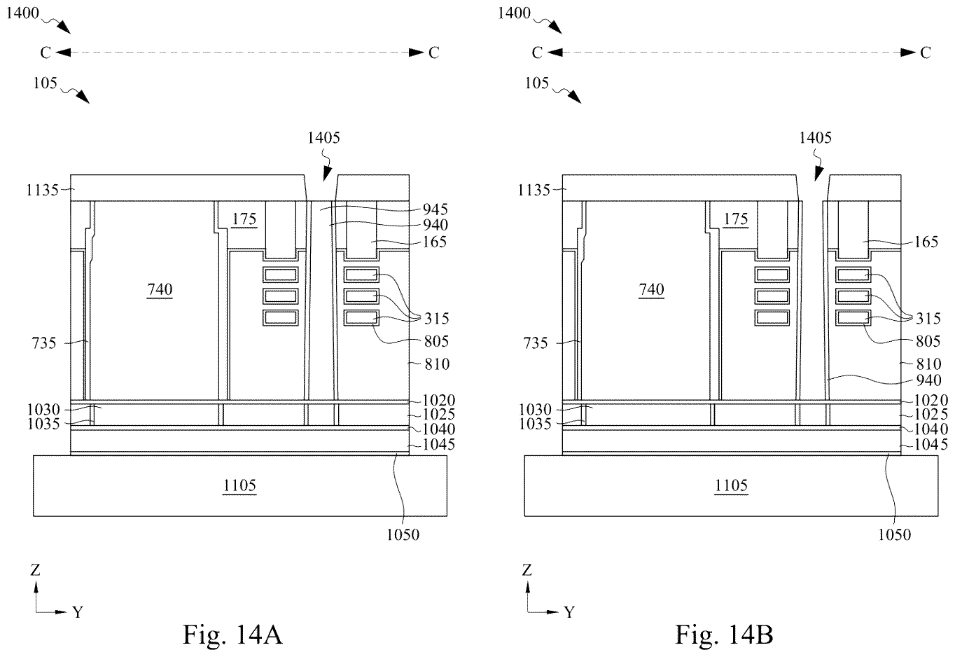

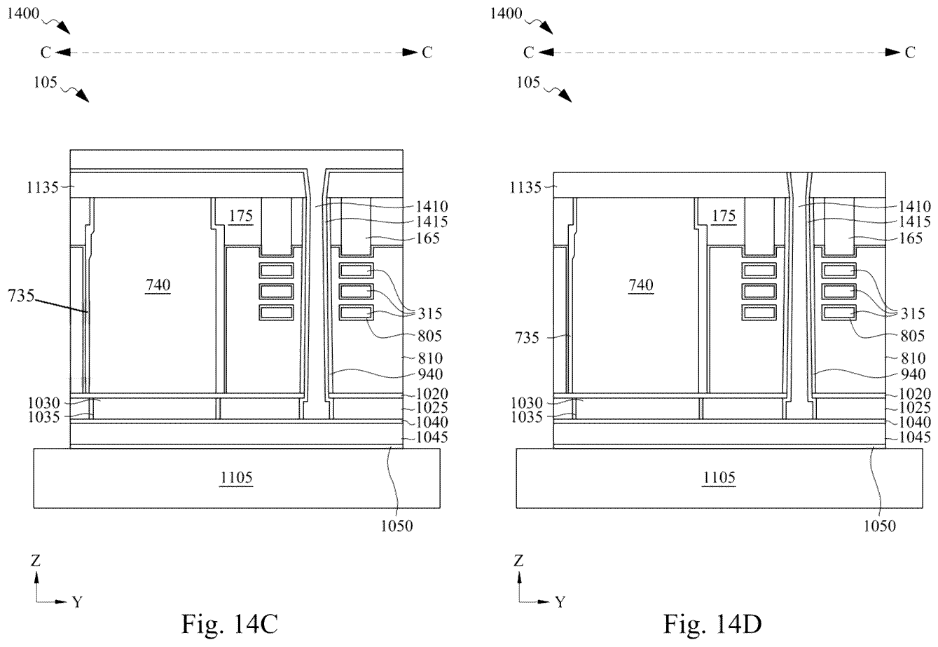

FIGS. 14A-14D are diagrams of an example implementation 1400 of a through-substrate interconnect formation process described herein. The example implementation 1400 includes an example of back side processing for the semiconductor device 105. In particular, the example implementation 1400 includes an example of replacing a gate isolation structure 945 from the back side of the semiconductor device 105 with a through-substrate interconnect structure (e.g., a CMG TSV structure). FIGS. 14A-14D are illustrated from the cross-sectional plane C-C in FIG. 2. In some implementations, the operations described in connection with the example implementation 1400 are performed after one or more operations described in connection with FIGS. 1A-11H.

As shown in FIG. 14A, a recess 1405 is formed from the back side of the semiconductor device 105 through the hard mask layer 1135. In some implementations, a patterning stack, similar to the patterning stack 705 and/or 910 may be formed over and/or on the hard mask layer 1135 and used to etch the hard mask layer 1135 to form the recess 1405. The recess 1405 is formed above the bottom of a gate isolation structure 945 so that the bottom of the gate isolation structure 945 is exposed through the recess 1405.

As shown in FIG. 14B, an etch tool may be used to perform an etch operation to etch the gate isolation structure 945 from the back side of the semiconductor device 105 to remove the gate isolation structure 945 through the recess 1405. This results in the recess 1405 extending through the area previously occupied by the gate isolation structure 945 and down to an underlying conductive structure 1030 of the front side interconnect layer that was formed on the top of the gate isolation structure 945.

The etch operation may be self-aligned in that the gate isolation structure 945 was formed of a material that enables the gate isolation structure 945 to be selectively etched with minimal to no etching of the hard mask layer 1135 and the dielectric liner 940. As an example, the hard mask layer 1135 and the dielectric liner 940 may be formed of a high-k dielectric material such as silicon nitride (SiₓN_{y} such as Si₃N₄), and the gate isolation structure 945 may be formed of a low-k dielectric material such as silicon oxide (SiOₓ such as SiO₂). As an example, the hard mask layer 1135 and the dielectric liner 940 may be formed of silicon carbide (SiC), and the gate isolation structure 945 may be formed of a low-k dielectric material such as silicon oxide (SiOₓ such as SiO₂).

The etch operation may include a BOE in which a mixture of hydrofluoric acid (HF) and ammonium fluoride (NH₄F) is used to etch the silicon oxide material of the gate isolation structure 945 with minimal to no etching of the silicon nitride material or silicon carbide material of the hard mask layer 1135 and the dielectric liner 940.

As shown in FIG. 14C, the recess 1405 is filled in with material of a through-substrate interconnect structure 1410 (e.g., a CMG TSV). The through-substrate interconnect structure 1410 provides electrical routing between the front side of the semiconductor device 105 and the back side of the semiconductor device 105, and enables signals and/or power to be distributed between the front side and the back side of the semiconductor device 105. The through-substrate interconnect structure 1410 may include a trench, a via, a pillar, a column, and/or another type of conductive structure that extends between the front side and the back side of the semiconductor device 105. The through-substrate interconnect structure 1410 may extend through one or more STI regions 175, through the ILD layer 605, and/or through one or more gate structures 810, among other examples.

The through-substrate interconnect structure 1410 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. A deposition tool may be used to through-substrate interconnect structure 1410 in the recess 1405 using an ALD technique, a CVD technique, a PVD technique, an electroplating technique, and/or another suitable deposition technique. In some implementations, material of the through-substrate interconnect structure 1410 is also deposited across the back side of the semiconductor device 105 to ensure that the recess 1405 is fully filled in with the material of the through-substrate interconnect structure 1410 to reduce the likelihood of void formation in the through-substrate interconnect structure 1410.

In some implementations, one or more liners 1415 are included on sidewalls of the through-substrate interconnect structure 1410. The one or more liners 1415 may include barrier liners, adhesion liners, and/or another type of liners. Examples of materials for the one or more liners 1415 include tantalum nitride (TaN) and/or titanium nitride (TiN), among other examples. A deposition tool may be used to deposit the liner(s) 1415 on the sidewalls of the recess 1405 using a conformal deposition technique such as an ALD technique and/or a CVD technique, among other examples. The through-substrate interconnect structure 1410 may then be deposited in the recess 1405 to fill in the remaining area in the recess 1405. Thus, the liner(s) 1415 may be on the sidewalls of the through-substrate interconnect structure 1410 and may be located between the sidewalls of the through-substrate interconnect structure 1410 and other layers and/or structures of the semiconductor device 105. The liner(s) 1415 may also be deposited across the back side of the semiconductor device 105.

As shown in FIG. 14D, a planarization tool may be used to perform a planarization operation (e.g., a CMP operation) to remove the excess material of the through-substrate interconnect structure 1410 and the excess material of the liner(s) 1415 from the back side of the semiconductor device 105. The planarization operation may be stopped once the hard mask layer 1135 is reached. Alternatively, material of the hard mask layer 1135 may also be removed during the planarization operation.

As indicated above, FIGS. 14A-14D are provided as an example. Other examples may differ from what is described with regard to FIGS. 14A-14D.

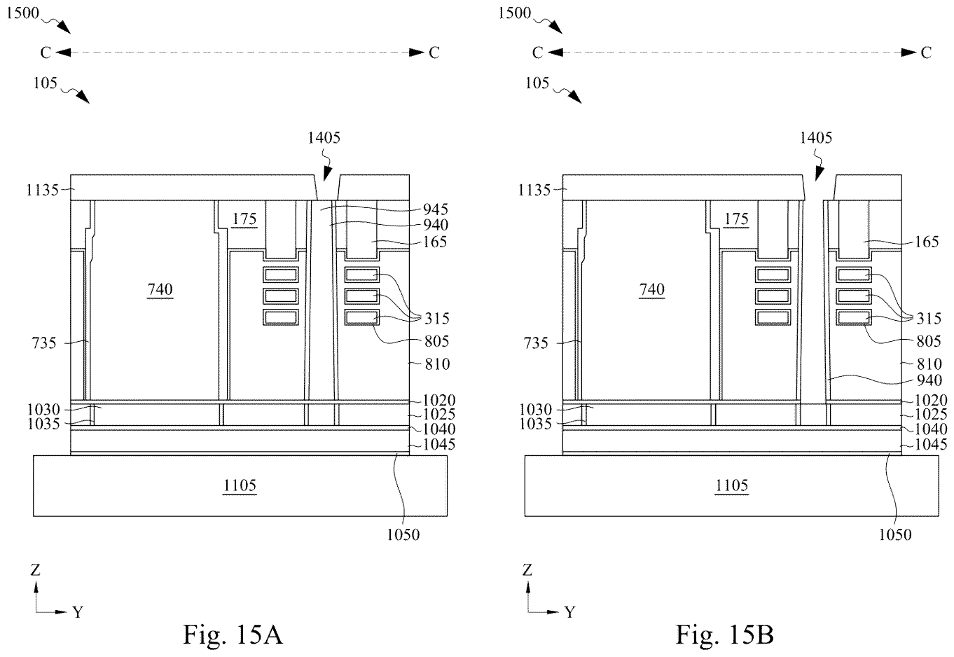

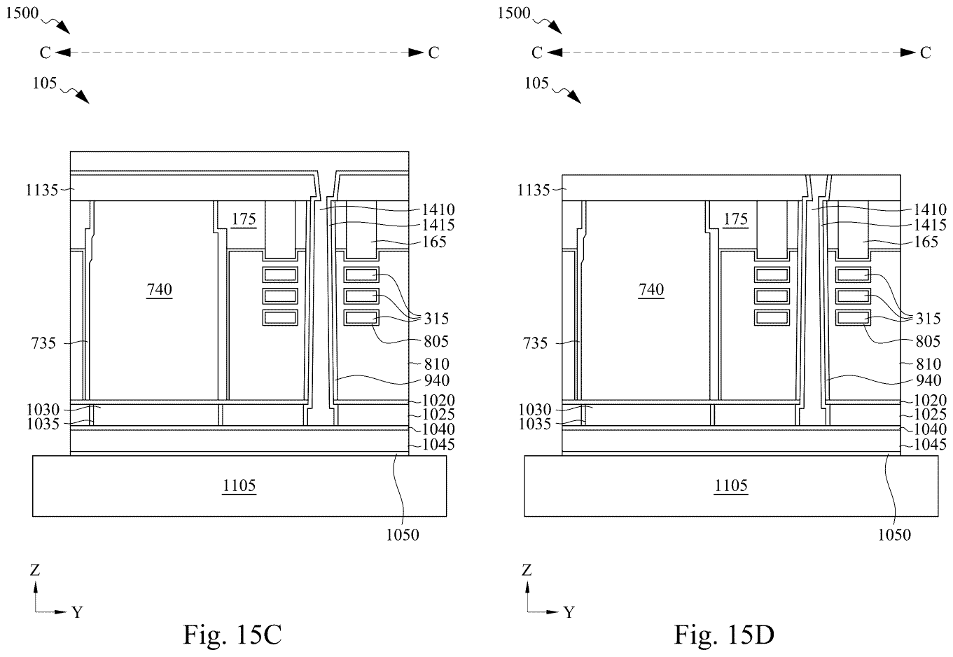

FIGS. 15A-15D are diagrams of an example implementation 1500 of a through-substrate interconnect formation process described herein. The example implementation 1500 includes an example of back side processing for the semiconductor device 105. In particular, the example implementation 1500 includes an example of replacing a gate isolation structure 945 from the back side of the semiconductor device 105 with a through-substrate interconnect structure (e.g., a CMG TSV structure). FIGS. 15A-15D are illustrated from the cross-sectional plane C-C in FIG. 2. In some implementations, the operations described in connection with the example implementation 1500 are performed after one or more operations described in connection with FIGS. 1A-11H.

As shown in FIGS. 15A-15D, the example implementation 1500 is similar to the example implementation 1400 in that a recess 1405 is formed from the back side of the semiconductor device 105 through the hard mask layer 1135, a gate isolation structure 945 is removed through the recess 1405 in the back side of the semiconductor device 105 using a self-aligned etch technique, and a through-substrate interconnect structure 1410 and the associated liner(s) 1415 are formed in the recess 1405.

However, in the example implementation 1500, an overlay shift occurs during formation of the recess 1405, resulting in the recess 1405 being partially laterally offset relative to the gate isolation structure 945. Thus, a portion of the material of one or more STI regions 175 may be exposed through the recess 1405. The use of the self-aligned etch technique enables the gate isolation structure 945 to be removed through the recess 1405, even where overlay shift occurs, with minimal to no etching of the STI regions 175. This is achieved through the use of different materials for the STI regions 175 and the gate isolation structure 945, in combination with an etchant that selectively etches the material of the gate isolation structure 945 with minimal to no etching of the material of the STI regions 175.

As shown in FIG. 15D, the portion of the through-substrate interconnect structure 1410 formed through the hard mask layer 1135 is partially laterally offset relative to the portion of the through-substrate interconnect structure 1410 formed in the area previously occupied by the gate isolation structure 945. The liner(s) 1415 may be prevent, minimize, and/or otherwise reduce the likelihood of material migration from the through-substrate interconnect structure 1410 into the portions of the STI regions 175 that were exposed through the recess 1405.

As indicated above, FIGS. 15A-15D are provided as an example. Other examples may differ from what is described with regard to FIGS. 15A-15D.

FIGS. 16A-16F are diagrams of an example implementation 1600 of a gate isolation structure formation process described herein. The example implementation 1600 includes an example of forming a gate isolation structure (e.g., a CMG structure) in the semiconductor device 105 after the replacement gate process described in connection with FIGS. 8A-8E and prior to a BEOL process to form an interconnect layer of the semiconductor device 105. The example implementation 1600 of the gate isolation structure formation process is different than the example implementation 900 of the gate isolation structure formation process in that the example implementation 1600 of the gate isolation structure formation process includes forming a “selective” or self-aligned gate isolation recess for the gate isolation structure.

FIGS. 16A-16F are illustrated from the perspective of the cross-sectional plane D-D in FIG. 2. In some implementations, the operations described in connection with the example implementation 1600 are performed after the operations described in connection with FIGS. 1A-8E. In these implementations, the semiconductor device 105 may include one or more active region isolation structures 740. In some implementations, the operations described in connection with the example implementation 800 shown in FIGS. 8A-8E are omitted. In these implementations, the active region isolation structures 740 are omitted from the semiconductor device 105.

As shown in FIG. 16A, the hard mask layer 905 may be formed over and/or on the ILD layer 605 in a similar manner as described in connection with FIGS. 9A and 9B, and/or over and/or on the gate structures 810. As further shown in FIG. 16A, the hard mask layer 905 may be etched (e.g., using a pattern 930 formed using a patterning stack 910 as described in connection with FIGS. 9C-9F) to form the gate isolation recess 935 in the hard mask layer 905.

As shown in FIG. 16B, one or more gate structures 810 may be etched to extend the gate isolation recess 935 down through one or more STI regions 175 under the one or more gate structures 810. As further shown in FIG. 16B, the gate isolation recess 935 is selectively formed in that the gate isolation recess 935 is formed by selectively etching the gate structure(s) 810 with minimal to no etching of the ILD layer 605. This results in gate isolation recess 935 having a plurality of trenches 1605 separated by the ILD layer 605. The selective etch may be performed using an etchant that selectively etches the material of the gate structure(s) 810 with minimal to no etching of the ILD layer 605.

As shown in FIG. 16C, the dielectric liner 940 and a plurality of gate isolation structures 945 are formed in the trenches 1605 of the gate isolation recess 935.

As shown in FIG. 16D, a planarization operation may be performed to planarize the semiconductor device 105 such that the plurality of gate isolation structures 945 are separated.

As shown in FIG. 16E, conductive structures 1030 may be formed over one or more of the gate isolation structures 945 in a similar manner as described in connection with FIGS. 10A-10C.

As shown in FIG. 16F, the gate isolation structures 945 may be replaced with through-substrate interconnect structures 1410 in a similar manner as described in connection with FIGS. 14A-14D and/or FIGS. 15A-15D.

As indicated above, FIGS. 16A-16F are provided as an example. Other examples may differ from what is described with regard to FIGS. 16A-16F.

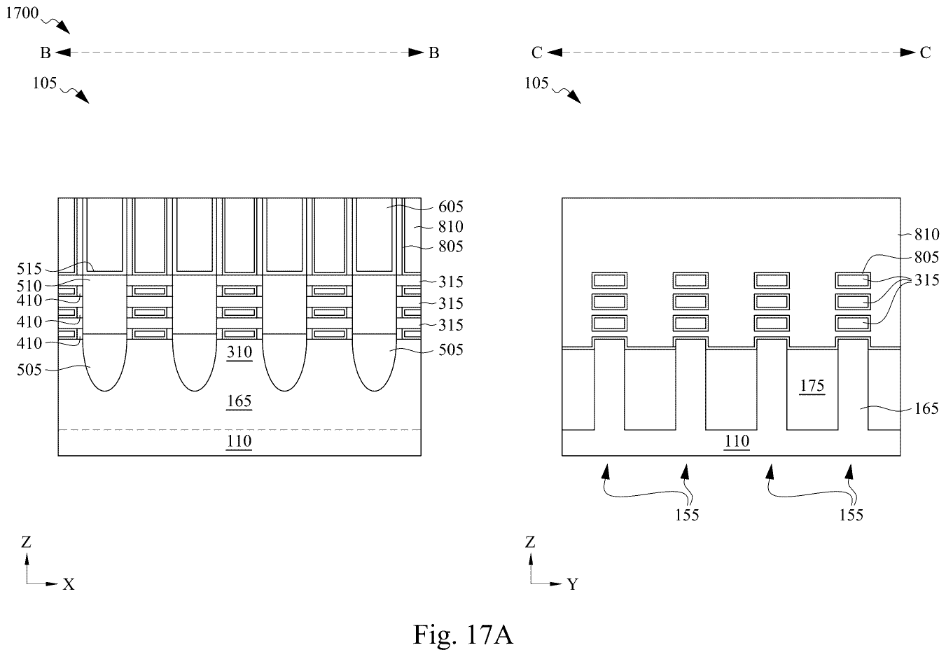

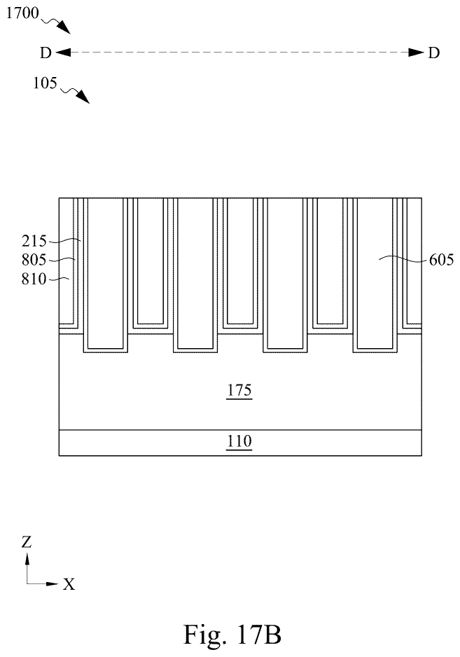

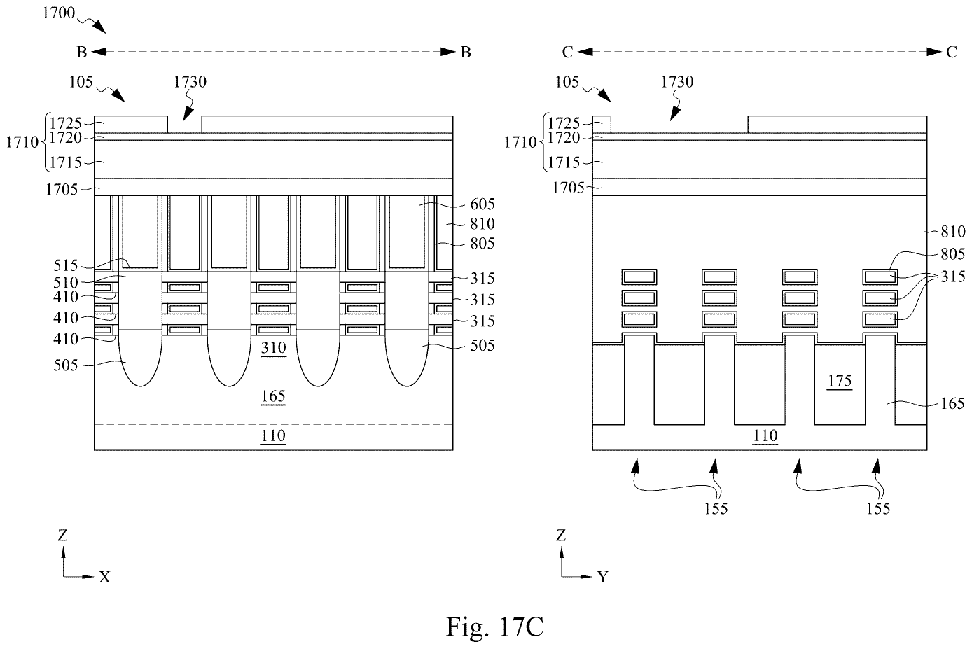

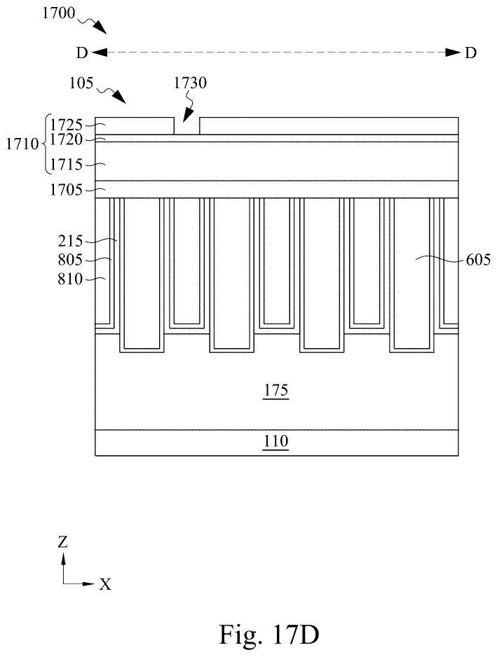

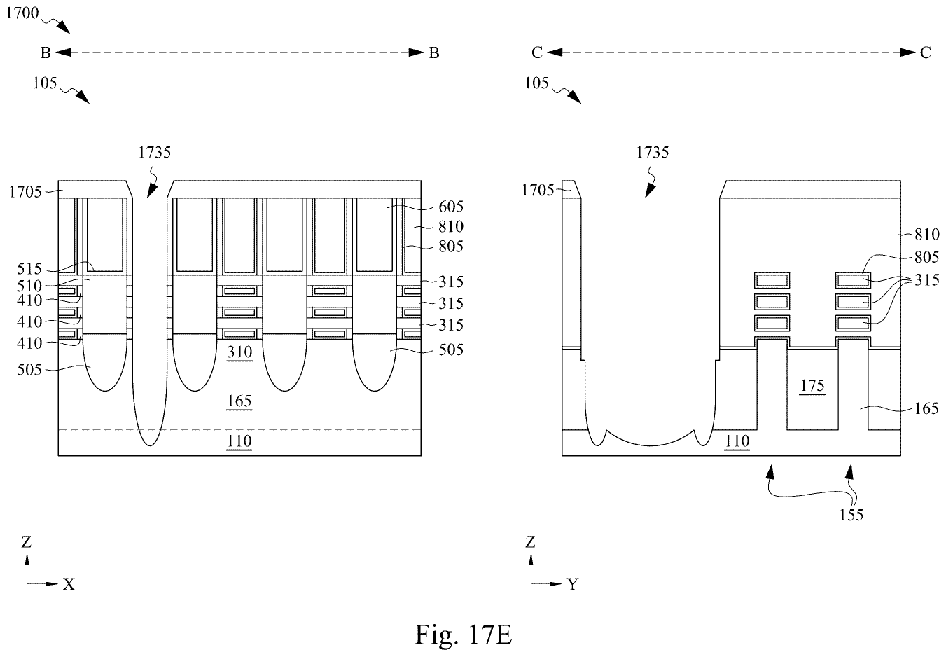

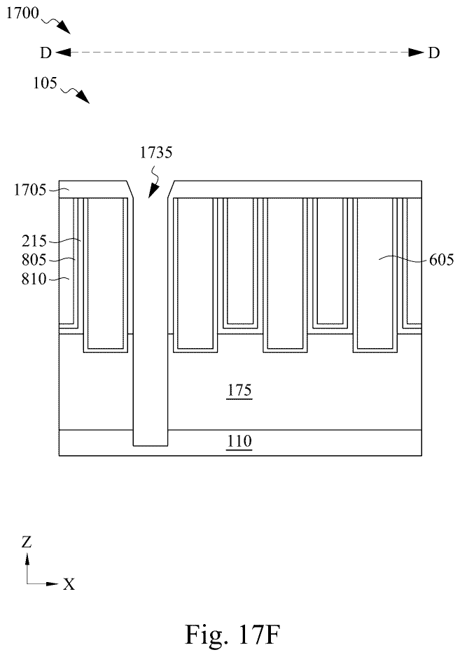

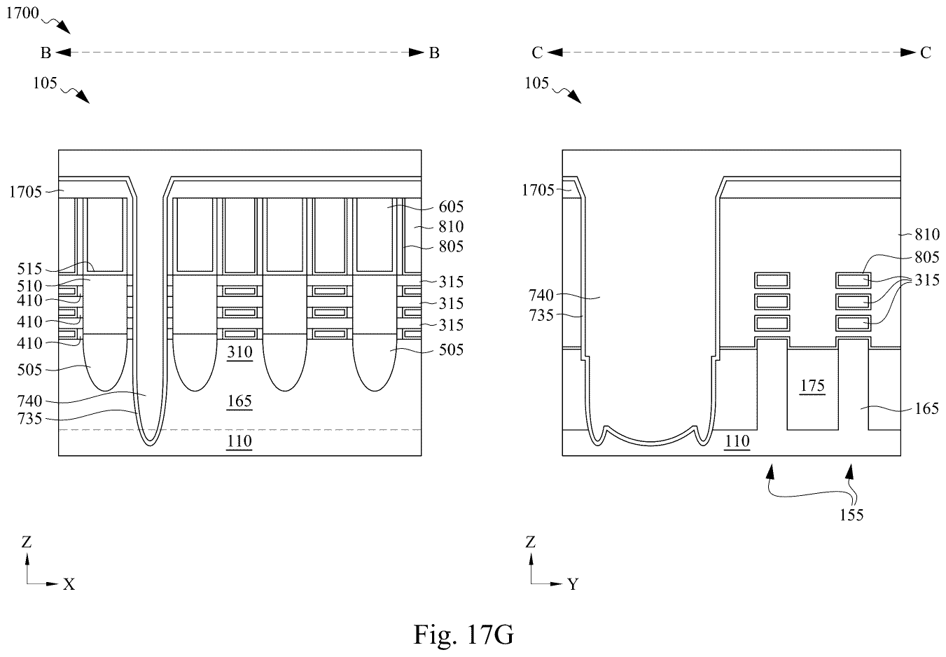

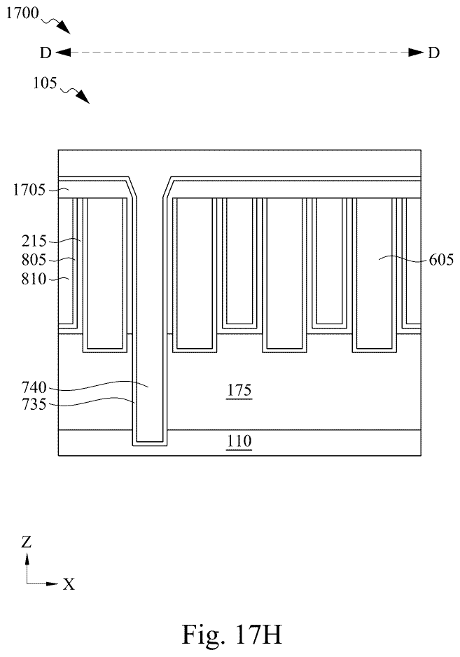

FIGS. 17A-17I are diagrams of an example implementation 1700 of an active region isolation structure formation process described herein. The example implementation 1700 is different than the example implementation 700 of the active region isolation structure formation process described in connection with FIGS. 7A-7N in that the example implementation 1700 includes an example of forming an active region isolation structure 740 after the replacement gate process described in connection with FIGS. 8A-8E, as opposed to prior to the replacement gate process. Accordingly, the example implementation 1700 of the active region isolation structure formation process may be referred to as a CMODE process in that the active region isolation structure 740 is formed through one or more gate structures 810 as opposed to one or more gate structures 810 being formed around the active region isolation structure 740.

FIGS. 17A-17I are illustrated from a plurality of perspectives illustrated in FIG. 2, including the perspective of the cross-sectional plane B-B in FIG. 2, the perspective of the cross-sectional plane C-C in FIG. 2, and/or the perspective of the cross-sectional plane D-D in FIG. 2.

As shown in FIGS. 17A and 17B, the operations described in connection with the example implementation 1700 are performed after the replacement gate process described in connection with FIGS. 8A-8E.

As shown in FIGS. 17C and 17D, a hard mask layer 1705 may be formed over and/or on the front side of the semiconductor device 105. A deposition tool may be used to deposit the hard mask layer 1705 using a PVD technique, an ALD technique, a CVD technique, an oxidation technique, and/or another suitable deposition technique. In some implementations, a planarization tool may be used to planarize the hard mask layer 1705 after the hard mask layer 7105 is deposited.

As further shown in FIGS. 17C and 17D, a patterning stack 1710 may be formed over and/or on the hard mask layer 1705. The patterning stack 1710 may be used to pattern the hard mask layer 1705 for forming an active region isolation recess. The patterning stack 1710 may include one or more masking layers, such as a bottom layer 1715, a middle layer 1720, and a top layer 1725. The bottom layer 1715 may include a carbon-containing material and/or another suitable material. The middle layer 1720 may include an oxide-containing material and/or another suitable material. The top layer 1725 may include a photoresist layer that is used to transfer a pattern 1730 to the bottom layer 1715 and middle layer 1720. The different materials of the bottom layer 1715 and middle layer 1720 provide etch selectivity between the bottom layer 1715 and middle layer 1720, which enables the aspect ratio of the pattern 1730 to be tightly controlled.

A deposition tool may be used to deposit the bottom layer 1715 and the middle layer 1720 using a PVD technique, an ALD technique, a CVD technique, an oxidation technique, and/or another suitable deposition technique. In some implementations, a planarization tool may be used to planarize the bottom layer 1715 and/or the middle layer 1720 after the bottom layer 1715 and/or the middle layer 1720 are deposited. A deposition tool may be used to deposit the top layer 1725 using a spin coating technique and/or another suitable deposition technique.

As shown in FIGS. 17E and 17F, the pattern 1730 may be used to form an active region isolation recess 1735 (e.g., a CMODE recess) through the hard mask layer 1705, through one or more fin portions 165, through one or more STI regions 175, through one or more stacks of nanostructure channels 315, and/or through one or more gate structures 810. The active region isolation recess 1735 may extend into the semiconductor substrate 110 of the semiconductor device 105.

As shown in FIGS. 17G and 17H, a dielectric liner 735 and an active region isolation structure 740 may be formed in the active region isolation recess 1735. The dielectric liner 735 and the active region isolation structure 740 may be formed in a similar manner as described in connection with FIGS. 7A-7N.

As shown in FIG. 17I, the active region isolation structure 740 may be subsequently replaced with a through-substrate interconnect structure 1210 in a similar manner as described in connection with FIGS. 12A-12D and/or 13A-13D.

As indicated above, FIGS. 17A-17I are provided as an example. Other examples may differ from what is described with regard to FIGS. 17A-17I.

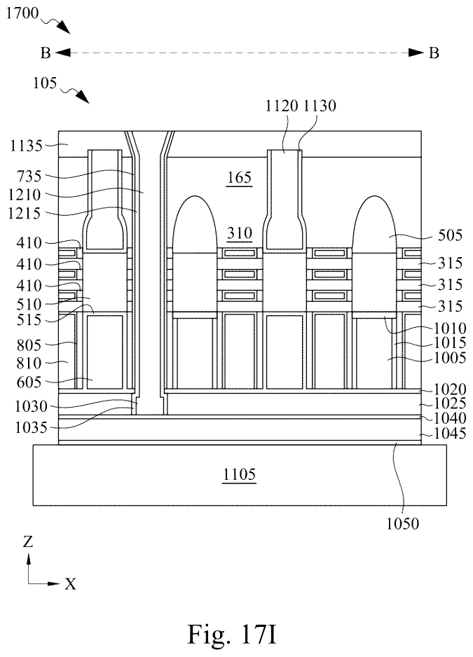

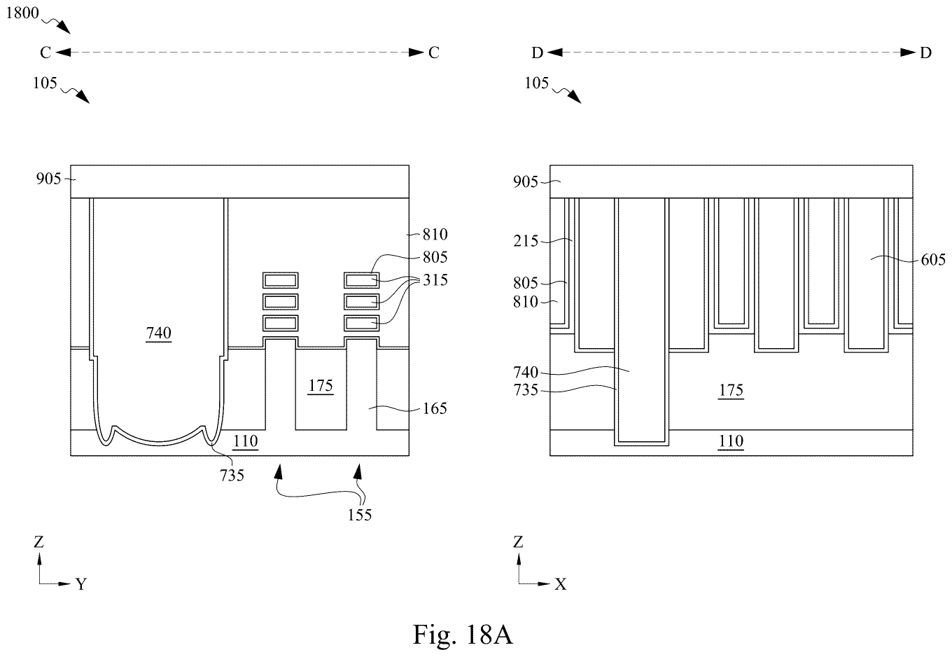

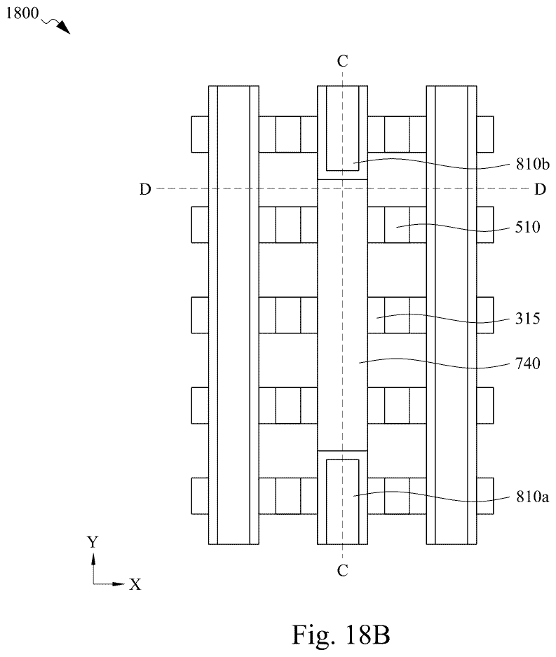

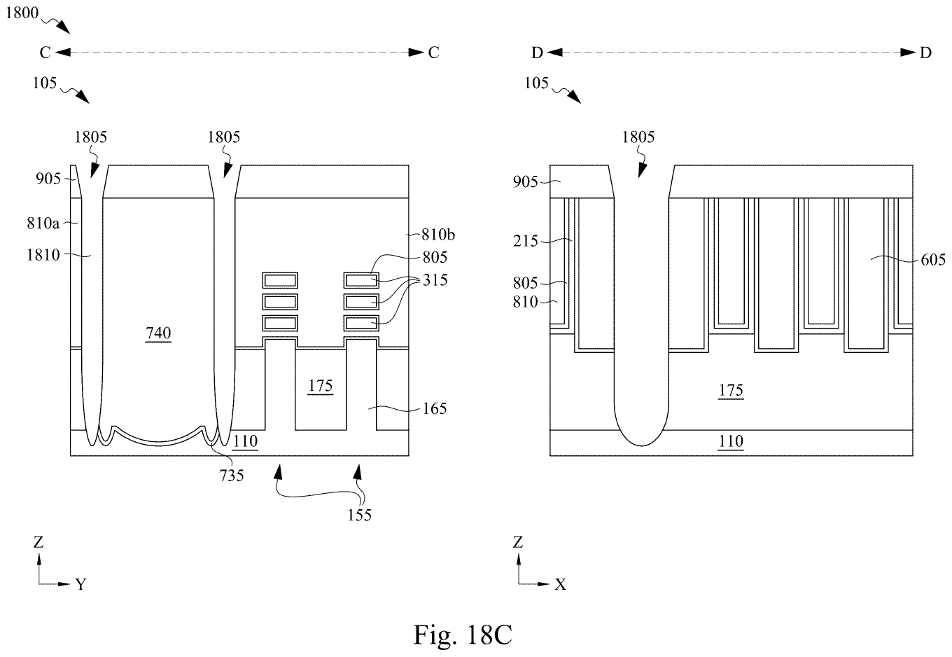

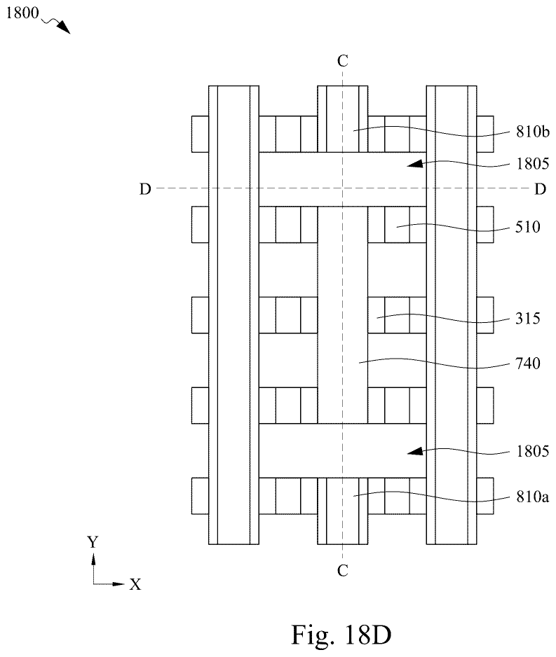

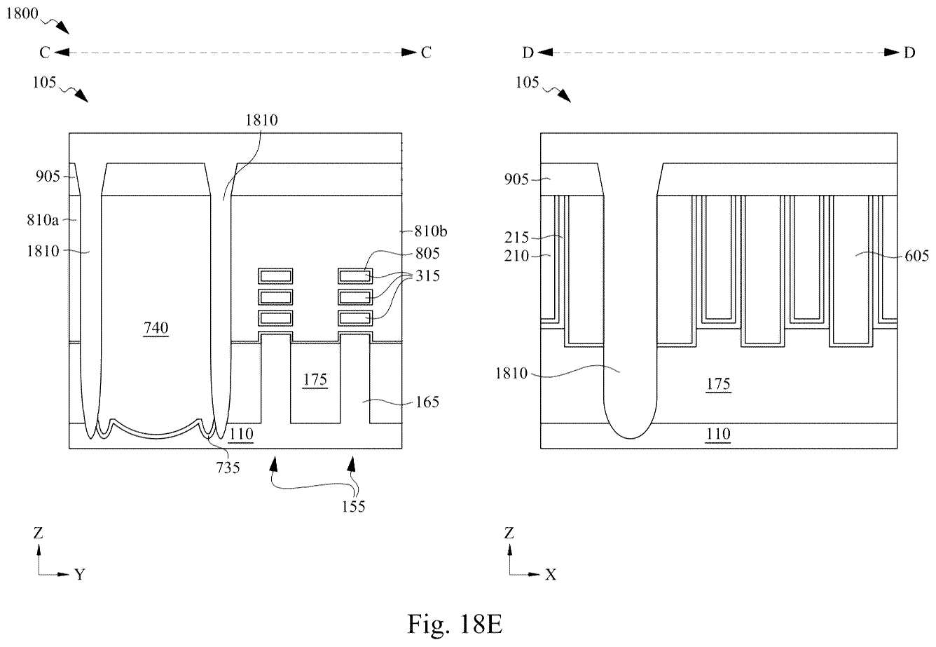

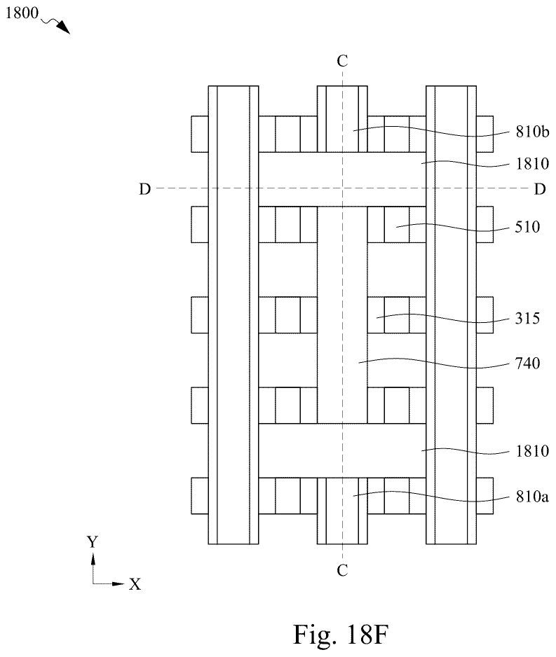

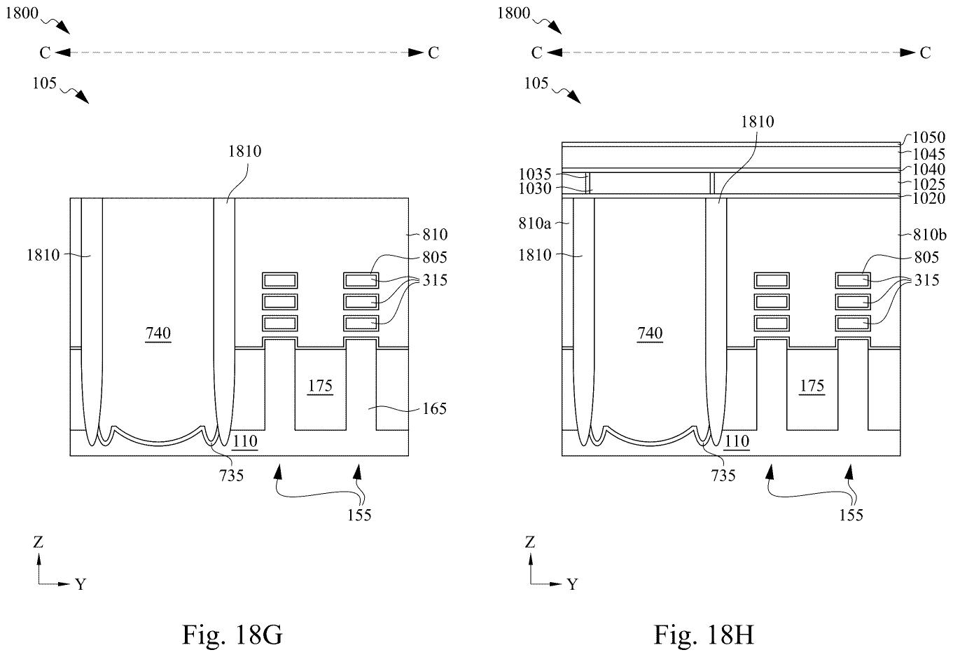

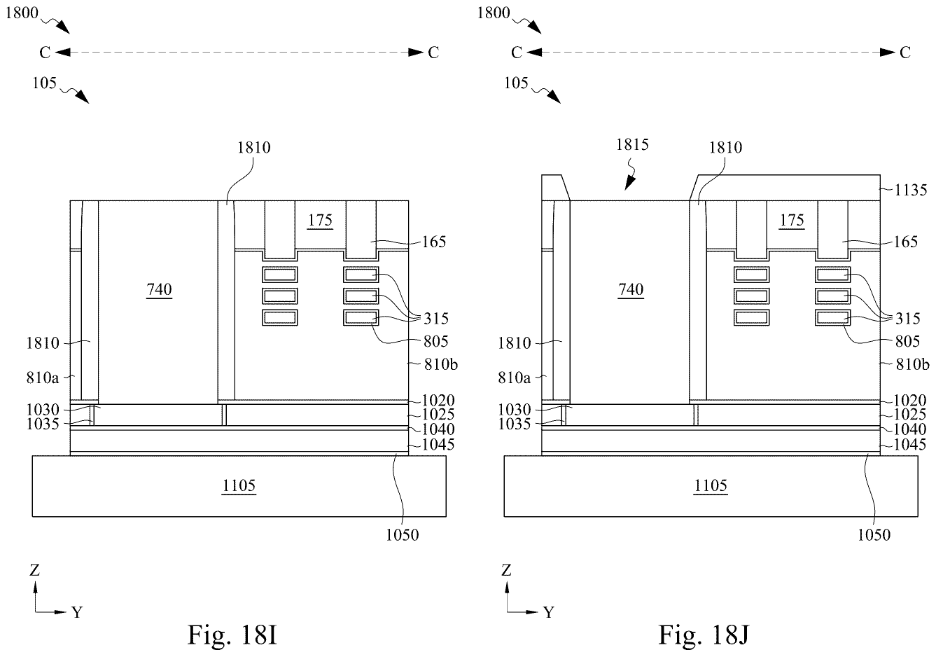

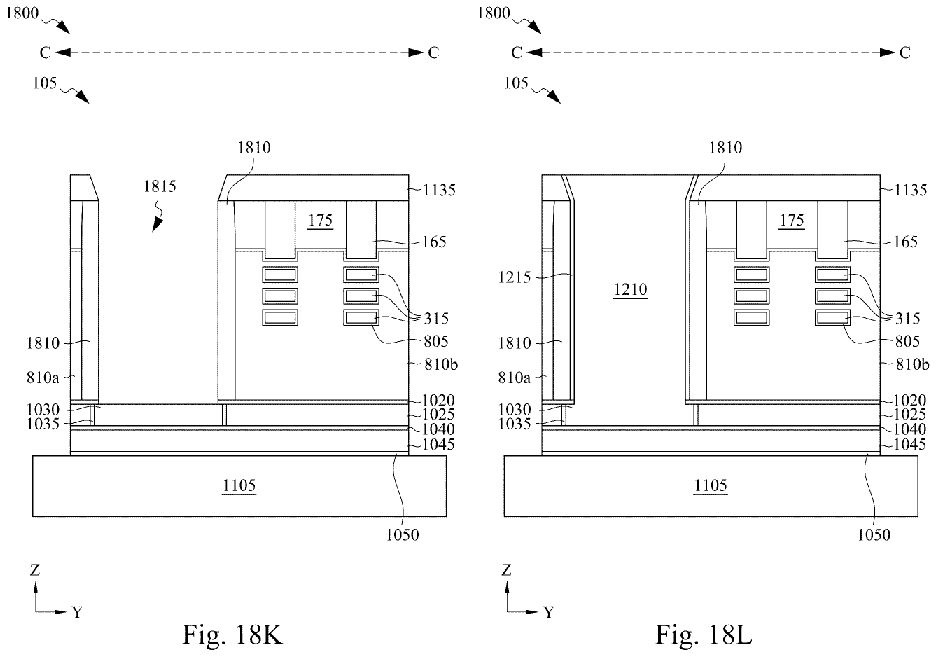

FIGS. 18A-18L are diagrams of an example implementation 1800 of a gate isolation structure formation process described herein. In particular, the example implementation 1800 is an example of forming gate isolation structures on opposing sides of an active region isolation structure 740. The active region isolation structure 740 may be subsequently replaced with a through-substrate interconnect structure 1210, and therefore the gate isolation structures provide electrical isolation and further assist with the self-aligned formation of the through-substrate interconnect structure 1210.

FIGS. 18A-18L are illustrated from a plurality of perspectives illustrated in FIG. 2, including the perspective of the cross-sectional plane C-C in FIG. 2 and/or the perspective of the cross-sectional plane D-D in FIG. 2. Moreover, one or more of FIGS. 18A-18L illustrate additional top views of the semiconductor device 105.

As shown in FIG. 18A, an active region isolation structure 740 may be formed in a similar manner as described in connection with FIGS. 7A-7N, FIGS. 17A-17I, and/or elsewhere herein.

As shown in FIG. 18B, the active region isolation structure 740 may extend in the y-direction in the semiconductor device 105 across one or more stacks of nanostructure channels 315. The active region isolation structure 740 may extend between one or more pairs of source/drain regions 510 and may be located between gate structures 810a and 810b in the y-direction. In particular, the active region isolation structure 740 may have been formed to replace a segment of a gate structure 810 that extends in the y-direction to form the gate structures 810a and 810b that are electrically isolated from each other by the active region isolation structure 740.

As shown in FIG. 18C, the gate isolation recesses 1805 may be formed on opposing sides of the active region isolation structure 740 in the y-direction. The gate isolation recesses 1805 may extend through the gate structures 810a and 810b, and may extend through one or more STI regions 175 and into the semiconductor substrate 110. An etch tool may be used to perform a dry etch operation (e.g., a plasma-based etch operation, a gas-based etch operation), a wet etch operation, and/or another type of etch operation to form the gate isolation recesses 1805.

As shown in FIG. 18D, in the top view of the semiconductor device 105, the gate isolation recesses 1805 may be located at opposing ends of the active region isolation structure 740 in the y-direction, and may be located between a plurality of stacks of nanostructure channels 315 in the y-direction. In some implementations, the gate isolation recesses 1805 may extend between opposing gate structures 810 in the x-direction.

As shown in FIG. 18E, the gate isolation recesses 1805 may be filled in with dielectric material to form gate isolation structures 1810 on opposing sides of the active region isolation structure 740. The gate isolation structures 1810 may extend through the gate structures 810a and 810b, through one or more STI regions 175, and into the semiconductor substrate 110. The dielectric material of the gate isolation structures 1810 may be different from the dielectric material of the active region isolation structure 740 so that the active region isolation structure 740 may be selectively etched to subsequently remove the active region isolation structure 740, so that a through-substrate interconnect structure 1210 can be formed between the gate isolation structures 1810.

A deposition tool may be used to deposit the dielectric material of the gate isolation structures 1810 in the gate isolation recesses 1805 using a PVD technique, an ALD technique, a CVD technique, an oxidation technique, and/or another suitable deposition technique.

As shown in FIG. 18F, the gate isolation structures 1810 are located on opposing sides of the active region isolation structure 740 in the y-direction. A gate isolation structure 1810 may be located laterally between the active region isolation structure 740 and the gate structure 810a in the y-direction, and another gate isolation structure 1810 may be located laterally between the active region isolation structure 740 and the gate structure 810b in the y-direction.

As shown in FIG. 18G, a planarization tool may be used to planarize the semiconductor device 105 to remove excess material of the gate isolation structures 1810 and/or to remove the hard mask layer 905.

As shown in FIG. 18H, a conductive structure 1030 may be formed above the front side of the semiconductor device 105 on the active region isolation structure 740 in a similar manner as described on connection with FIGS. 10A-10C.

As shown in FIG. 18I, the semiconductor device 105 may be flipped and placed on the carrier substrate 1105, and the back side of the semiconductor device 105 may be planarized in a similar manner as described in connection with FIGS. 11A-11H to expose the bottom of the active region isolation structure 740. In some implementations, the bottoms of the gate isolation structures 1810 are also planarized in the planarization operation.

As shown in FIG. 18J, the hard mask layer 1135 may be formed over the back side of the semiconductor device 105. A recess 1815 may be formed in the hard mask layer 1135 to expose the bottom of the active region isolation structure 740 in a similar manner as the recess 1205.

As shown in FIG. 18K, the active region isolation structure 740 may be removed through the recess 1815 in a similar manner as described in connection with FIGS. 12A-12D and/or 13A-13D. The gate isolation structures 1810 may define the ends of the recess 1815.

As shown in FIG. 18L, a through-substrate interconnect structure 1210 and the associated liners 1215 may be formed in the recess 1815 such that the through-substrate interconnect structure 1210 is located laterally between the gate isolation structures 1810. The through-substrate interconnect structure 1210 may be formed in a similar manner as described in connection with FIGS. 12A-12D and/or 13A-13D.

As indicated above, FIGS. 18A-18L are provided as an example. Other examples may differ from what is described with regard to FIGS. 18A-18L.

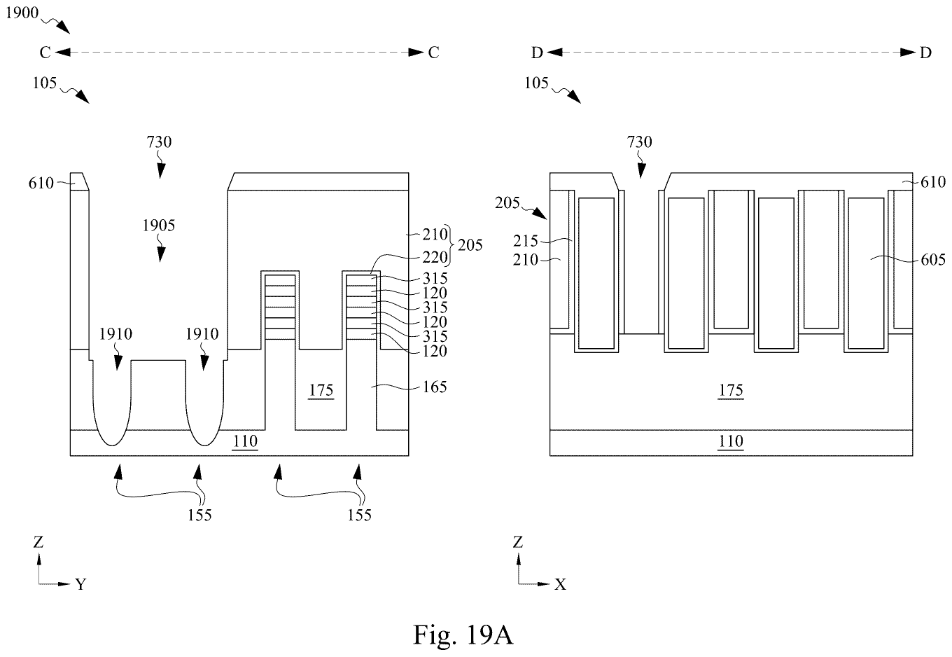

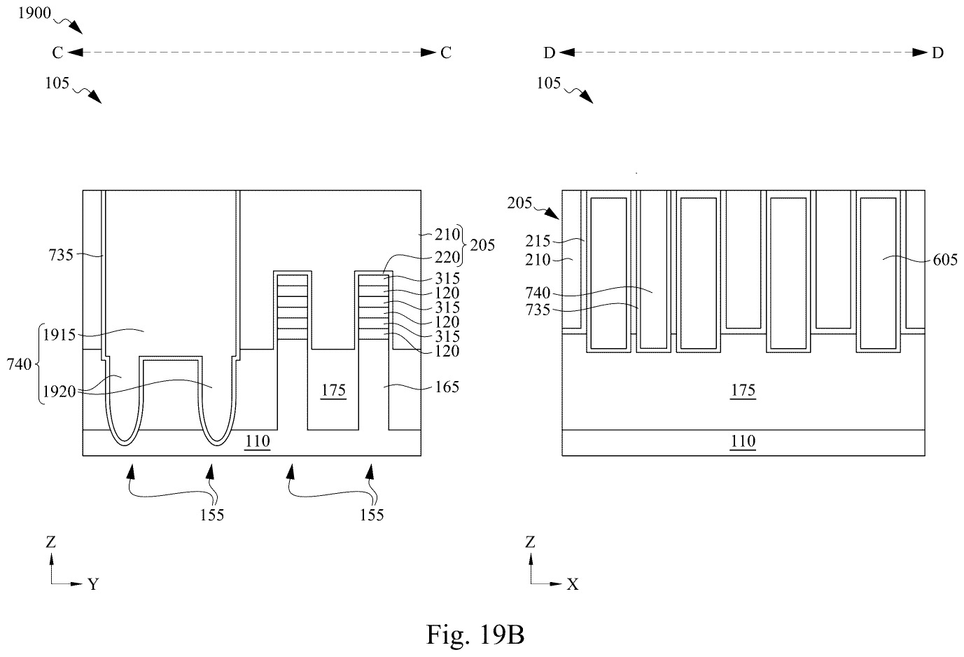

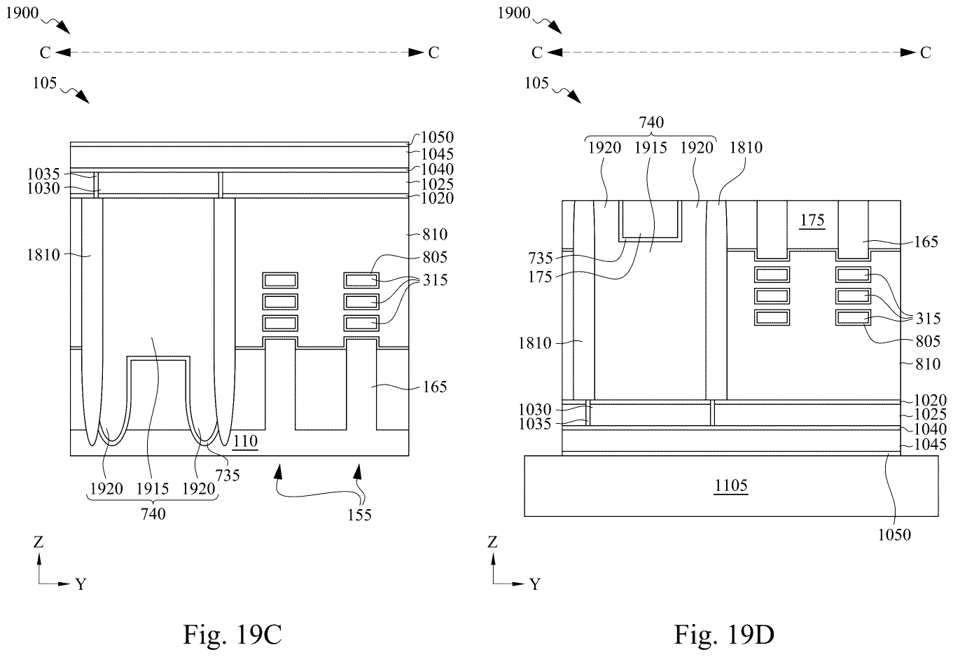

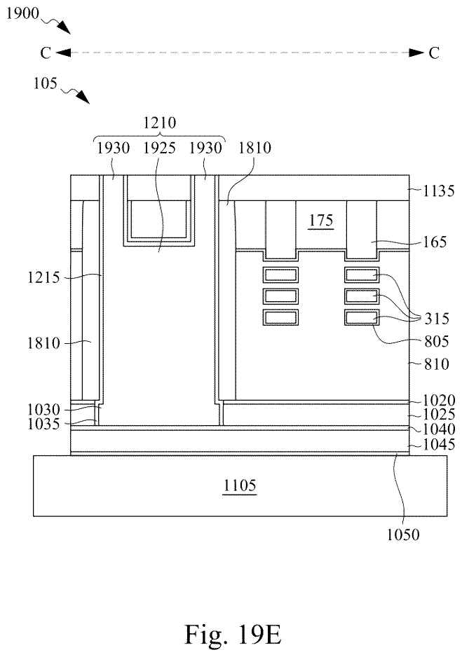

FIGS. 19A-19E are diagrams of an example implementation 1900 of a gate isolation structure formation process described herein. In particular, the example implementation 1900 is an example of forming gate isolation structures on opposing sides of an active region isolation structure 740. The active region isolation structure 740 may be subsequently replaced with a through-substrate interconnect structure 1210, and therefore the gate isolation structures provide electrical isolation and further assist with the self-aligned formation of the through-substrate interconnect structure 1210.

As shown in FIGS. 19A-19E, the example implementation 1900 is similar to the example implementation 1800 is an example of forming gate isolation structures. However, as shown in FIG. 19A, the active region isolation recess 730 is selectively formed with minimal to no etching of the underlying STI regions 175. As a result, the active region isolation recess 730 includes a main trench 1905 that extends through a dummy gate structure 205 and one or more stacks of nanostructure channels 315, and one or more extension vias 1910 that extend through one or more fin portions 165 of one or more fin structures 155 and into the semiconductor substrate 110. An etchant may be used to form the active region isolation recess 730 that exhibits minimal to no etching of the STI regions 175.

As shown in FIG. 19B, the resulting active region isolation structure 740 formed in the active region isolation recess 730 has a main body 1915 that is formed in the main trench 1905 of the active region isolation recess 730, and extension regions 1920 that are formed in the extension vias 1910 of the active region isolation recess 730.

As shown in FIG. 19C, gate isolation structures 1810 may be formed on opposing ends of the active region isolation structure 740 in a similar manner as described in connection with FIGS. 18A-18L. As further shown in FIG. 19C, a conductive structure 1030 may be formed above the front side of the semiconductor device 105 on the active region isolation structure 740 in a similar manner as described on connection with FIGS. 10A-10C.

As shown in FIG. 19D, the semiconductor device 105 may be flipped and placed on the carrier substrate 1105, and the back side of the semiconductor device 105 may be planarized in a similar manner as described in connection with FIGS. 11A-11H to expose the bottoms of the extension regions 1920 of the active region isolation structure 740. In some implementations, the bottoms of the gate isolation structures 1810 are also planarized in the planarization operation.

As shown in FIG. 19E, the hard mask layer 1135 may be formed over the back side of the semiconductor device 105. A plurality of recesses may be formed in the hard mask layer 1135 to expose the bottoms of the extension regions 1920 of the active region isolation structure 740 in a similar manner as the recess 1205. The active region isolation structure 740 may be removed through the recesses in a similar manner as described in connection with FIGS. 12A-12D and/or 13A-13D, and a through-substrate interconnect structure 1210 and the associated liners 1215 may be formed in the recess such that the through-substrate interconnect structure 1210 is located laterally between the gate isolation structures 1810. The through-substrate interconnect structure 1210 may be formed in a similar manner as described in connection with FIGS. 12A-12D and/or 13A-13D, and may include a main body 1925 and extension via structures 1930.

As indicated above, FIGS. 19A-19E are provided as an example. Other examples may differ from what is described with regard to FIGS. 19A-19E.

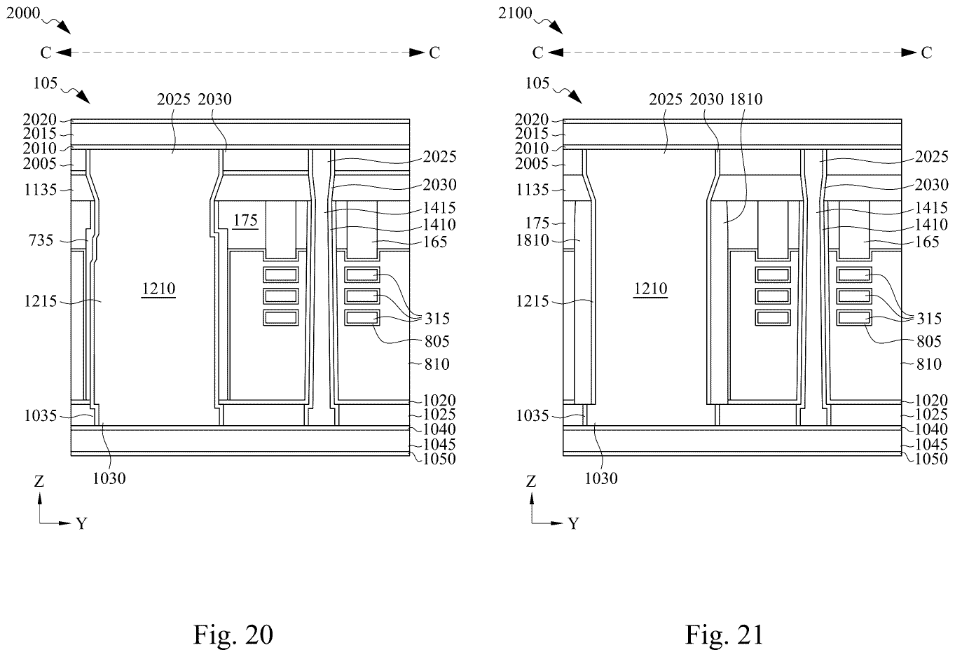

FIG. 20 is a diagram of an example implementation 2000 of an interconnect layer formation process described herein. The example implementation 2000 includes an example of BEOL process for forming dielectric layers and conductive structures of a back side interconnect layer (e.g., an interconnect layer on the back side of the semiconductor device 105). FIG. 20 is illustrated from the perspective of the cross-sectional plane C-C in FIG. 2. In some implementations, the operations described in connection with the example implementation 2000 are performed after one or more operations described in connection with FIGS. 1A-15D.

As shown in FIG. 20, a plurality of dielectric layers may be formed above the hard mask layer 1135 over the back side of the semiconductor device 105. For example, an ILD layer 2005 may be formed over and/or on the hard mask layer 1135. As another example an ESL 2010 may be formed over an/or on the ILD layer 2005. As another example, an ILD layer 2015 may be formed over and/or on the ESL 2010. As another example, an ESL 2020 may be formed over and/or on the ILD layer 2015. In some implementations, additional ILD layers and additional ESLs may be formed over the back side of the semiconductor device 105.

A deposition tool may be used to deposit the ILD layers 2005, 2015 and/or the ESLs 2010, 2020 using a PVD technique, an ALD technique, a CVD technique, an oxidation technique, and/or another suitable deposition technique. In some implementations, a planarization tool may be used to perform a planarization operation (e.g., a CMP operation) to planarize the ILD layers 2005, 2015 and/or the ESLs 2010, 2020 after the ILD layers 2005, 2015 and/or the ESLs 2010, 2020 are deposited.

The ILD layers 2005 and 2015 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the ILD layers 2005, 2015 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 2010 and 2020 may include a silicon nitride (SiₓN_{y}), silicon carbide (SiC), silicon oxynitride (SiON), and/or another suitable dielectric material. In some implementations, the ESLs 2010 and 2020 and the ILD layers 2005 and 2015 include different dielectric materials to provide etch selectivity to enable various structures to be formed in the back side interconnect layer.

As further shown in FIG. 20, conductive structures 2025 of the back side interconnect layer may be formed in and/or through the ILD layer 605. In some implementations, one or more of the conductive structures 2025 may be formed on (e.g., may land on) a through-substrate interconnect structure 1210. In some implementations, one or more of the conductive structures 2025 may be formed on (e.g., may land on) a through-substrate interconnect structure 1210. In some implementations, one or more of the conductive structures 2025 may be formed on (e.g., may land on) a source/drain contact 1120 (not shown).

The conductive structures 2025 may be similar to the conductive structures 1030 on the front side of the semiconductor device 105, and may include a combination of metallization structures and interconnect structures. The metallization structures may include trenches, metallization layers, conductive traces, and/or other types of metallization structures. The interconnect structures may include vias, plugs, interconnects, and/or another type of interconnect structures. The conductive structures 2025 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liners 2030 are included on sidewalls of the conductive structures 2025. The one or more liners 2030 may include barrier liners, adhesion liners, and/or another type of liners. Examples of materials for the one or more liners 2030 include tantalum nitride (TaN) and/or titanium nitride (TiN), among other examples.

In some implementations, the conductive structures 2025 of the back side interconnect layer may be arranged in a plurality of layers that are arranged in a vertical manner (e.g., in the z-direction) in the back side interconnect layer. In other words, a plurality of layers of conductive structures 2025 may extend above the back side of the semiconductor device 105. The conductive structures 2025 may include metallization structures that are arranged in metallization layers referred to as M-layers. For example, a metal-0 (M0) layer that includes a plurality of conductive structures 2025 (e.g., metallization structures) may be located at the bottom of the back side interconnect layer and may be directly coupled with the through-substrate interconnect structures 1210, 1410 and/or with the source/drain contacts 1120 (not shown). A via-1 (V1) layer that includes a plurality of conductive structures 2025 (e.g., interconnect structures) may be included above the M0 layer. A metal-1 layer (M1) layer that includes a plurality of conductive structures 2025 (e.g., metallization structures) may be located above the V1 layer in the back side interconnect layer, a via-2 (V2) layer that includes a plurality of conductive structures 2025 (e.g., interconnect structures) may be included above the M1 layer, a metal-2 layer (M2) layer that includes a plurality of conductive structures 2025 (e.g., metallization structures) may be located above the V2 layer, and so on.

In this way, the semiconductor device 105 may include a plurality of nanostructure channels 315 arranged in the z-direction. The semiconductor device 105 may include a source/drain region 510 adjacent to first ends of the nanostructure channels 315 and a source/drain region 510 adjacent to second ends of the nanostructure channels 315 opposing the first ends in in the x-direction. The semiconductor device 105 may include a gate structure 810 extending between the source/drain regions 510 in the y-direction, and the gate structure 810 may wrap around the nanostructure channels 315.

In some implementations, the semiconductor device 105 includes a through-substrate interconnect structure 1210 extending in the y-direction and that extends from the front side of the semiconductor device 105 to the back side of the semiconductor device 105 such that the through-substrate interconnect structure 1210 is electrically coupled to a conductive structure 1030 on the front side at a first end of the through-substrate interconnect structure 1210, and is electrically coupled to a conductive structure 2025 on the back side at a second end of the through-substrate interconnect structure 1210.

In some implementations, the semiconductor device 105 includes a through-substrate interconnect structure 1410 extending in the x-direction and that extends from the front side of the semiconductor device 105 to the back side of the semiconductor device 105 such that the through-substrate interconnect structure 1410 is electrically coupled to a conductive structure 1030 on the front side at a first end of the through-substrate interconnect structure 1410, and is electrically coupled to a conductive structure 2025 on the back side at a second end of the through-substrate interconnect structure 1410.

In some implementations, the semiconductor device 105 includes one or more through-substrate interconnect structures 1210 and one or more through-substrate interconnect structure 1410.

As indicated above, FIG. 20 is provided as an example. Other examples may differ from what is described with regard to FIG. 20.

FIG. 21 is a diagram of an example implementation 2100 of an interconnect layer formation process described herein. The example implementation 2100 is similar to the example implementation 2000, except that the semiconductor device 105 includes the gate isolation structures 1810 on opposing ends of the through-substrate interconnect structure 1210.

As indicated above, FIG. 21 is provided as an example. Other examples may differ from what is described with regard to FIG. 21.

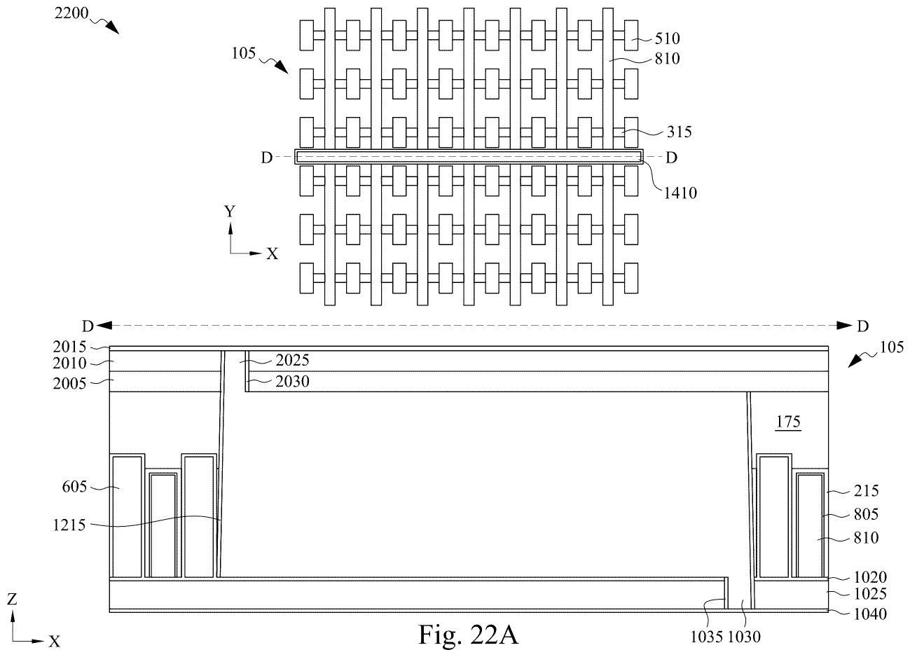

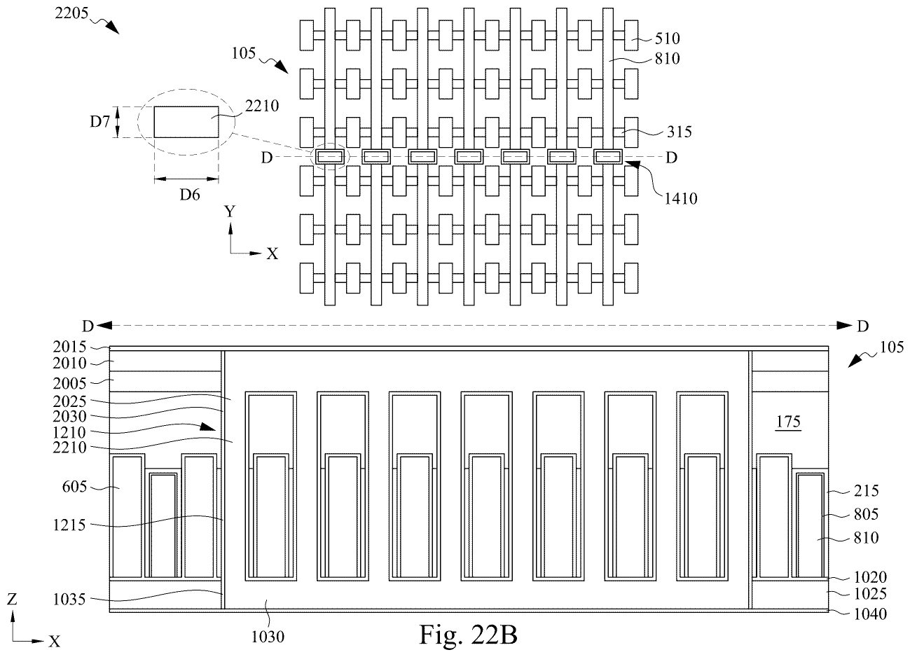

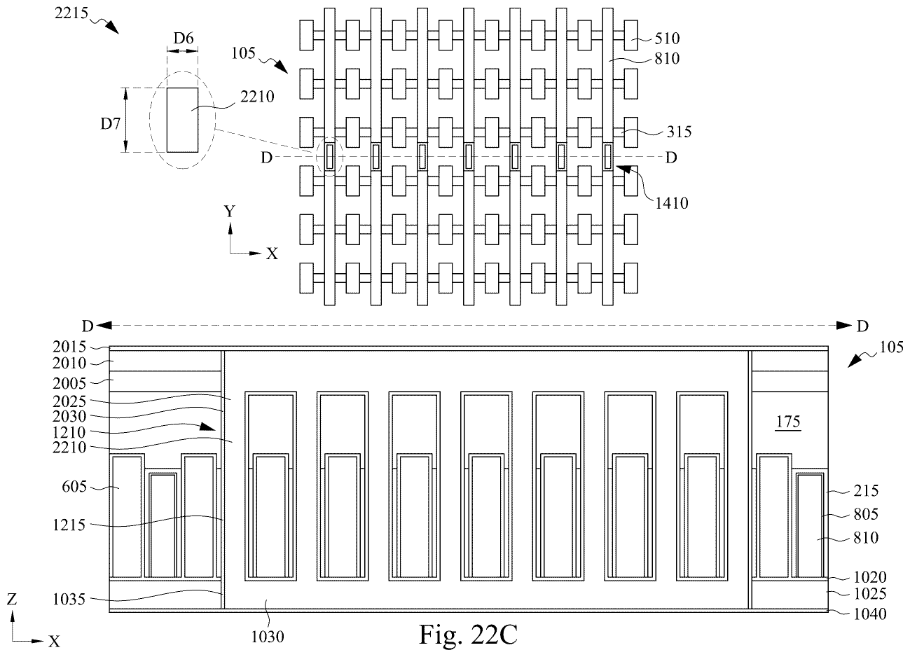

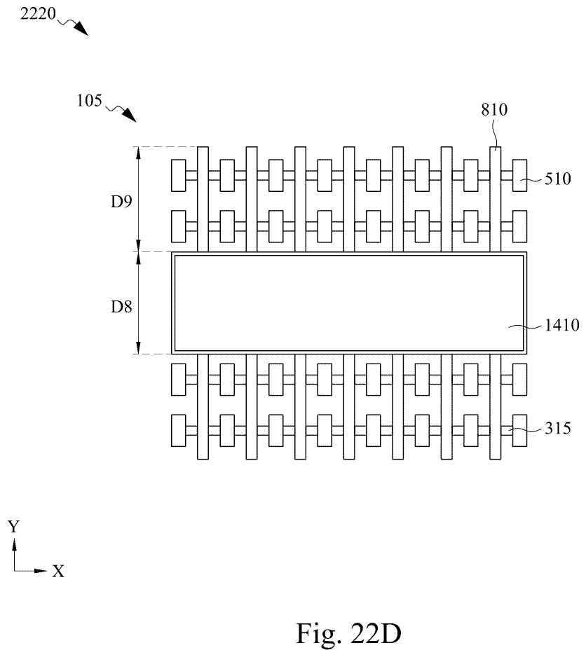

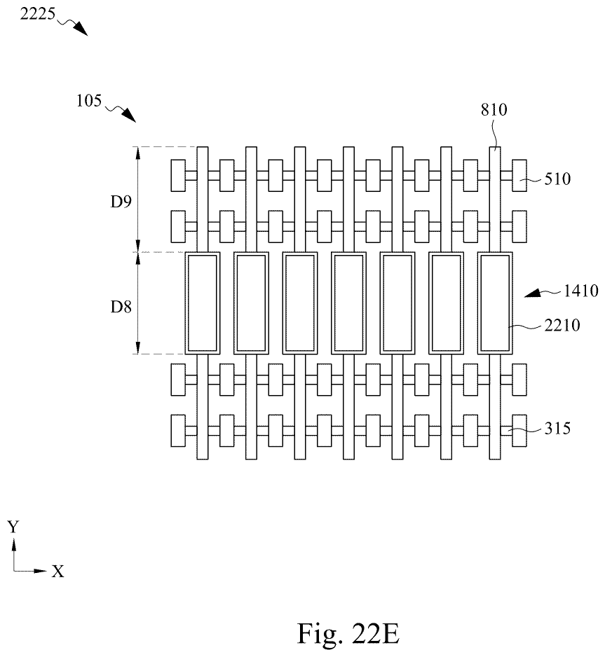

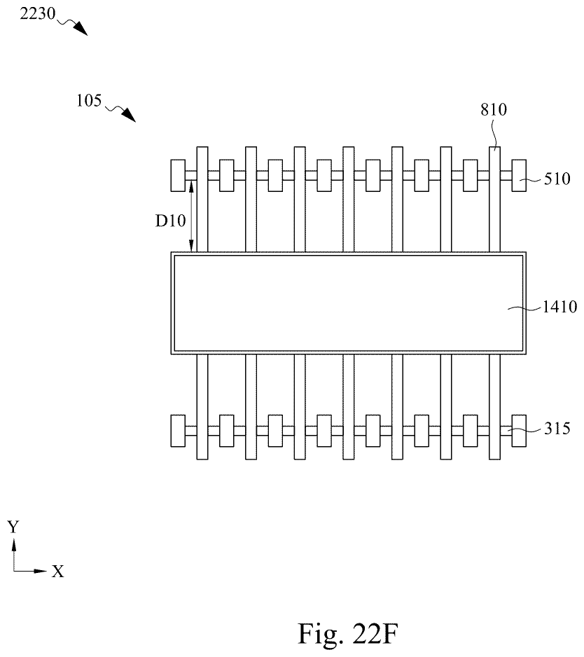

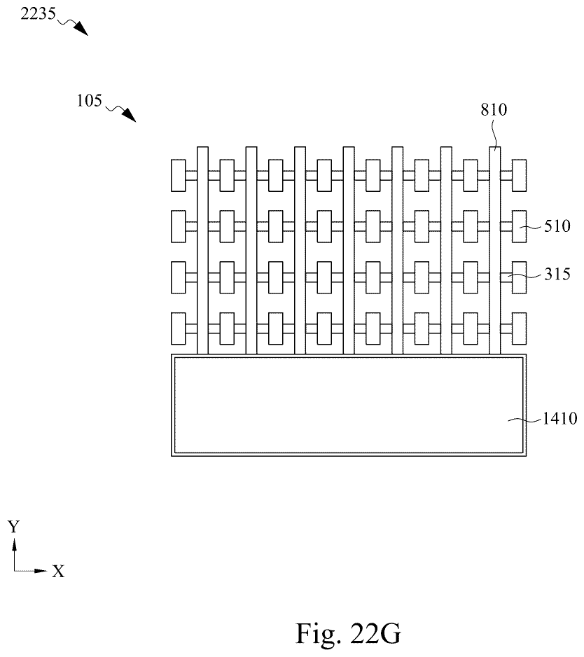

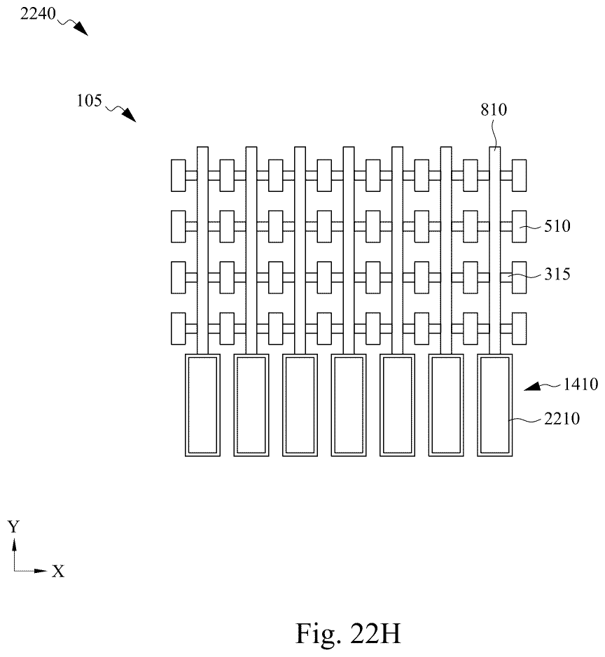

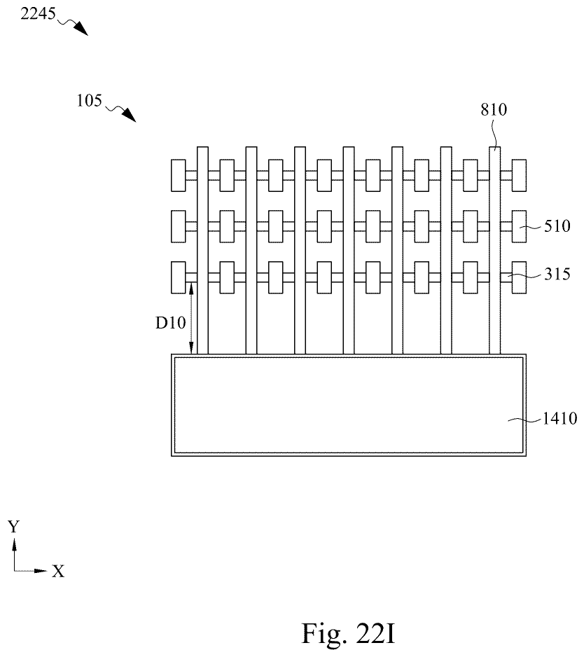

FIGS. 22A-22I are diagrams of example implementations of top view layouts for through-substrate interconnect structures 1410 (e.g., CMG TSVs) in the semiconductor device 105 described herein. The example implementations of top view layouts illustrated in FIGS. 22A-22I are examples, and other example implementations of top view layouts for through-substrate interconnect structure(s) 1410 are within the scope of the present disclosure.

As shown in an example implementation 2200 of a top view layout in FIG. 22A, the semiconductor device 105 may include a plurality of stacks of nanostructure channels 315, a plurality of source/drain regions 510, a plurality of gate structures 810, and one or more through-substrate interconnect structures 1410. A through-substrate interconnect structure 1410 may be located laterally between a first row of a plurality of stacks of nanostructure channels 315 (e.g., that are arranged in the x-direction) and a second row of a plurality of stacks of nanostructure channels 315 (e.g., that are arranged in the x-direction) in the y-direction. As further shown in the top view in FIG. 22A and in the cross-section along the line D-D in FIG. 22A, the through-substrate interconnect structure 1410 may include a continuous structure that extends in the x-direction across a plurality of gate structures 810.

As shown in an example implementation 2205 of a top view layout in FIG. 22B, a through-substrate interconnect structure 1410 may include a plurality of non-contiguous segments 2210 that are arranged in the x-direction. In some implementations, each of the segments 2210 may extend through a respective gate structure 810. In the example implementation 2205, a segment 2210 may have an x-direction width (indicated in FIG. 22B as a dimension D6) that is greater than a y-direction width (indicated in FIG. 22B as a dimension D7) of the segment 2210. As shown in the cross-section along the line D-D in FIG. 22B, the segments 2210 may be electrically coupled to a same conductive structure 1030 and/or may be electrically coupled to a same conductive structure 2025.

As shown in an example implementation 2215 of a top view layout in FIG. 22C, a through-substrate interconnect structure 1410 may include a plurality of non-contiguous segments 2210 that are arranged in the x-direction. In some implementations, each of the segments 2210 may extend through a respective gate structure 810. In the example implementation 2215, a segment 2210 may have an x-direction width (indicated in FIG. 22C as a dimension D6) that is less than a y-direction width (indicated in FIG. 22C as a dimension D7) of the segment 2210. As shown in the cross-section along the line D-D in FIG. 22C, the segments 2210 may be electrically coupled to a same conductive structure 1030 and/or may be electrically coupled to a same conductive structure 2025.

As shown in an example implementation 2220 of a top view layout in FIG. 22D, a through-substrate interconnect structure 1410 may have a y-direction width (indicated in FIG. 22D as a dimension D8) that is approximately equal to a total distance (indicated in FIG. 22D as dimension D9) across a plurality of rows of nanostructure channels 315. This may enable a low electrical resistance to be achieved for the through-substrate interconnect structure 1410.

As shown in an example implementation 2225 of a top view layout in FIG. 22E, a through-substrate interconnect structure 1410 may include a plurality of non-contiguous segments 2210 that are arranged in the x-direction. A segment 2210 may have a y-direction width (indicated in FIG. 22E as a dimension D8) that is approximately equal to a total distance (indicated in FIG. 22E as dimension D9) across a plurality of rows of nanostructure channels 315. This may enable a low electrical resistance to be achieved for the segments 2210 of the through-substrate interconnect structure 1410.

As shown in an example implementation 2230 of a top view layout in FIG. 22F, a through-substrate interconnect structure 1410 may be spaced apart from an adjacent row of nanostructure channels 315 by a distance (indicated in FIG. 22F as dimension D10) corresponding to one or more rows of nanostructure channels 315. This may reduce the likelihood of occurrence of layout-dependent effects for the through-substrate interconnect structure 1410.

As shown in an example implementation 2235 of a top view layout in FIG. 22G, a through-substrate interconnect structure 1410 may be located adjacent to an end of an array of nanostructure channels 315, as opposed to being located between rows of nanostructure channels 315 in the y-direction.

As shown in an example implementation 2240 of a top view layout in FIG. 22H, a through-substrate interconnect structure 1410 may include a plurality of non-contiguous segments 2210 that are located adjacent to an end of an array of nanostructure channels 315, as opposed to being located between rows of nanostructure channels 315 in the y-direction.

As shown in an example implementation 2245 of a top view layout in FIG. 22I, a through-substrate interconnect structure 1410 may be located adjacent to an end of an array of nanostructure channels 315, as opposed to being located between rows of nanostructure channels 315 in the y-direction. Moreover, the through-substrate interconnect structure 1410 may be spaced apart from an adjacent row of nanostructure channels 315 by a distance (indicated in FIG. 22I as dimension D10) corresponding to one or more rows of nanostructure channels 315. This may reduce the likelihood of occurrence of layout-dependent effects for the through-substrate interconnect structure 1410.

As indicated above, FIGS. 22A-22I are provided as examples. Other examples may differ from what is described with regard to FIGS. 22A-22I.

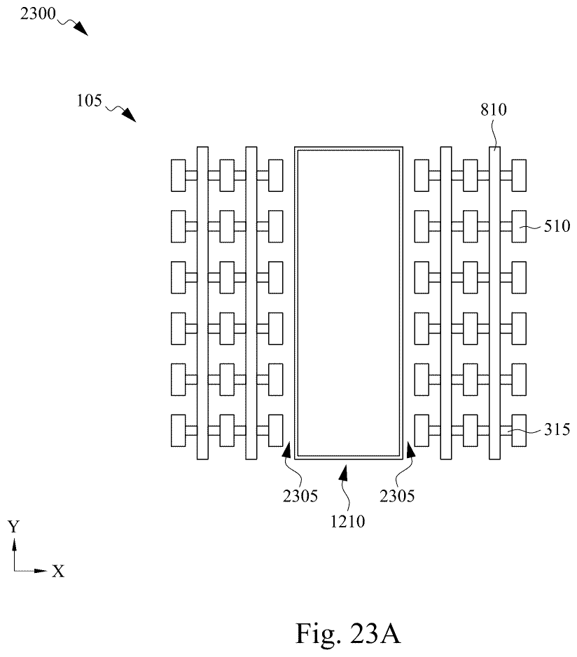

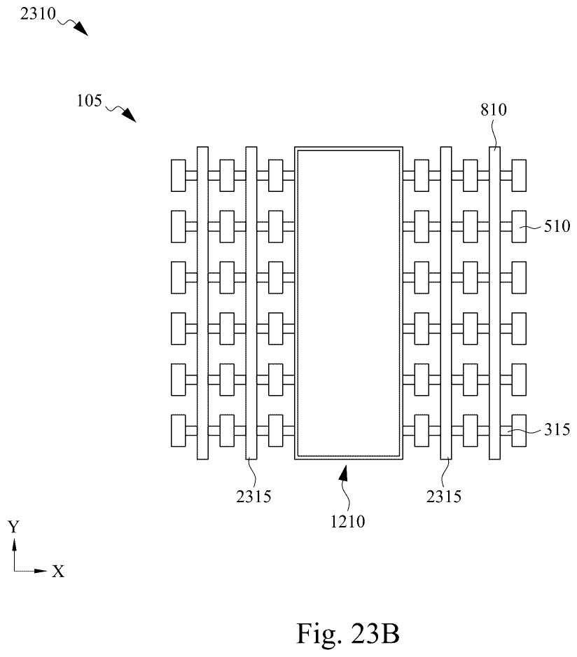

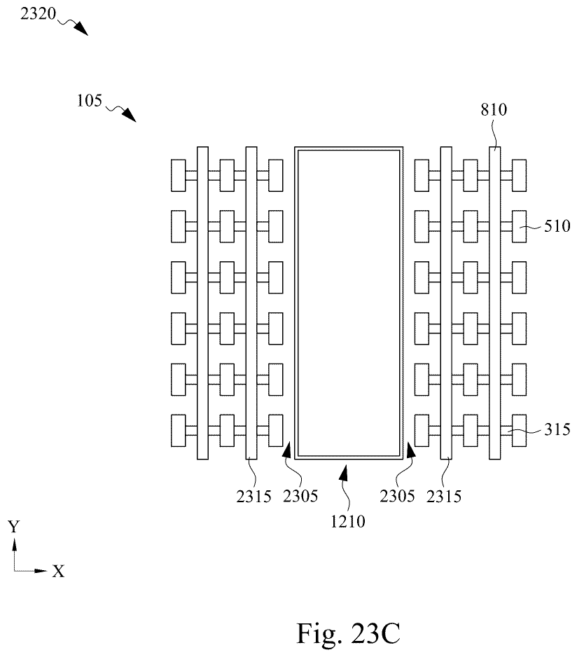

FIGS. 23A-23C are diagrams of example implementations of top view layouts for through-substrate interconnect structures 1210 (e.g., CPODE/CMODE TSVs) in the semiconductor device 105 described herein. The example implementations of top view layouts illustrated in FIGS. 23A-23C are examples, and other example implementations of top view layouts for through-substrate interconnect structure(s) 1210 are within the scope of the present disclosure.

As shown in an example implementation 2300 of a top view layout in FIG. 23A, the semiconductor device 105 may include a plurality of stacks of nanostructure channels 315, a plurality of source/drain regions 510, a plurality of gate structures 810, and one or more through-substrate interconnect structures 1210. As further shown in FIG. 23A, a through-substrate interconnect structure 1210 may extend in the y-direction and may extend approximately parallel to the gate structures 810 and approximately perpendicular to the nanostructure channels 315.

As further shown in FIG. 23A, gaps 2305 are included between the sides of the through-substrate interconnect structures 1210 and the source/drain regions 510 laterally adjacent to the through-substrate interconnect structures 1210. In other words, stacks of nanostructure channels 315 are omitted from between the through-substrate interconnect structures 1210 and the source/drain regions 510 adjacent to the through-substrate interconnect structures 1210. This may reduce the likelihood of occurrence of layout-dependent effects for the through-substrate interconnect structure 1210, may reduce the likelihood of capacitive coupling between the through-substrate interconnect structure 1210 and the source/drain regions 510, and/or may reduce current leakage from the through-substrate interconnect structure 1210.

As shown in an example implementation 2310 of a top view layout in FIG. 23B, the semiconductor device 105 may include one or more active region isolation structures 2315 that extend in the y-direction. An active region isolation structure 2315 may be included to further reduce the likelihood of occurrence of layout-dependent effects for the through-substrate interconnect structure 1210, to further reduce the likelihood of capacitive coupling between the through-substrate interconnect structure 1210 and the source/drain regions 510, and/or to further reduce current leakage from the through-substrate interconnect structure 1210.

As shown in an example implementation 2320 of a top view layout in FIG. 23C, the semiconductor device 105 may include one or more active region isolation structures 2315 that extend in the y-direction, in addition to gaps 2305 that are included between the sides of the through-substrate interconnect structures 1210 and the source/drain regions 510 laterally adjacent to the through-substrate interconnect structures 1210. The active region isolation structure(s) 2315, in combination with the gaps 2305, may be included to further reduce the likelihood of occurrence of layout-dependent effects for the through-substrate interconnect structure 1210, to further reduce the likelihood of capacitive coupling between the through-substrate interconnect structure 1210 and the source/drain regions 510, and/or to further reduce current leakage from the through-substrate interconnect structure 1210.

As indicated above, FIGS. 23A-23C are provided as examples. Other examples may differ from what is described with regard to FIG. 23A-23C.

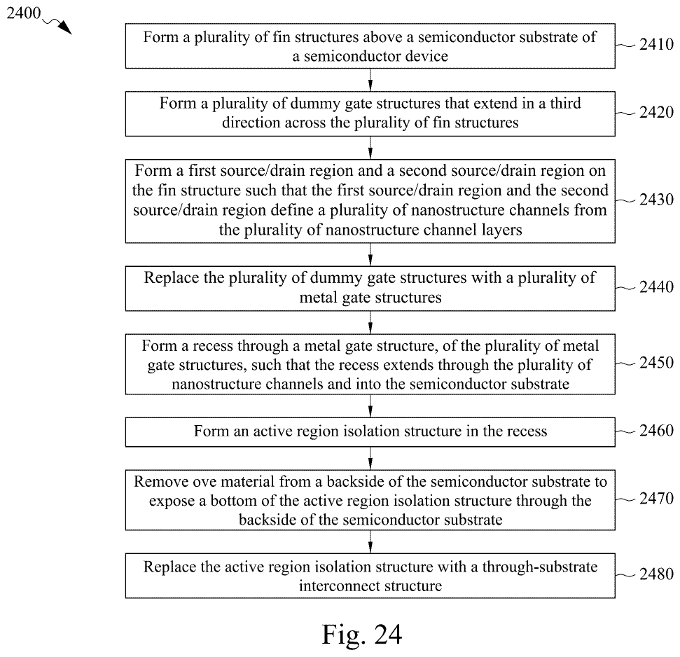

FIG. 24 is a flowchart of an example process 2400 associated with forming a semiconductor device described herein. In some implementations, one or more process blocks of FIG. 24 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 24, process 2400 may include forming a plurality of fin structures above a semiconductor substrate of a semiconductor device (block 2410). For example, one or more semiconductor processing tools may be used to form a plurality of fin structures (e.g., fin structures 155) above a semiconductor substrate (e.g., a semiconductor substrate 110) of a semiconductor device (e.g., a semiconductor device 105), as described herein. In some implementations, the plurality of fin structures extend in a first direction (e.g., an x-direction) in the semiconductor device. In some implementations, a fin structure, of the plurality of fin structures, includes a plurality of nanostructure channel layers (e.g., nanostructure channel layers 125) arranged in a second direction (e.g., a z-direction) that is approximately perpendicular to the semiconductor substrate.

As further shown in FIG. 24, process 2400 may include forming a plurality of dummy gate structures that extend in a third direction across the plurality of fin structures (block 2420). For example, one or more semiconductor processing tools may be used to form a plurality of dummy gate structures (e.g., dummy gate structures 205) that extend in a third direction (e.g., a y-direction) across the plurality of fin structures, as described herein. In some implementations, the third direction is approximately perpendicular to the first direction.

As further shown in FIG. 24, process 2400 may include forming a first source/drain region and a second source/drain region on the fin structure such that the first source/drain region and the second source/drain region define a plurality of nanostructure channels from the plurality of nanostructure channel layers (block 2430). For example, one or more semiconductor processing tools may be used to form a first source/drain region (e.g., a source/drain region 510) and a second source/drain region (e.g., a source/drain region 510) on the fin structure such that the first source/drain region and the second source/drain region define a plurality of nanostructure channels (e.g., nanostructure channels 315) from the plurality of nanostructure channel layers, as described herein. In some implementations, the first source/drain region and the second source/drain region are located on opposing sides of a dummy gate structure (e.g., a dummy gate structure 205) of the plurality of dummy gate structures.

As further shown in FIG. 24, process 2400 may include replacing the plurality of dummy gate structures with a plurality of metal gate structures (block 2440). For example, one or more semiconductor processing tools may be used to replace the plurality of dummy gate structures with a plurality of metal gate structures (e.g., gate structures 810), as described herein.

As further shown in FIG. 24, process 2400 may include forming a recess through a metal gate structure, of the plurality of metal gate structures, such that the recess extends through the plurality of nanostructure channels and into the semiconductor substrate (block 2450). For example, one or more semiconductor processing tools may be used to form a recess (e.g., an active region isolation recess 730) through a metal gate structure, of the plurality of metal gate structures, such that the recess extends through the plurality of nanostructure channels and into the semiconductor substrate, as described herein.

As further shown in FIG. 24, process 2400 may include forming an active region isolation structure in the recess (block 2460). For example, one or more semiconductor processing tools may be used to form an active region isolation structure (e.g., an active region isolation structure 740) in the recess, as described herein.

As further shown in FIG. 24, process 2400 may include removing material from a backside of the semiconductor substrate to expose a bottom of the active region isolation structure through the backside of the semiconductor substrate (block 2470). For example, one or more semiconductor processing tools may be used to remove material from a backside of the semiconductor substrate to expose a bottom of the active region isolation structure through the backside of the semiconductor substrate, as described herein.

As further shown in FIG. 24, process 2400 may include replacing the active region isolation structure with a through-substrate interconnect structure (block 2480). For example, one or more semiconductor processing tools may be used to replace the active region isolation structure with a through-substrate interconnect structure (e.g., a through-substrate interconnect structure 1210), as described herein.

Process 2400 may include additional implementations, such as any single implementation or any combination of implementations described below and/or in connection with one or more other processes described elsewhere herein.

In a first implementation, replacing the active region isolation structure with the through-substrate interconnect structure includes etching the active region isolation structure from the backside of the semiconductor substrate to remove the active region isolation structure, removal of the active region isolation structure results in formation of another recess (e.g., a recess 1205) through the semiconductor substrate and to a conductive structure (e.g., a conductive structure 1030) above a frontside of the semiconductor substrate, and forming the through-substrate interconnect structure in the other recess.

In a second implementation, alone or in combination with the first implementation, process 2400 includes forming a hard mask layer (e.g., a hard mask layer 1135) on the backside of the semiconductor substrate, where etching the active region isolation structure includes etching the active region isolation structure through the hard mask layer to form the other recess.

In a third implementation, alone or in combination with one or more of the first and second implementations, process 2400 includes forming, from the backside of the semiconductor substrate, another recess (e.g., a source/drain recess 1115) through the semiconductor substrate and to the first source/drain region, and forming a source/drain contact (e.g., a source/drain contact 1120) on the first source/drain region in the other recess.

In a fourth implementation, alone or in combination with one or more of the first through third implementations, forming the source/drain contact includes forming the source/drain contact prior to replacing the active region isolation structure with the through-substrate interconnect structure.

In a fifth implementation, alone or in combination with one or more of the first through fourth implementations, forming the recess includes forming the recess through two or more of the fin structures.

In a sixth implementation, alone or in combination with one or more of the first through fifth implementations, process 2400 includes forming another recess (e.g., a gate isolation recess 935) through two or more metal gate structures of the plurality of metal gate structures, filling the other recess with a gate isolation structure (e.g., a gate isolation structure 945), and replacing the gate isolation structure with another through-substrate interconnect structure (e.g., a through-substrate interconnect structure 1410).

In a seventh implementation, alone or in combination with one or more of the first through sixth implementations, the recess extends along opposing sides of an interlayer dielectric region (e.g., an ILD layer 605) between the two or more metal gate structures.

Although FIG. 24 shows example blocks of process 2400, in some implementations, process 2400 includes additional blocks, fewer blocks, different blocks, or differently arranged blocks than those depicted in FIG. 24. Additionally, or alternatively, two or more of the blocks of process 2400 may be performed in parallel.

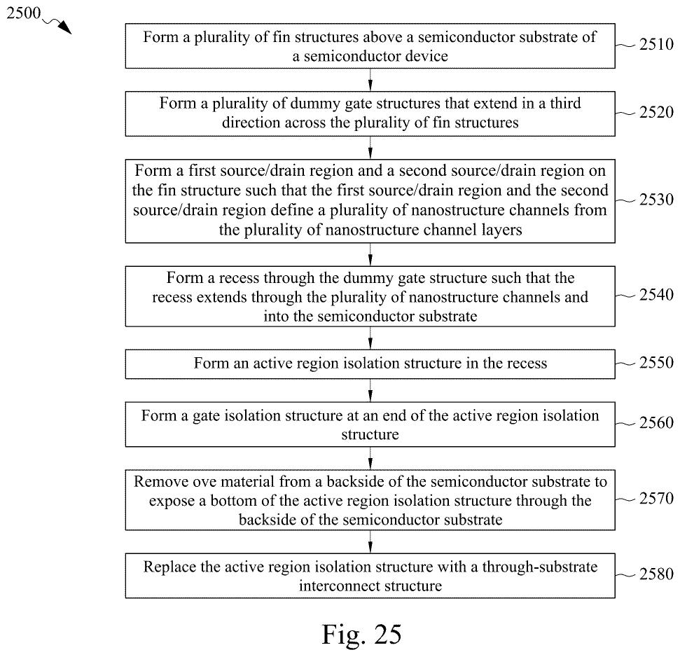

FIG. 25 is a flowchart of an example process 2500 associated with forming a semiconductor device described herein. In some implementations, one or more process blocks of FIG. 25 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 25, process 2500 may include forming a plurality of fin structures above a semiconductor substrate of a semiconductor device (block 2510). For example, one or more semiconductor processing tools may be used to form a plurality of fin structures (e.g., fin structures 155) above a semiconductor substrate (e.g., a semiconductor substrate 110) of a semiconductor device (e.g., a semiconductor device 105), as described herein. In some implementations, the plurality of fin structures extend in a first direction (e.g., an x-direction) in the semiconductor device. In some implementations, a fin structure, of the plurality of fin structures, includes a plurality of nanostructure channel layers (e.g., nanostructure channel layers 125) arranged in a second direction (e.g., a z-direction) that is approximately perpendicular to the semiconductor substrate.

As further shown in FIG. 25, process 2500 may include forming a plurality of dummy gate structures that extend in a third direction across the plurality of fin structures (block 2520). For example, one or more semiconductor processing tools may be used to form a plurality of dummy gate structures (e.g., dummy gate structures 205) that extend in a third direction (e.g., a y-direction) across the plurality of fin structures, as described herein. In some implementations, the third direction is approximately perpendicular to the first direction.

As further shown in FIG. 25, process 2500 may include forming a first source/drain region and a second source/drain region on the fin structure such that the first source/drain region and the second source/drain region define a plurality of nanostructure channels from the plurality of nanostructure channel layers (block 2530). For example, one or more semiconductor processing tools may be used to form a first source/drain region (e.g., a source/drain region 510) and a second source/drain region (e.g., a source/drain region 510) on the fin structure such that the first source/drain region and the second source/drain region define a plurality of nanostructure channels (e.g., nanostructure channels 315) from the plurality of nanostructure channel layers, as described herein. In some implementations, the first source/drain region and the second source/drain region are located on opposing sides of a dummy gate structure (e.g., a dummy gate structure 205) of the plurality of dummy gate structures.

As further shown in FIG. 25, process 2500 may include forming a recess through the dummy gate structure such that the recess extends through the plurality of nanostructure channels and into the semiconductor substrate (block 2540). For example, one or more semiconductor processing tools may be used to form a recess (e.g., an active region isolation recess 730) through the dummy gate structure such that the recess extends through the plurality of nanostructure channels and into the semiconductor substrate, as described herein.

As further shown in FIG. 25, process 2500 may include forming an active region isolation structure in the recess (block 2550). For example, one or more semiconductor processing tools may be used to form an active region isolation structure (e.g., an active region isolation structure 740) in the recess, as described herein.

As further shown in FIG. 25, process 2500 may include forming a gate isolation structure at an end of the active region isolation structure (block 2560). For example, one or more semiconductor processing tools may be used to form a gate isolation structure (e.g., a gate isolation structure 1810) at an end of the active region isolation structure, as described herein.

As further shown in FIG. 25, process 2500 may include removing material from a backside of the semiconductor substrate to expose a bottom of the active region isolation structure through the backside of the semiconductor substrate (block 2570). For example, one or more semiconductor processing tools may be used to remove material from a backside of the semiconductor substrate to expose a bottom of the active region isolation structure through the backside of the semiconductor substrate, as described herein.

As further shown in FIG. 25, process 2500 may include replacing the active region isolation structure with a through-substrate interconnect structure (block 2580). For example, one or more semiconductor processing tools may be used to replace the active region isolation structure with a through-substrate interconnect structure (e.g., a through-substrate interconnect structure 1210), as described herein.

Process 2500 may include additional implementations, such as any single implementation or any combination of implementations described below and/or in connection with one or more other processes described elsewhere herein.

In a first implementation, forming the gate isolation structure includes forming the gate isolation structure adjacent to a first end of the active region isolation structure, and the process 2500 includes forming another gate isolation structure (e.g., a gate isolation structure 1810) adjacent to a second end of the active region isolation structure opposing the first end.

In a second implementation, alone or in combination with the first implementation, replacing the active region isolation structure with the through-substrate interconnect structure includes forming the through-substrate interconnect structure laterally between the gate isolation structure and the other gate isolation structure.

In a third implementation, alone or in combination with one or more of the first and second implementations, forming the gate isolation structure includes forming another recess (e.g., a gate isolation recess 1805) that extends through the end of the active region isolation structure, and depositing dielectric material of the gate isolation structure such that the gate isolation structure is in contact with the end of the active region isolation structure.

In a fourth implementation, alone or in combination with one or more of the first through third implementations, forming the recess includes forming a main trench (e.g., a main trench 1905) of the recess such that the main trench extends through the dummy gate structure and to a top of a STI region (e.g., an STI region 175), and forming bottom extension vias (e.g., extension vias 1910) that extend from a bottom of the main trench through two or more of the fin structures.

In a fifth implementation, alone or in combination with one or more of the first through fourth implementations, replacing the active region isolation structure with the through-substrate interconnect structure includes forming extension via structures (e.g., extension via structures 1930) of the active region isolation structure in the bottom extension vias, and forming a main body (e.g., a main body 1925) of the active region isolation structure in the main trench.

Although FIG. 25 shows example blocks of process 2500, in some implementations, process 2500 includes additional blocks, fewer blocks, different blocks, or differently arranged blocks than those depicted in FIG. 25. Additionally, or alternatively, two or more of the blocks of process 2500 may be performed in parallel.

In this way, an electrical isolation structure (e.g., an active region isolation structure, a gate isolation structure) of a semiconductor device is removed from a back side of the semiconductor device after formation of nanostructure transistors of the semiconductor device and replaced with a through-substrate interconnect structure. The back side of the semiconductor device may be grinded down to reveal the bottom of the electrical isolation structure, and the electrical isolation structure may be removed through the back side of the semiconductor device and filled in with the through-substrate interconnect structure from the back side of the semiconductor device. Using the electrical isolation structure as a placeholder for the through-substrate interconnect structure enables the through-substrate interconnect structure to be formed from the back side of the semiconductor device in a self-aligned manner, which increases the reliability and repeatability of forming electrical connections between the back side and a front side of the semiconductor device, compared to other techniques that might otherwise result in misalignment (and failed electrical connection) when forming portions of a through-substrate interconnect structure from both the front side and the back side of the semiconductor device.

The through-substrate interconnect structure may be electrically coupled to conductive structures on the front side and on the back side of the semiconductor device. In this way, the through-substrate interconnect structure enables signals and/or power to be routed between the front side and the back side of the semiconductor device.

As described in greater detail above, some implementations described herein provide a method. The method includes forming a plurality of fin structures above a semiconductor substrate of a semiconductor device, where the plurality of fin structures extend in a first direction in the semiconductor device, and where a fin structure, of the plurality of fin structures, comprises a plurality of nanostructure channel layers arranged in a second direction that is approximately perpendicular to the semiconductor substrate. The method includes forming a plurality of dummy gate structures that extend in a third direction across the plurality of fin structures, where the third direction is approximately perpendicular to the first direction. The method includes forming a first source/drain region and a second source/drain region on the fin structure such that the first source/drain region and the second source/drain region define a plurality of nanostructure channels from the plurality of nanostructure channel layers, where the first source/drain region and the second source/drain region are located on opposing sides of a dummy gate structure of the plurality of dummy gate structures. The method includes replacing the plurality of dummy gate structures with a plurality of metal gate structures. The method includes forming a recess through a metal gate structure, of the plurality of metal gate structures, such that the recess extends through the plurality of nanostructure channels and into the semiconductor substrate. The method includes forming an active region isolation structure in the recess. The method includes removing material from a backside of the semiconductor substrate to expose a bottom of the active region isolation structure through the backside of the semiconductor substrate. The method includes replacing the active region isolation structure with a through-substrate interconnect structure.

As described in greater detail above, some implementations described herein provide a method. The method includes forming a plurality of fin structures above a semiconductor substrate of a semiconductor device, where the plurality of fin structures extend in a first direction in the semiconductor device, and where a fin structure, of the plurality of fin structures, includes a plurality of nanostructure channel layers arranged in a second direction that is approximately perpendicular to the semiconductor substrate. The method includes forming a plurality of dummy gate structures that extend in a third direction across the plurality of fin structures, where the third direction is approximately perpendicular to the first direction. The method includes forming a first source/drain region and a second source/drain region on the fin structure such that the first source/drain region and the second source/drain region define a plurality of nanostructure channels from the plurality of nanostructure channel layers, where the first source/drain region and the second source/drain region are located on opposing sides of a dummy gate structure of the plurality of dummy gate structures. The method includes forming a recess through the dummy gate structure such that the recess extends through the plurality of nanostructure channels and into the semiconductor substrate. The method includes forming an active region isolation structure in the recess. The method includes forming a gate isolation structure at an end of the active region isolation structure. The method includes removing material from a backside of the semiconductor substrate to expose a bottom of the active region isolation structure through the backside of the semiconductor substrate. The method includes replacing the active region isolation structure with a through-substrate interconnect structure.

As described in greater detail above, some implementations described herein provide a semiconductor device. The semiconductor device includes a plurality of nanostructure channels arranged in a first direction. The semiconductor device includes a first source/drain region adjacent to first ends of the plurality of nanostructure channels. The semiconductor device includes a second source/drain region adjacent to second ends of the plurality of nanostructure channels opposing the first ends in a second direction. The semiconductor device includes a first gate structure extending between the first source/drain region and the second source/drain region in a third direction, where the first gate structure wraps around the plurality of nanostructure channels. The semiconductor device includes a through-substrate interconnect structure arranged in the second direction, where the through-substrate interconnect structure extends in the first direction alongside the plurality of nanostructure channels.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of fin structures above a semiconductor substrate of a semiconductor device,
wherein the plurality of fin structures extend in a first direction in the semiconductor device, and
wherein a fin structure, of the plurality of fin structures, comprises a plurality of nanostructure channel layers arranged in a second direction that is approximately perpendicular to the semiconductor substrate;
forming a plurality of dummy gate structures that extend in a third direction across the plurality of fin structures,
wherein the third direction is approximately perpendicular to the first direction;
forming a first source/drain region and a second source/drain region on the fin structure such that the first source/drain region and the second source/drain region define a plurality of nanostructure channels from the plurality of nanostructure channel layers,
wherein the first source/drain region and the second source/drain region are located on opposing sides of a dummy gate structure of the plurality of dummy gate structures;
replacing the plurality of dummy gate structures with a plurality of metal gate structures;
forming a recess through a metal gate structure, of the plurality of metal gate structures, such that the recess extends through the plurality of nanostructure channels and into the semiconductor substrate;
forming an active region isolation structure in the recess;
removing material from a backside of the semiconductor substrate to expose a bottom of the active region isolation structure through the backside of the semiconductor substrate; and
replacing the active region isolation structure with a through-substrate interconnect structure.

2. The method of claim 1, wherein replacing the active region isolation structure with the through-substrate interconnect structure comprises:
etching the active region isolation structure from the backside of the semiconductor substrate to remove the active region isolation structure,
wherein removal of the active region isolation structure results in formation of another recess through the semiconductor substrate and to a conductive structure above a frontside of the semiconductor substrate; and
forming the through-substrate interconnect structure in the other recess.

3. The method of claim 2, further comprising:
forming a hard mask layer on the backside of the semiconductor substrate,
wherein etching the active region isolation structure comprises etching the active region isolation structure through the hard mask layer to form the other recess.

4. The method of claim 1, further comprising:
forming, from the backside of the semiconductor substrate, another recess through the semiconductor substrate and to the first source/drain region; and
forming a source/drain contact on the first source/drain region in the other recess.

5. The method of claim 4, wherein forming the source/drain contact comprises:
forming the source/drain contact prior to replacing the active region isolation structure with the through-substrate interconnect structure.

6. The method of claim 1, wherein forming the recess comprises:
forming the recess through two or more of the fin structures.

7. The method of claim 1, further comprising:
forming another recess through two or more metal gate structures of the plurality of metal gate structures;
filling the other recess with a gate isolation structure; and
replacing the gate isolation structure with another through-substrate interconnect structure.

8. The method of claim 7, further comprising:
wherein the recess extends along opposing sides of an interlayer dielectric region between the two or more metal gate structures.

9. A method, comprising:
forming a plurality of fin structures above a semiconductor substrate of a semiconductor device,
wherein the plurality of fin structures extend in a first direction in the semiconductor device, and
wherein a fin structure, of the plurality of fin structures, comprises a plurality of nanostructure channel layers arranged in a second direction that is approximately perpendicular to the semiconductor substrate;
forming a plurality of dummy gate structures that extend in a third direction across the plurality of fin structures,
wherein the third direction is approximately perpendicular to the first direction;
forming a first source/drain region and a second source/drain region on the fin structure such that the first source/drain region and the second source/drain region define a plurality of nanostructure channels from the plurality of nanostructure channel layers,
wherein the first source/drain region and the second source/drain region are located on opposing sides of a dummy gate structure of the plurality of dummy gate structures;
forming a recess through the dummy gate structure such that the recess extends through the plurality of nanostructure channels and into the semiconductor substrate;
forming an active region isolation structure in the recess;
forming a gate isolation structure at an end of the active region isolation structure;
removing material from a backside of the semiconductor substrate to expose a bottom of the active region isolation structure through the backside of the semiconductor substrate; and
replacing the active region isolation structure with a through-substrate interconnect structure.

10. The method of claim 9, wherein forming the gate isolation structure comprises:
forming the gate isolation structure adjacent to a first end of the active region isolation structure; and
wherein the method further comprises:
forming another gate isolation structure adjacent to a second end of the active region isolation structure opposing the first end.

11. The method of claim 10, wherein replacing the active region isolation structure with the through-substrate interconnect structure comprises:
forming the through-substrate interconnect structure laterally between the gate isolation structure and the other gate isolation structure.

12. The method of claim 9, wherein forming the gate isolation structure comprises:
forming another recess that extends through the end of the active region isolation structure; and
depositing dielectric material of the gate isolation structure such that the gate isolation structure is in contact with the end of the active region isolation structure.

13. The method of claim 9, wherein forming the recess comprises:
forming a main trench of the recess such that the main trench extends through the dummy gate structure and to a top of a shallow trench isolation (STI) region; and
forming bottom extension vias that extend from a bottom of the main trench through two or more of the fin structures.

14. The method of claim 13, wherein replacing the active region isolation structure with the through-substrate interconnect structure comprises:
forming extension via structures of the active region isolation structure in the bottom extension vias; and
forming a main body of the active region isolation structure in the main trench.

15. A semiconductor device, comprising:
a plurality of nanostructure channels arranged in a first direction;
a first source/drain region adjacent to first ends of the plurality of nanostructure channels;
a second source/drain region adjacent to second ends of the plurality of nanostructure channels opposing the first ends in a second direction;
a first gate structure extending between the first source/drain region and the second source/drain region in a third direction,
wherein the first gate structure wraps around the plurality of nanostructure channels; and
a through-substrate interconnect structure arranged in the second direction,
wherein the through-substrate interconnect structure extends in the first direction alongside the plurality of nanostructure channels.

16. The semiconductor device of claim 15, wherein the through-substrate interconnect structure continuously extends alongside the first source/drain region, the plurality of nanostructure channels, and the second source/drain region in the second direction.

17. The semiconductor device of claim 15, wherein the through-substrate interconnect structure comprises a plurality of non-contiguous segments arranged in the second direction alongside the first source/drain region, the plurality of nanostructure channels, and the second source/drain region in the second direction.

18. The semiconductor device of claim 15, wherein a width of the through-substrate interconnect structure in the third direction is approximately equal to a distance across a plurality of sets of nanostructure channels arranged in the third direction.

19. The semiconductor device of claim 17, further comprising:
another through-substrate interconnect structure extending in the third direction and laterally adjacent to the first source/drain region.

20. The semiconductor device of claim 19, further comprising:
a third source/drain region laterally adjacent to the other through-substrate interconnect structure; and
an active region isolation structure laterally adjacent to the third source/drain region,
wherein the third source/drain region is laterally between the active region isolation structure and the other through-substrate interconnect structure.
